(19) United States
(12) Patent Application Publication
(10) Pub. No.: US 2024/0247186 A1
(43) Pub. Date: Jul. 25, 2024

(54) LIGHT-EMITTING ORGANIC NANOPARTICLES, COMPOSITION FOR COLOR CONVERSION FILM INCLUDING THE SAME, AND COLOR CONVERSION FILM, DISPLAY DEVICE, AND LIGHT-EMITTING DIODE DEVICE MANUFACTURED USING THE SAME

(71) Applicants: ND-Materials Corp., Seoul (KR); Clap Co., Ltd., Seoul (KR)

(72) Inventors: Jang Hyuk Kwon, Seongnam-si (KR); Gyeong Min Ki, Seongnam-si (KR); Sung Ho Kim, Seoul (KR); Kang II Seo, Seoul (KR); Mi Young Chae, Yongin-si (KR); Young Hun Jung, Seoul (KR)

(73) Assignees: ND-Materials Corp., Seoul (KR); Clap Co., Ltd., Seoul (KR)

(21) Appl. No.: 18/491,206

(22) Filed: Oct. 20, 2023

(30) Foreign Application Priority Data
Dec. 30, 2022 (KR) 10-2022-0190644
Apr. 11, 2023 (KR) 10-2023-0047372

(51) Int. Cl. C09K 11/06; C09K 11/02; H10K 59/38

(52) U.S. Cl. CPC C09K 11/06; C09K 11/025; H10K 59/38; C09K 2211/1018; G02F 1/133514

(57) ABSTRACT

Provided are light-emitting organic nanoparticles containing an organic phosphor having a luminous efficiency of 80% or more, wherein the light-emitting organic nanoparticles has an average particle size of 100 to 170 nm and a standard deviation of particle sizes of 500 nm or less, a composition for a color conversion film including the same, and a color conversion film, a display device, and a light-emitting diode device manufactured using the same.

### CROSS-REFERENCE TO RELATED APPLICATION

This application claims priority to and the benefit of Korean Patent Application No. 10-2022-0190644, filed on Dec. 30, 2022, the disclosure of which is incorporated herein by reference in its entirety.

### BACKGROUND

### 1. Field of the Invention

The present invention relates to light-emitting organic nanoparticles, a composition for a color conversion film including the same, and a color conversion film, a display device, and a light-emitting diode device manufactured using the same.

### 2. Discussion of Related Art

In order to make white light using a light-emitting diode (LED) as a light source, a method in which a blue LED is used as a light source and light emitted from the blue LED is converted into white light using a color conversion film formed of phosphors, organic dyes, quantum dots (QDs), and the like is mainly used. In this case, a material of the color conversion film should have a wide full width at half maximum (FWHM) to have a high color rendering index and should have high heat resistance to withstand heat of the LED. In comparison, since a material of a color conversion film used in a display should have high color purity unlike the LED for a light source, fluorescence, phosphorescence, QDs, and the like showing light emission properties with a small FWHM are mainly used.

A method in which a blue LED and a yellow phosphor, which are most widely used in LEDs, are used has a disadvantage in that it has a high correlated color temperature because a color rendering index is low and the yellow phosphor emits a small amount of red light. When organic dyes are used in a color conversion layer, there is a problem in that quenching occurs and photochemical stability is lowered due to the properties of aggregation during light emission.

QDs using inorganic materials have advantages of high photoluminescence quantum yield (PLQY), fast response time, and high reliability, whereas the QDs have disadvantages of being very vulnerable to moisture, having poor heat resistance lower than 100° C. so that it is difficult to use as a color conversion film for a LED, and using heavy metals such as cadmium, arsenic, and lead. Specifically, heavy metals such as lead, cadmium, mercury, chromium, arsenic, and the like have high accumulation in the body and are emerging as a major public health problem. Heavy metals absorbed into the body are accumulated in the hair and organs of the body through the blood, and the residence time of heavy metals in the body is relatively short in blood or urine, but the residence time of heavy metals in the body is relatively long in hair. Generally, the accumulation of heavy metals in vivo is achieved through a serial food chain, and the concentration in the body of the predator is higher than that of the prey. In particular, cadmium, which is used as a fluorescent substance, can cause serious damage to the stomach, lungs, and bones.

In order to apply organic materials or organic nanoparticles to display devices and the like, the organic materials or organic nanoparticles cannot be used alone and should be prepared and used in the form of a film. Films manufactured using organic materials directly have lower light stability than films manufactured using organic nanoparticles. In order to manufacture a film using organic nanoparticles, it is necessary to satisfy conditions such as maintaining the properties of organic nanoparticles, having high dispersion in a resin, having no degradation of properties even when exposed to incident light for a long time, having excellent room temperature stability, and the like.

### RELATED ART DOCUMENT

### Patent Document

(Patent Document 1) Korean Patent Registration No. 10-2081481
(Patent Document 2) Korean Laid-open Patent Application No. 10-2020-0034949

### SUMMARY OF THE INVENTION

The present invention is directed to providing organic nanoparticles obtained from a light-emitting organic material that has excellent color conversion efficiency and thermal stability and does not use heavy metals, a composition for a color conversion film including the same, and a color conversion film, a display device, and a light-emitting diode device manufactured using the same.

One aspect of the present invention provides light-emitting organic nanoparticles containing an organic phosphor having a luminous efficiency of 80% or more, wherein the light-emitting organic nanoparticles has an average particle size of 100 to 170 nm and a standard deviation of particle sizes of 500 nm or less.

The light-emitting organic nanoparticles may have a core-shell structure in which the organic phosphor is surrounded by a surfactant.

The organic phosphor may be a delayed fluorescence material.

The delayed fluorescence material may include a compound represented by Chemical Formula 1 below:

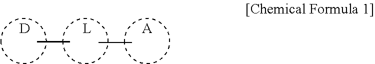

(In Chemical Formula 1 above, L is any one selected from the group consisting of an aryl group, an arylene group, and a carbon-nitrogen single bond, when L is an aryl group, A is a cyano group mono- or di-substituted on the aryl group, and D is a substituent tetra- or penta-substituted on the aryl group, wherein each substituent is independently a heteroaryl group containing a nitrogen atom substituted or unsubstituted with a heteroaryl group having 1 to 10 carbon atoms, when L is an arylene group, A is a substituted or unsubstituted triazine group, and D is a substituted or unsubstituted multi-fused ring, including a conjugated or non-conjugated five-membered or six-membered ring containing a nitrogen atom bonded to the arylene group, wherein the multi-fused ring may further comprise 1 to 9 nitrogen atoms or one Group 16 element as ring-forming elements, in addition to the nitrogen atom boned to the arylene group, when L is a carbon-nitrogen single bond, D is a fused ring having 10 to 40 carbon atoms, including a conjugated or non-conjugated five-membered or six-membered ring containing the nitrogen atom of the L, wherein the conjugated or non-conjugated five-membered or six-membered ring is a substituted or unsubstituted ring, does not contain or contains a Group 16 element as ring-forming elements, and contains 1 or 2 nitrogen atoms as ring-forming elements, and A is a heterocyclic ring having 10 to 40 carbon atoms, including an aryl group containing a carbon atom bonded to the L, wherein the heterocyclic ring includes a ring structure forming a fused ring with the aryl group containing a carbon atom bonded to the L, and wherein the ring structure is a ring structure containing a boron atom and an oxygen atom as ring-forming elements, or is a five-membered or six-membered ring structure containing two conjugated nitrogen atoms).

The compound represented by Chemical Formula 1 above may be one or more selected from the group consisting of compounds T-1 to T-28 below:

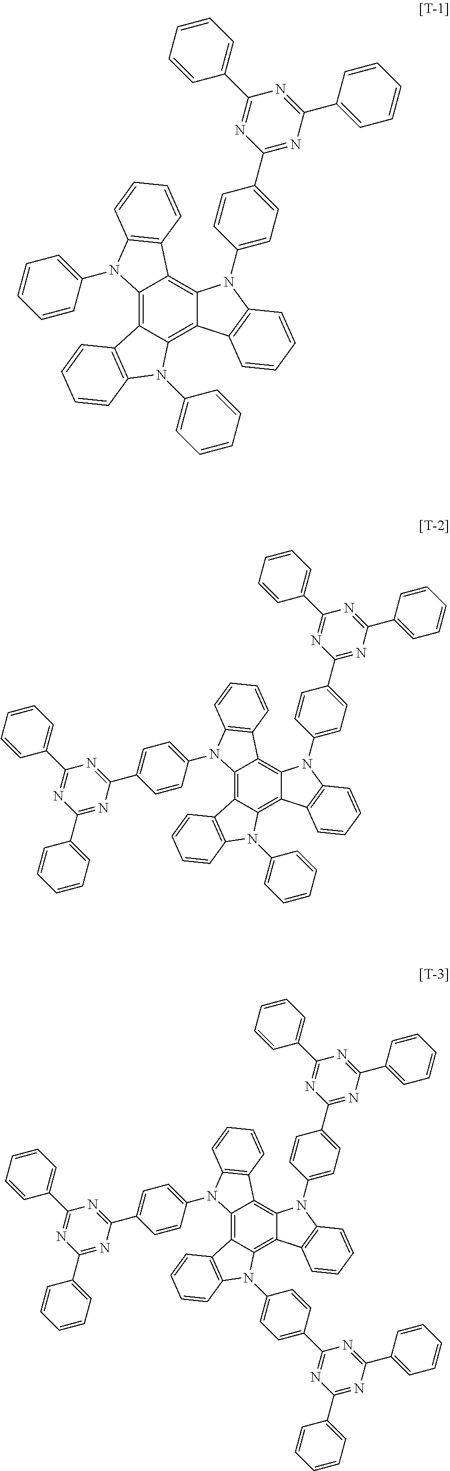 [SMILES: c1ccc(-c2nc(-c3ccccc3)nc(-c3ccc(-n4c5ccccc5c5c6c(c7ccccc7n6-c6ccccc6)c6c(c7ccccc7n6-c6ccccc6)c54)cc3)n2)cc1 ; c1ccc(-c2nc(-c3ccccc3)nc(-c3ccc(-n4c5ccccc5c5c6c(c7ccccc7n6-c6ccccc6)c6c(c7ccccc7n6-c6ccc(-c7nc(-c8ccccc8)nc(-c8ccccc8)n7)cc6)c54)cc3)n2)cc1 ; c1ccc(-c2nc(-c3ccccc3)nc(-c3ccc(-n4c5ccccc5c5c4c4c6ccccc6n(-c6ccc(-c7nc(-c8ccccc8)nc(-c8ccccc8)n7)cc6)c4c4c6ccccc6n(-c6ccc(-c7nc(-c8ccccc8)nc(-c8ccccc8)n7)cc6)c54)cc3)n2)cc1]

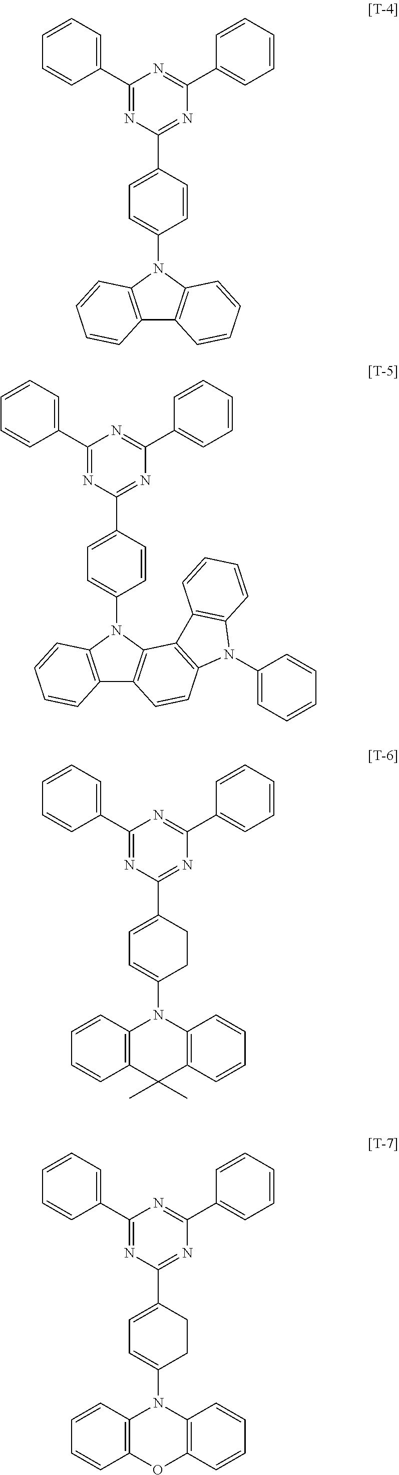

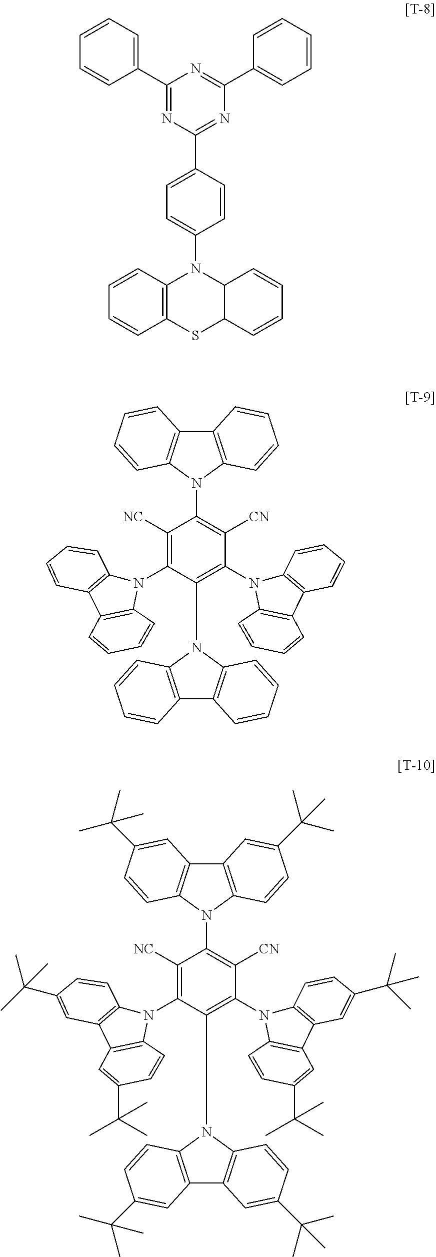 [SMILES: C1=CC2Sc3ccccc3N(c3ccc(-c4nc(-c5ccccc5)nc(-c5ccccc5)n4)cc3)C2C=C1 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21 ; CC(C)(C)c1ccc2c(c1)c1cc(C(C)(C)C)ccc1n2-c1c(C#N)c(-n2c3ccc(C(C)(C)C)cc3c3cc(C(C)(C)C)ccc32)c(-n2c3ccc(C(C)(C)C)cc3c3cc(C(C)(C)C)ccc32)c(-n2c3ccc(C(C)(C)C)cc3c3cc(C(C)(C)C)ccc32)c1C#N]

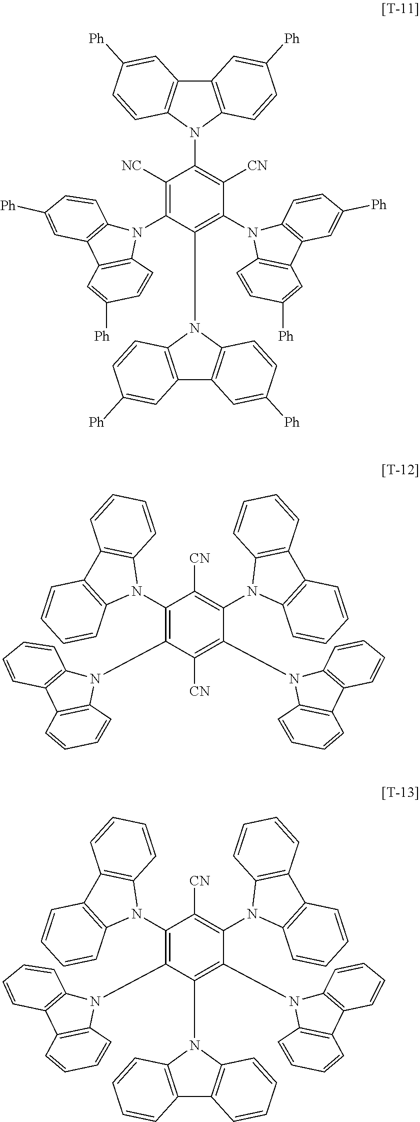 [SMILES: N#Cc1c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c(-n2c3ccc(-c4ccccc4)cc3c3cc(-c4ccccc4)ccc32)c1-n1c2ccc(-c3ccccc3)cc2c2cc(-c3ccccc3)ccc21 ; N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21 ; N#Cc1c(-n2c3ccccc3c3ccccc32)c(-n2c3ccccc3c3ccccc32)c(-n2c3ccccc3c3ccccc32)c(-n2c3ccccc3c3ccccc32)c1-n1c2ccccc2c2ccccc21]

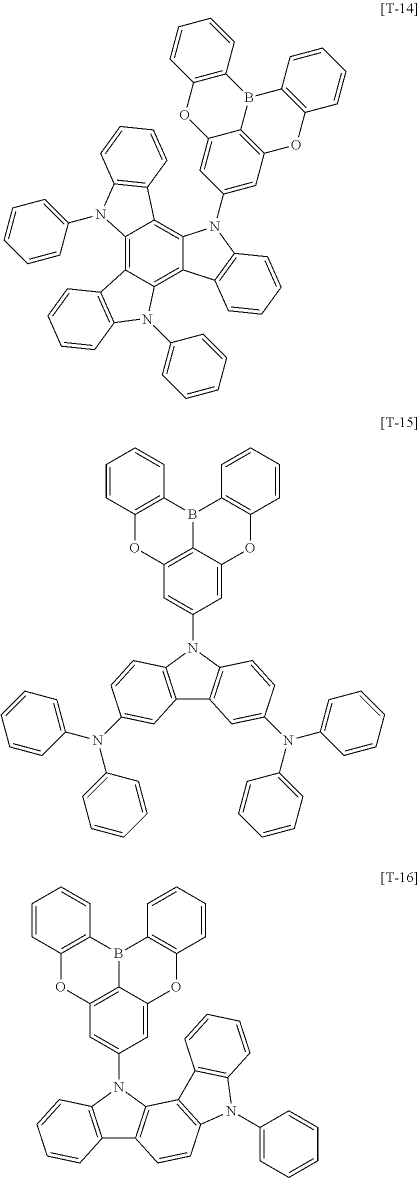 [SMILES: c1ccc(-n2c3ccccc3c3c2c2c4ccccc4n(-c4cc5c6c(c4)Oc4ccccc4B6c4ccccc4O5)c2c2c4ccccc4n(-c4ccccc4)c32)cc1 ; c1ccc(N(c2ccccc2)c2ccc3c(c2)c2cc(N(c4ccccc4)c4ccccc4)ccc2n3-c2cc3c4c(c2)Oc2ccccc2B4c2ccccc2O3)cc1 ; c1ccc(-n2c3ccccc3c3c2ccc2c4ccccc4n(-c4cc5c6c(c4)Oc4ccccc4B6c4ccccc4O5)c23)cc1]

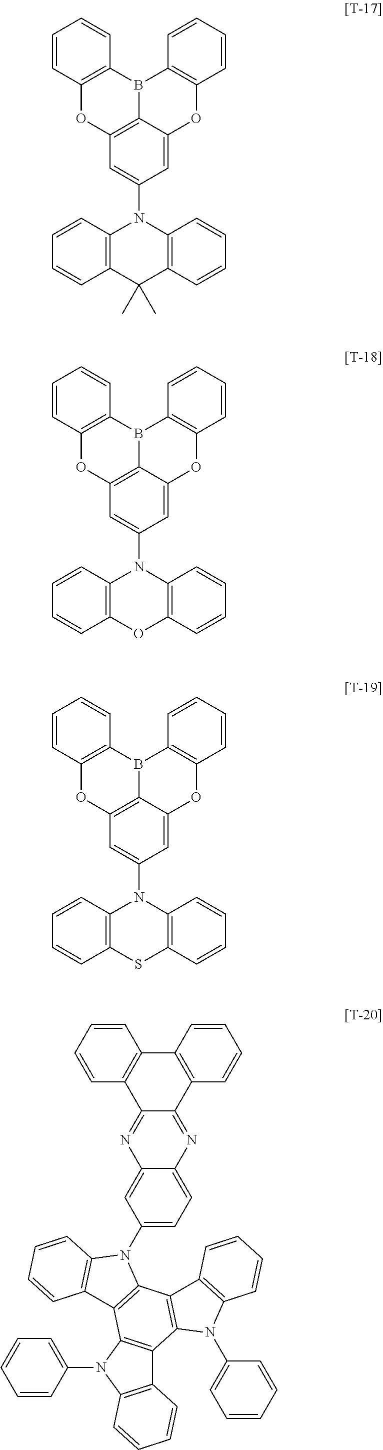 [SMILES: CC1(C)c2ccccc2N(c2cc3c4c(c2)Oc2ccccc2B4c2ccccc2O3)c2ccccc21 ; c1ccc2c(c1)Oc1cc(N3c4ccccc4Oc4ccccc43)cc3c1B2c1ccccc1O3 ; c1ccc2c(c1)Oc1cc(N3c4ccccc4Sc4ccccc43)cc3c1B2c1ccccc1O3 ; c1ccc(-n2c3ccccc3c3c2c2c4ccccc4n(-c4ccc5nc6c7ccccc7c7ccccc7c6nc5c4)c2c2c4ccccc4n(-c4ccccc4)c32)cc1]

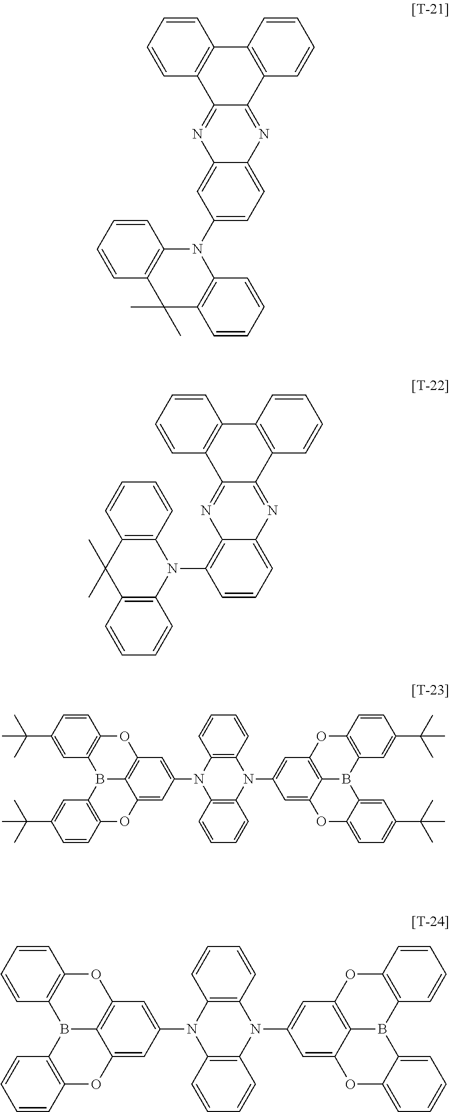 [SMILES: CC1(C)c2ccccc2N(c2ccc3nc4c5ccccc5c5ccccc5c4nc3c2)c2ccccc21 ; CC1(C)c2ccccc2N(c2cccc3nc4c5ccccc5c5ccccc5c4nc23)c2ccccc21 ; CC(C)(C)c1ccc2c(c1)B1c3cc(C(C)(C)C)ccc3Oc3cc(N4c5ccccc5N(c5cc6c7c(c5)Oc5ccc(C(C)(C)C)cc5B7c5cc(C(C)(C)C)ccc5O6)c5ccccc54)cc(c31)O2 ; c1ccc2c(c1)Oc1cc(N3c4ccccc4N(c4cc5c6c(c4)Oc4ccccc4B6c4ccccc4O5)c4ccccc43)cc3c1B2c1ccccc1O3]

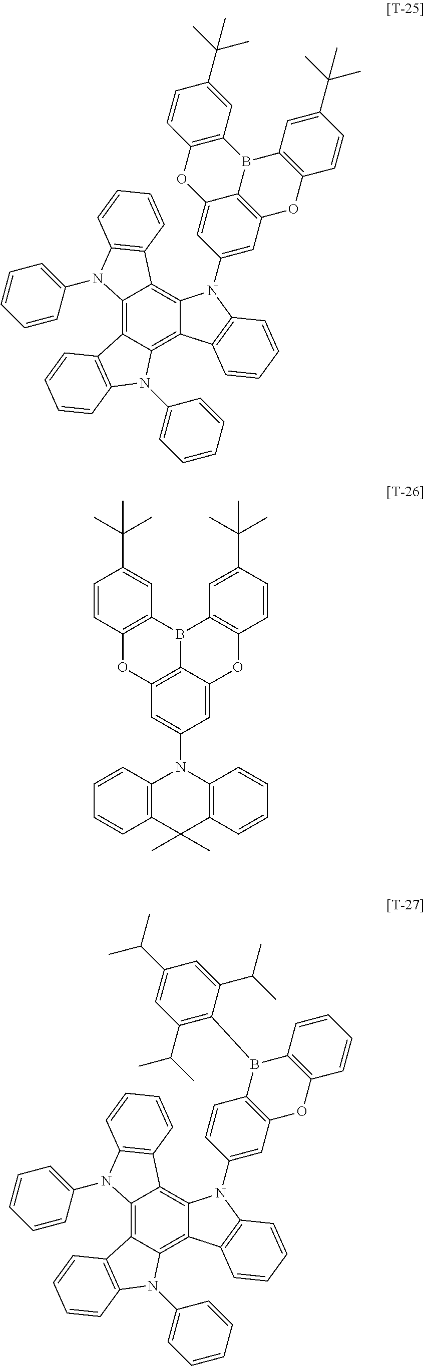 [SMILES: CC(C)(C)c1ccc2c(c1)B1c3cc(C(C)(C)C)ccc3Oc3cc(-n4c5ccccc5c5c6c(c7ccccc7n6-c6ccccc6)c6c(c7ccccc7n6-c6ccccc6)c54)cc(c31)O2 ; CC(C)(C)c1ccc2c(c1)B1c3cc(C(C)(C)C)ccc3Oc3cc(N4c5ccccc5C(C)(C)c5ccccc54)cc(c31)O2 ; CC(C)c1cc(C(C)C)c(B2c3ccccc3Oc3cc(-n4c5ccccc5c5c6c(c7ccccc7n6-c6ccccc6)c6c(c7ccccc7n6-c6ccccc6)c54)ccc32)c(C(C)C)c1]

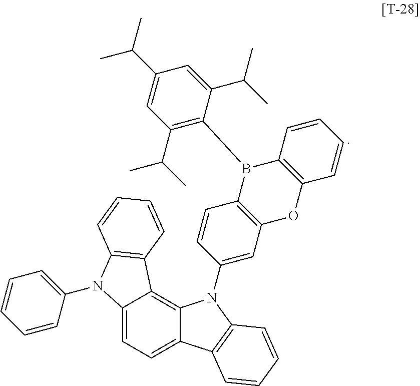 [SMILES: CC(C)c1cc(C(C)C)c(B2c3ccccc3Oc3cc(-n4c5ccccc5c5ccc6c(c7ccccc7n6-c6ccccc6)c54)ccc32)c(C(C)C)c1]

The organic phosphor may include a boron compound represented by Chemical Formula 2 below:

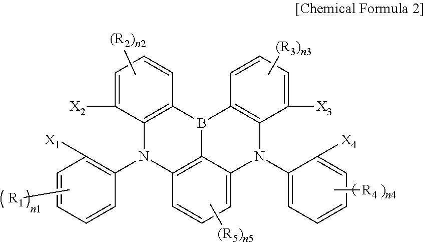

(In Chemical Formula 2 above, R₁ to R₅ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, X₁ to X₄ are each independently hydrogen, hydroxyl group or a substituted or unsubstituted alkyl group, n1 and n4 are each independently an integer of 1 to 4, n2, n3 and n5 are each independently an integer of 1 to 3, if n1 to n5 are 2 or more, the structures in the brackets, are the same or different, respectively, R₁ to R₅ and X₁ to X₄ may bond to adjacent substituents to form a substituted or unsubstituted ring).

The boron compound represented by Chemical Formula 2 above may be one or more selected from the group consisting of compounds D-1 to D-30 below:

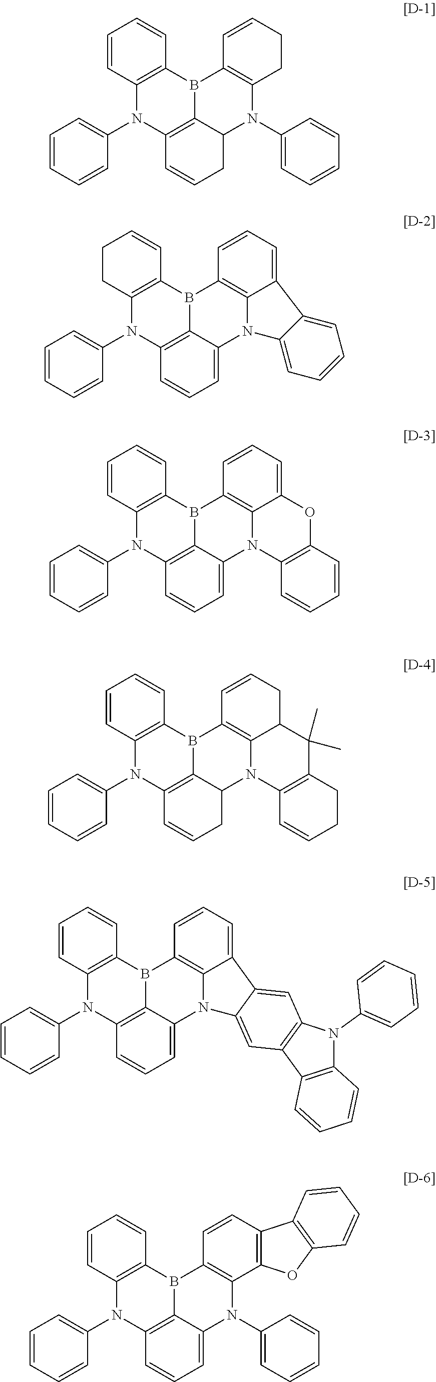 [SMILES: C1=CC2=C(CC1)N(c1ccccc1)C1CC=CC3=C1B2c1ccccc1N3c1ccccc1 ; C1=CC2=C(CC1)N(c1ccccc1)c1cccc3c1B2c1cccc2c4ccccc4n-3c12 ; c1ccc(N2c3ccccc3B3c4cccc5c4N(c4ccccc4O5)c4cccc2c43)cc1 ; CC1(C)C2=C(C=CCC2)N2C3=C(C=CCC31)B1C3=C(C=CCC32)N(c2ccccc2)c2ccccc21 ; c1ccc(N2c3ccccc3B3c4c2cccc4-n2c4cc5c6ccccc6n(-c6ccccc6)c5cc4c4cccc3c42)cc1 ; c1ccc(N2c3ccccc3B3c4ccc5c(oc6ccccc65)c4N(c4ccccc4)c4cccc2c43)cc1]

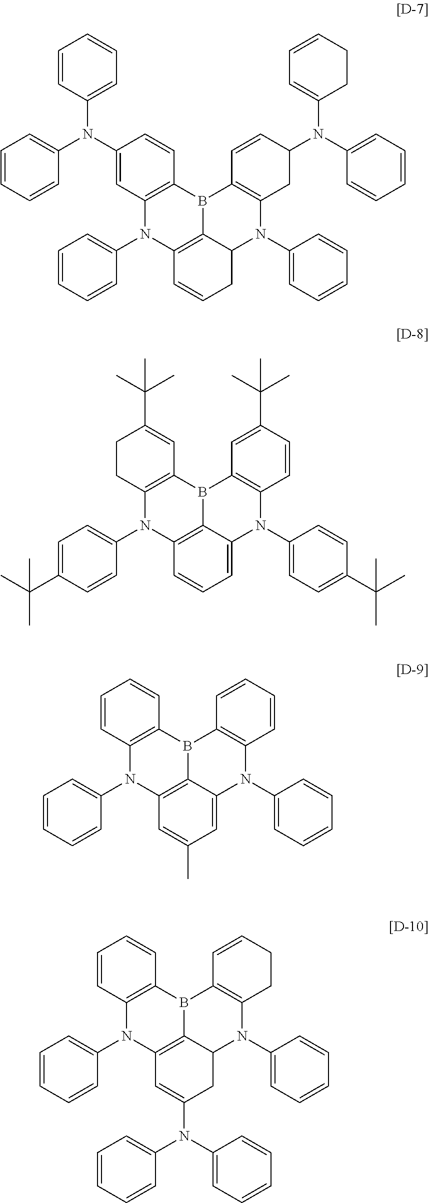 [SMILES: C1=CCCC(N(c2ccccc2)C2C=CC3=C(C2)N(c2ccccc2)C2CC=CC4=C2B3c2ccc(N(c3ccccc3)c3ccccc3)cc2N4c2ccccc2)=C1 ; CC(C)(C)C1=CC2=C(CC1)N(c1ccc(C(C)(C)C)cc1)c1cccc3c1B2c1cc(C(C)(C)C)ccc1N3c1ccc(C(C)(C)C)cc1 ; Cc1cc2c3c(c1)N(c1ccccc1)c1ccccc1B3c1ccccc1N2c1ccccc1 ; C1=CC2=C(CC1)N(c1ccccc1)C1CC(N(c3ccccc3)c3ccccc3)=CC3=C1B2c1ccccc1N3c1ccccc1]

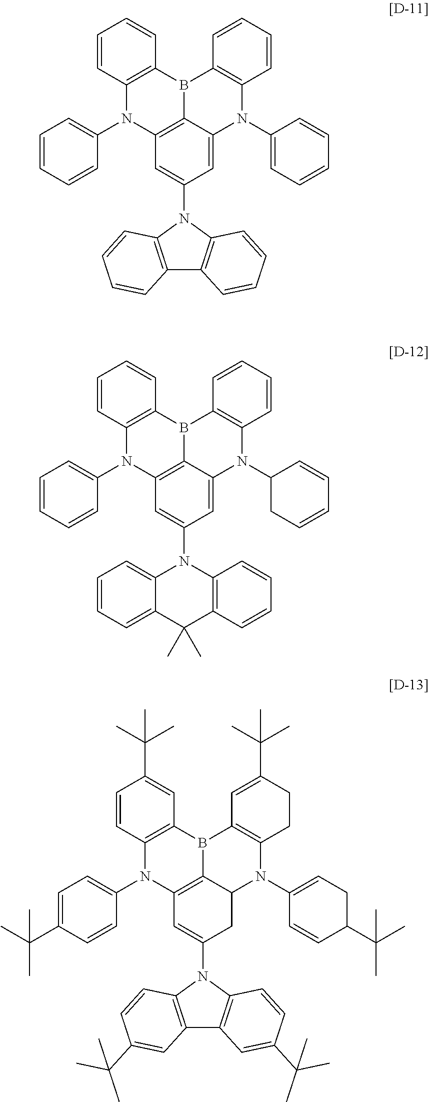 [SMILES: c1ccc(N2c3ccccc3B3c4ccccc4N(c4ccccc4)c4cc(-n5c6ccccc6c6ccccc65)cc2c43)cc1 ; CC1(C)c2ccccc2N(c2cc3c4c(c2)N(C2C=CC=CC2)c2ccccc2B4c2ccccc2N3c2ccccc2)c2ccccc21 ; CC(C)(C)C1=CC2=C(CC1)N(C1=CCC(C(C)(C)C)C=C1)C1CC(n3c4ccc(C(C)(C)C)cc4c4cc(C(C)(C)C)ccc43)=CC3=C1B2c1cc(C(C)(C)C)ccc1N3c1ccc(C(C)(C)C)cc1]

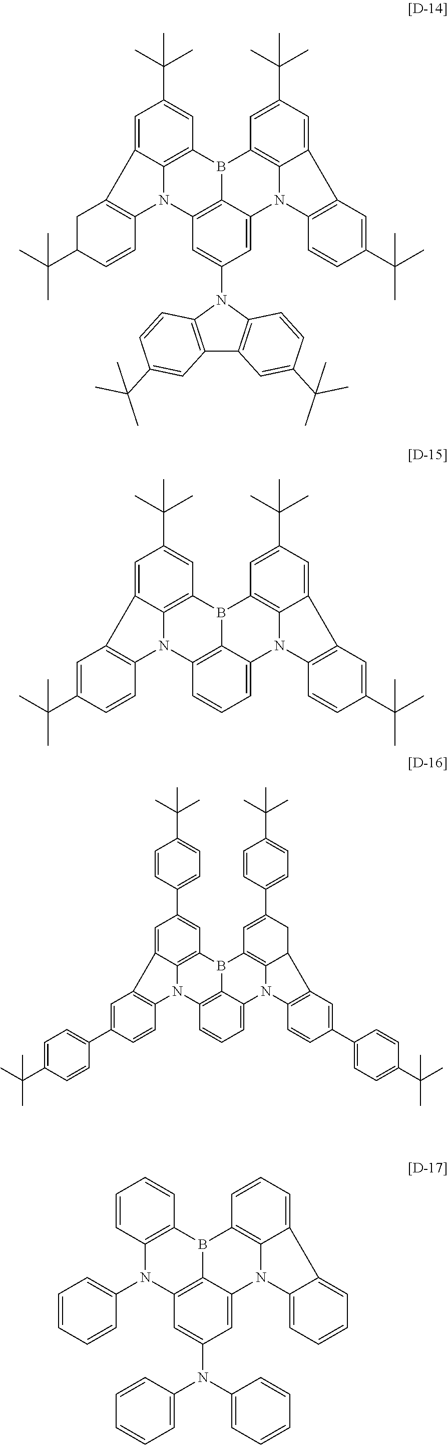

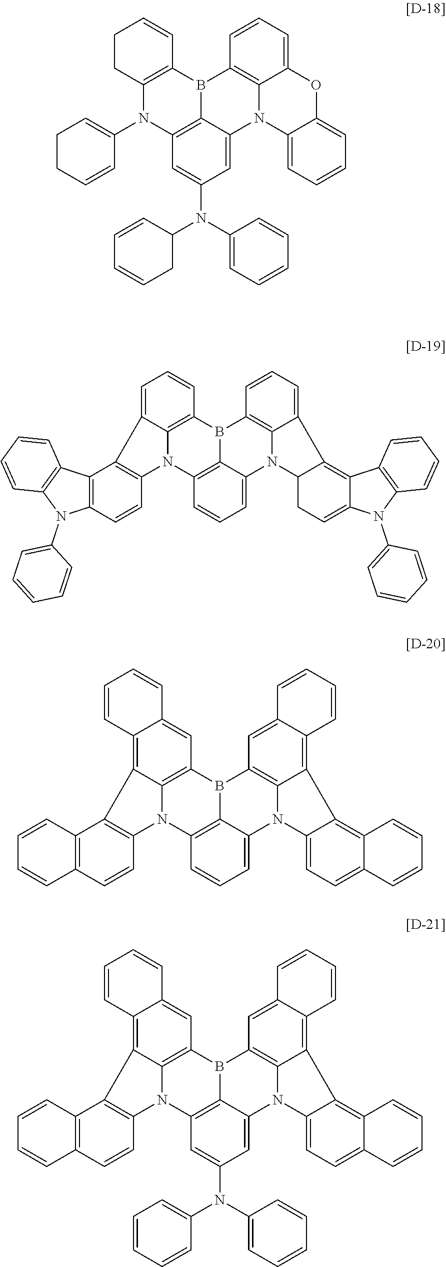 [SMILES: C1=CCC(N(c2ccccc2)c2cc3c4c(c2)N2c5ccccc5Oc5cccc(c52)B4C2=C(CCC=C2)N3C2=CCCC=C2)C=C1 ; C1=c2c(c3ccccc3n2-c2ccccc2)=C2c3cccc4c3N(c3cccc5c3B4c3cccc4c6c7c8ccccc8n(-c8ccccc8)c7ccc6n-5c34)C2C1 ; c1cc2c3c(c1)-n1c4ccc5ccccc5c4c4c5ccccc5cc(c41)B3c1cc3ccccc3c3c4c5ccccc5ccc4n-2c13 ; c1ccc(N(c2ccccc2)c2cc3c4c(c2)-n2c5ccc6ccccc6c5c5c6ccccc6cc(c52)B4c2cc4ccccc4c4c5c6ccccc6ccc5n-3c24)cc1]

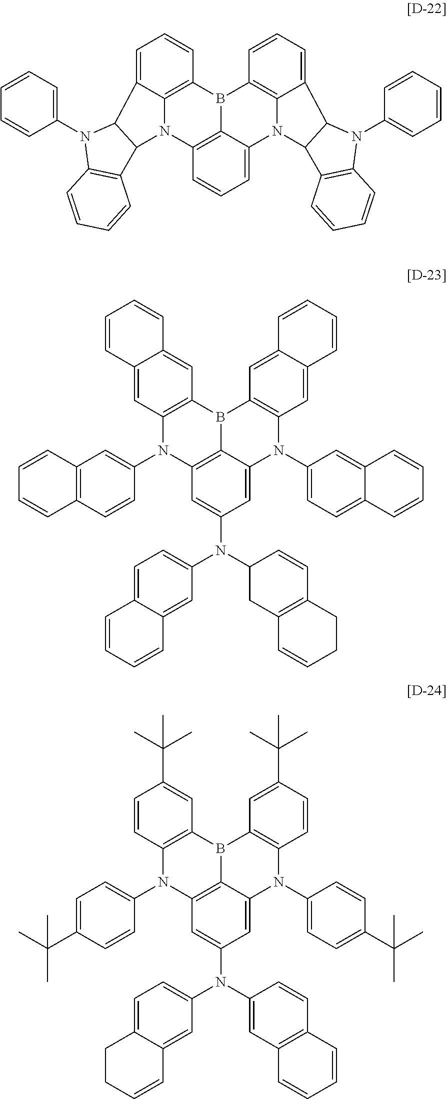 [SMILES: c1ccc(N2c3ccccc3C3C2c2cccc4c2N3c2cccc3c2B4c2cccc4c2N3C2c3ccccc3N(c3ccccc3)C42)cc1 ; C1=CC2=C(C=CC(N(c3cc4c5c(c3)N(c3ccc6ccccc6c3)c3cc6ccccc6cc3B5c3cc5ccccc5cc3N4c3ccc4ccccc4c3)c3ccc4ccccc4c3)C2)CC1 ; CC(C)(C)c1ccc(N2c3ccc(C(C)(C)C)cc3B3c4cc(C(C)(C)C)ccc4N(c4ccc(C(C)(C)C)cc4)c4cc(N(c5ccc6c(c5)C=CCC6)c5ccc6ccccc6c5)cc2c43)cc1]

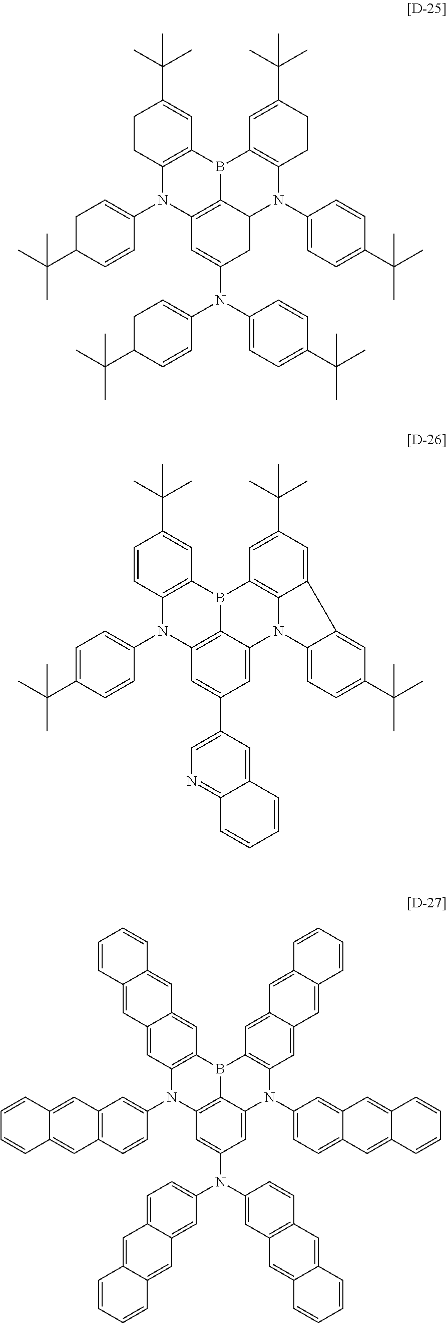

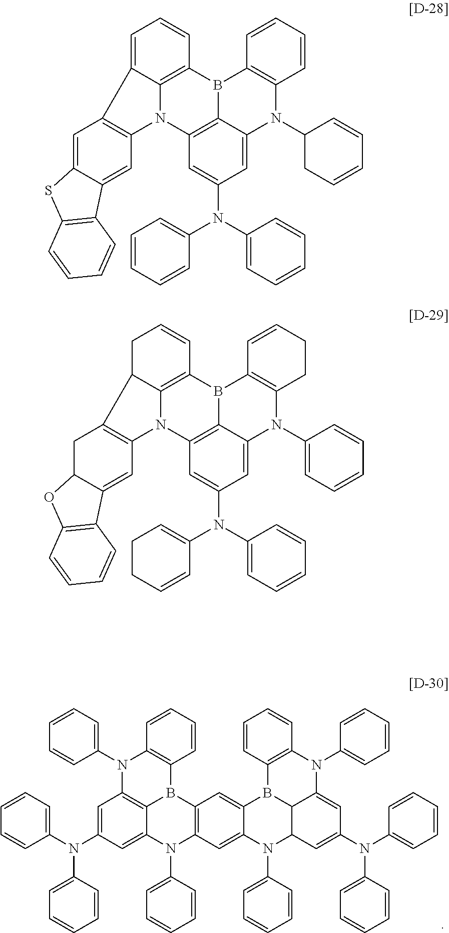

The organic phosphor may include a boron compound represented by Chemical Formula 3 below:

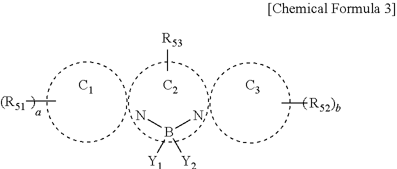

(In Chemical Formula 3 above, C₁ to C₃ each have a five-membered or six-membered ring structure, R₅₁ and R₅₂ each independently correspond to at least any one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted thioether group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, R₅₃ corresponds to any one selected from the group consisting of hydrogen, deuterium, a halogen group, a hydroxyl group, a cyano group, a nitro group, an amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted thioether group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, Y₁ and Y₂ are each independently a fluorine group or an alkoxy group, a and b are each independently an integer of 1 to 4, if a and b are 2 or more, the structures in the brackets, are the same or different, respectively, R₅₁ and R₅₂ may bond to adjacent substituents to form a substituted or unsubstituted ring).

The boron compound represented by Chemical Formula 3 above may be one or more selected from the group consisting of compounds B-1 to B-33 below:

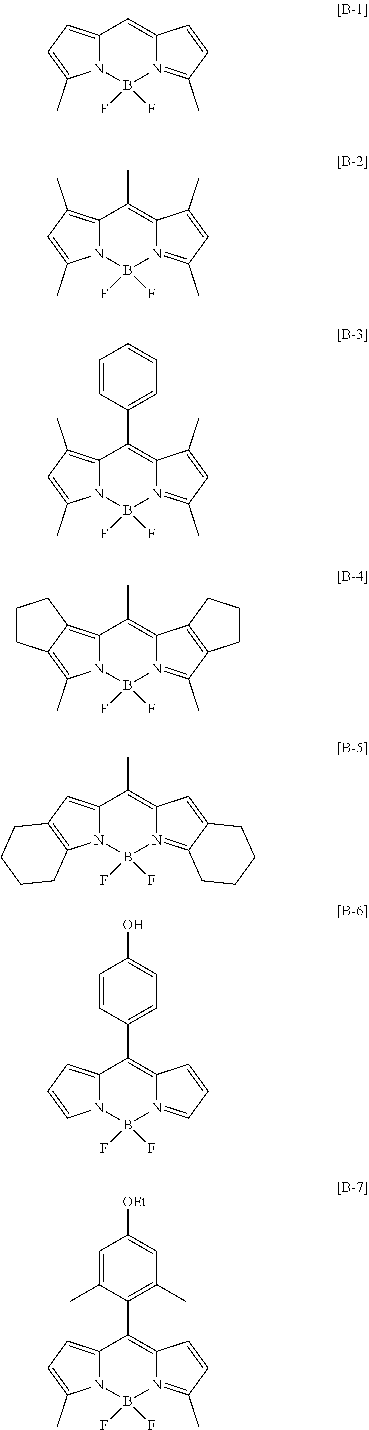

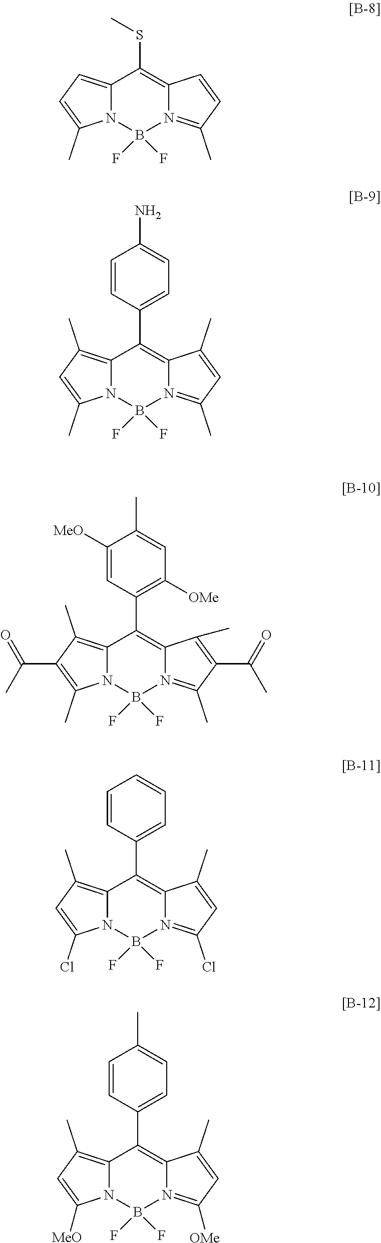

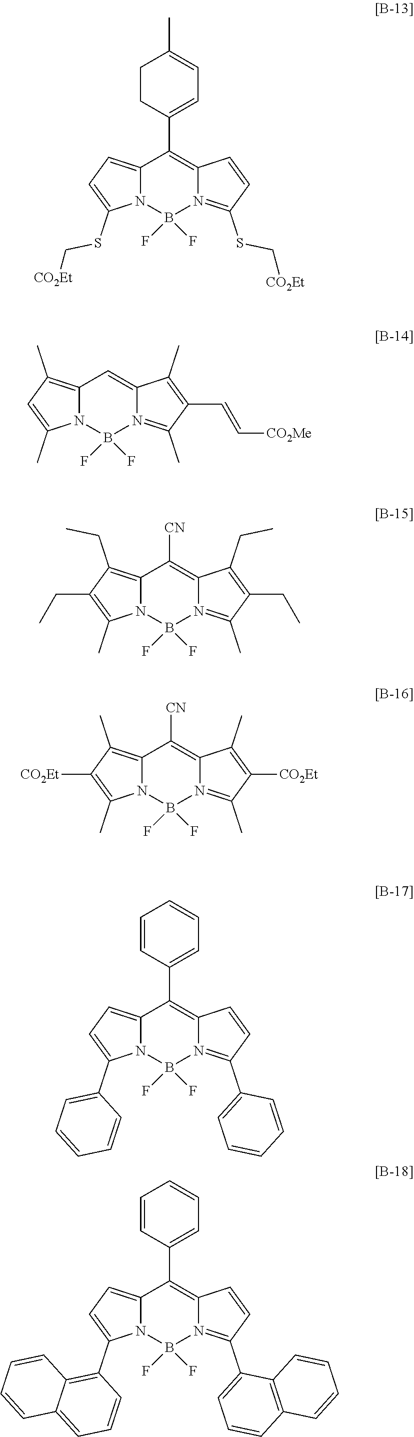

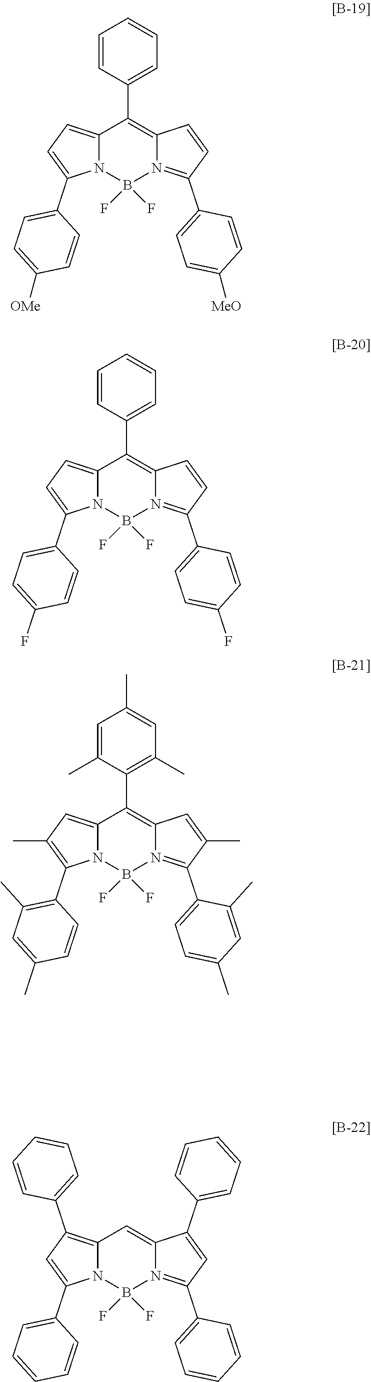

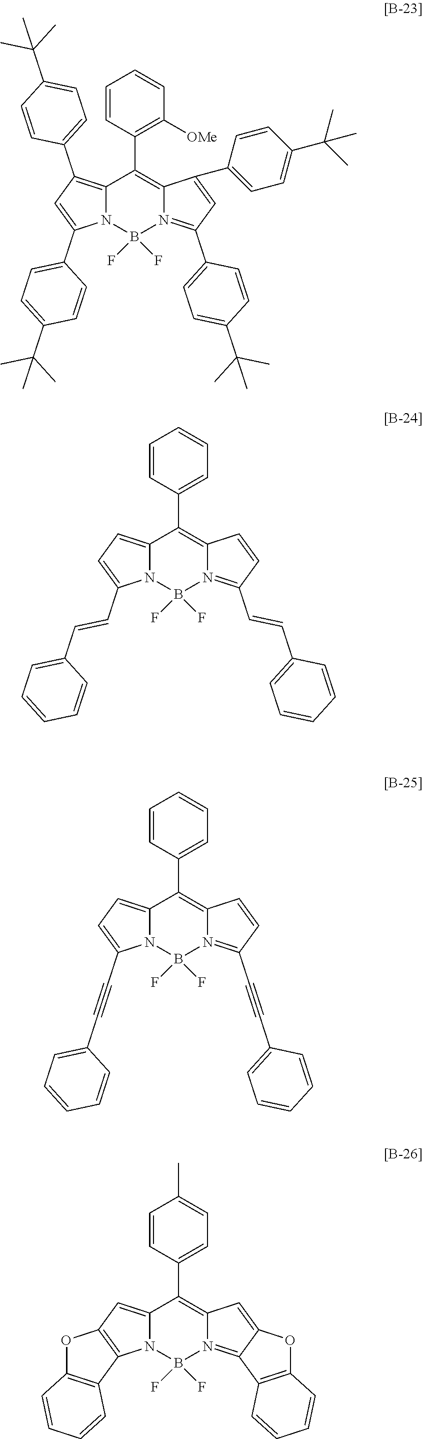

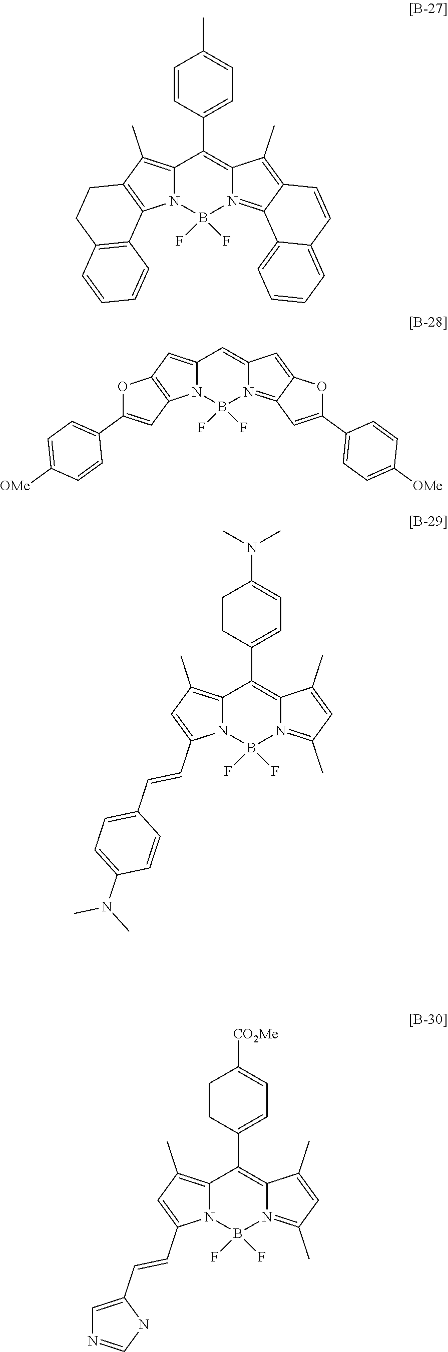

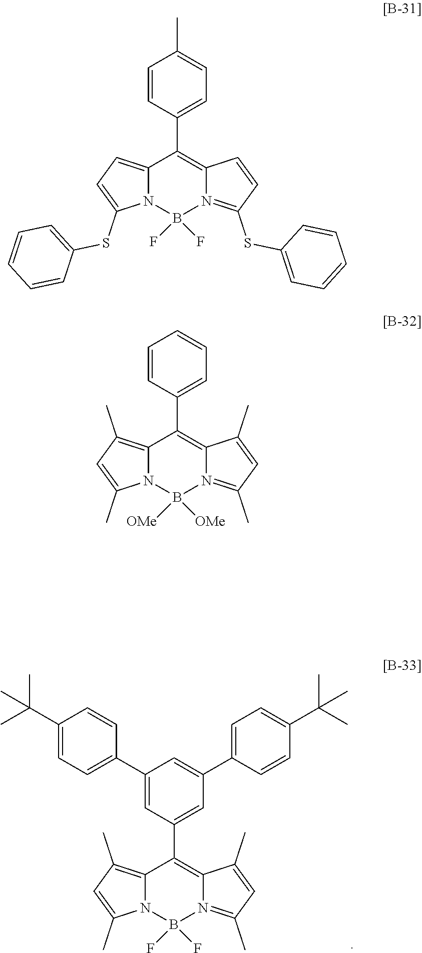

The surfactant may be one or more selected from the group consisting of an anionic surfactant, a cationic surfactant, an amphoteric surfactant, and a nonionic surfactant.

Another aspect of the present invention provides a composition for a color conversion film, including the light-emitting organic nanoparticles and a water-soluble polymer resin.

The composition for a color conversion film may include the 1 to 20 parts by weight of light-emitting organic nanoparticles based on 100 parts by weight of the water-soluble polymer resin.

The composition for a color conversion film may further include a 0.01 to 20 parts by weight of a crosslinking agent based on 100 parts by weight of the water-soluble polymer resin.

The composition for a color conversion film may further include a 1 to 20 parts by weight of a light scattering agent based on 100 parts by weight of the water-soluble polymer resin.

The water-soluble polymer resin may have a weight average molecular weight of 5,000 to 100,000 g/mol and a degree of hydration of 70 to 100%, and may be at least one polymer or copolymer selected from the group consisting of a nonionic water-soluble polymer, an anionic water-soluble polymer, and a cationic water-soluble polymer.

The nonionic water-soluble polymer may be one or more polymers or copolymers selected from the group consisting of polyvinyl alcohol (PVA), polyethylene oxide (PEO), polyacrylamide (PAM), and polyvinylpyrrolidone (PVP).

The anionic water-soluble polymer may be one or more polymers or copolymers selected from the group consisting of polyacrylic acid (PAA) and its derivatives, poly(styrene sulfonic acid) (PSSA), poly(silicic acid) (PSiA), poly(phosphoric acid) (PPA), poly(ethylenesulfinic acid) (PESA), poly[3-(vinyloxy)propane-1-sulfonic acid], poly(4-vinylphenol), poly(4-vinylphenol sulfuric acid), poly(ethylenephosphoric acid), poly(maleic acid), poly(2-methacryloxyethane-1-sulfonic acid), poly(3-methacryloyloxypropane-1-sulfonic acid) and poly(4-vinylbenzoic acid).

The cationic water-soluble polymer may be one or more polymers or copolymers selected from the group consisting of polyethyleneimine (PEI), polyamines, polyamideamine (PAMAM), poly(diallyldimethyl ammonium chloride) (PDADMAC), poly(4-vinylbenzyltrimethylammonium salt), poly[(dimethylimino)trimethylene(dimethylimino)hexamethylenedibromide] (polybrene), poly(2-vinylpiperidine salt), poly(vinylamine salt), and poly(2-vinylpyridine) and derivatives thereof.

The crosslinking agent may be one or more selected from the group consisting of glutaraldehyde, glyoxal, maleic acid, citric acid, trisodium trimetaphosphate, sodium hexametaphosphate, dianhydrides, succinic acid, suberic acid, sulfosuccinic acid, and K₂S₂O₈.

The light scattering agent may be one or more types of inorganic oxide particles selected from the group consisting of TiO₂, ZnO, Fe₃O₄, CeO₂, MoO₂, Ag₂O, CuO, and NiO.

The inorganic metal oxide particles may have an average particle size of 200 to 400 nm.

Still another aspect of the present invention provides a color conversion manufactured using the composition for a color conversion film.

Yet another aspect of the present invention provides a display device or a light-emitting diode device including the color conversion film.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 shows the ¹H-NMR data of Ttrz-DI;

FIG. 2A shows the ultraviolet-visible spectroscopy (UV-Vis) and room temperature photoluminescence (RTPL) and low temperature photoluminescence (LTPL) spectra of Ttrz-DI in toluene, and FIG. 2B shows the time resolved photoluminescence (TRPL) of Ttrz-DI in a solvent;

FIG. 3A is a graph showing the sizes and emission wavelengths of particles that vary depending on a state of Ttrz-DI when Triton X-100 is used as a surfactant, and FIG. 3B is a graph showing the sizes and emission wavelengths of particles that vary depending on a state of Ttrz-DI when TBAOleate is used as a surfactant;

FIG. 4A shows the results of measuring transparency after leaving a base film according to Manufacturing Example 2-2 at each of room temperature (25° C.), 130° C., 180° C., and 200° C. for 1 hour, and FIG. 4B is a photograph of a base film according to Manufacturing Example 2-2 after the base film was left at a temperature of 200° C. for 1 hour;

FIG. 5A is a photograph of a base film according to Manufacturing Example 2-1 after measuring the pencil hardness of the base film, and FIG. 5B is a photograph of a base film according to Comparative Manufacturing Example 2-1 after measuring the pencil hardness of the base film;

FIG. 6 shows a method of calculating the optical properties and color conversion efficiency (CCE) of a color conversion film of Manufacturing Example 3-1;

FIG. 7 is a graph showing the results of light resistance evaluation after exposing the color conversion films of Manufacturing Example 3-1 and Comparative Manufacturing Example 3-2 to UV for 120 hours;

FIG. 8 is a graph showing the emission intensity according to wavelength of color conversion films of Manufacturing Examples 4-1 to 4-4;

FIGS. 9A to 9E are graphs showing the radiant power according to wavelength of color conversion films of Manufacturing Examples 4-1 to 4-4;

FIG. 10 is a graph showing the absorbance of color conversion films of Manufacturing Examples 4-4 to 4-6;

FIGS. 11A to 11D are graphs showing the radiant power of films made of a single layer of the respective color conversion films of Manufacturing Examples 4-4 to 4-6;

FIG. 12 is a graph showing the radiant power of films manufactured by laminating two color conversion films of Manufacturing Examples 4-4 to 4-6;

FIGS. 13A to 13C are graphs showing the absorbance of color conversion films of Reference Examples 1 to 3;

FIG. 14 is a graph showing the photoluminescence intensity of the color conversion films of Reference Examples 1 to 3;

FIGS. 15A to 15D are graphs showing the radiant intensity of the color conversion films of Reference Examples 1 to 3;

FIG. 16 is a graph showing the radiant power of a color conversion film of Manufacturing Example 4-5;

FIGS. 17A to 17C are graphs showing the results of constant temperature and humidity evaluation for the color conversion film of Reference Example 2;

FIG. 18 is a graph showing the results of constant temperature and humidity evaluation for the color conversion film of Manufacturing Example 4-5;

FIGS. 19A to 19C are graphs showing the results of light resistance evaluation for the color conversion film of Reference Example 2;

FIGS. 20A to 20C are graphs showing the results of light resistance evaluation for the color conversion film of Manufacturing Example 4-5;

FIG. 21 is a graph showing the absorbance of color conversion films of Manufacturing Examples 5-1 to 5-4;

FIGS. 22A to 22F are graphs showing the radiant power of films made of a single layer of the respective color conversion films of Manufacturing Examples 5-1 to 5-5; and

FIGS. 23A to 23C are graphs showing the radiant power of films manufactured by laminating two color conversion films of Manufacturing Examples 5-4 and 5-5.

### DETAILED DESCRIPTION OF EXEMPLARY EMBODIMENTS

Prior to the detailed description of the present invention, terms and words used in this specification and claims should not be interpreted as limited to commonly used meanings or meanings in dictionaries and should be interpreted with meanings and concepts which are consistent with the technological scope of the invention based on the principle that the inventors have appropriately defined concepts of terms in order to describe the invention in the best way. Therefore, since the embodiments described in this specification and configurations illustrated in drawings are only exemplary embodiments and do not represent the overall technological scope of the invention, it should be understood that the invention covers various equivalents, modifications, and substitutions at the time of filing of this application.

Throughout this specification, when a certain part “includes” a certain component, it means that another component may be further included, not excluding the other component unless otherwise stated. Further, throughout this specification, the singular forms include the plural forms unless the context clearly indicates otherwise.

When ranges of numerical values are set forth herein, the values have the precision of significant digits provided according to the standard rules in chemistry for significant digits unless a specific range is stated otherwise. For example, the number 10 includes a range 5.0 to 14.9, and the number 10.0 includes a range 9.50 to 10.49.

### Light-Emitting Organic Nanoparticles

According to one aspect of the present invention, light-emitting organic nanoparticles containing an organic phosphor having a luminous efficiency of 80% or more are provided.

An average particle size of the light-emitting organic nanoparticles may be 100 to 170 nm, preferably, 110 to 160 nm, and more preferably, 120 to 150 nm.

A standard deviation of the particle sizes of the light-emitting organic nanoparticles may be 500 nm or less, preferably, 450 nm or less, more preferably, 400 nm or less, furthermore preferably, 350 nm or less, furthermore preferably, 300 nm or less, and most preferably, 280 nm or less.

A color conversion film using the light-emitting organic nanoparticles having the average particle size and the standard deviation of the particle sizes within the ranges described above has excellent color conversion efficiency (CCE), ultraviolet (UV) stability, room temperature stability, and the like.

### Organic Phosphor

The organic phosphor may be at least one selected from the group consisting of a green phosphor, a blue phosphor, and a red phosphor, and various phosphors having a luminous efficiency of 80% or more that are already known in the art to which the present invention pertains may be used as the organic phosphor.

In the case of applying the light-emitting organic nanoparticles to the use of a light-emitting diode (LED), the light-emitting organic nanoparticles should have a wide full width at half maximum (FWHM), and thus it is preferable to use a delayed fluorescence material.

The delayed fluorescence material is a material capable of increasing internal quantum efficiency, and it is preferable to use a thermally activated delayed fluorescence (TADF) material, which is a material that emits fluorescence by moving particles of three triplet excitons, which are particles that are annihilated by heat or vibration, to a level of a singlet exciton using heat.

The delayed fluorescence material having such properties is not particularly limited, and for example, a compound represented by Chemical Formula 1 below may be used.

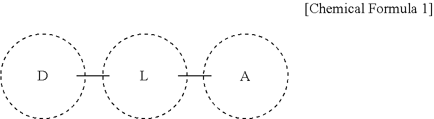

(In Chemical Formula 1 above, L is any one selected from the group consisting of an aryl group, an arylene group, and a carbon-nitrogen single bond, when L is an aryl group, A is a cyano group mono- or di-substituted on the aryl group, and D is a substituent tetra- or penta-substituted on the aryl group, wherein each substituent is independently a heteroaryl group containing a nitrogen atom substituted or unsubstituted with a heteroaryl group having 1 to 10 carbon atoms, when L is an arylene group, A is a substituted or unsubstituted triazine group, and D is a substituted or unsubstituted multi-fused ring, including a conjugated or non-conjugated five-membered or six-membered ring containing a nitrogen atom bonded to the arylene group, wherein the multi-fused ring may further comprise 1 to 9 nitrogen atoms or one Group 16 element as ring-forming elements, in addition to the nitrogen atom boned to the arylene group, when L is a carbon-nitrogen single bond, D is a fused ring having 10 to 40 carbon atoms, including a conjugated or non-conjugated five-membered or six-membered ring containing the nitrogen atom of the L, wherein the conjugated or non-conjugated five-membered or six-membered ring is a substituted or unsubstituted ring, does not contain or contains a Group 16 element as ring-forming elements, and contains 1 or 2 nitrogen atoms as ring-forming elements, and A is a heterocyclic ring having 10 to 40 carbon atoms, including an aryl group containing a carbon atom bonded to the L, wherein the heterocyclic ring includes a ring structure forming a fused ring with the aryl group containing a carbon atom bonded to the L, and wherein the ring structure is a ring structure containing a boron atom and an oxygen atom as ring-forming elements, or is a five-membered or six-membered ring structure containing two conjugated nitrogen atoms).

The compound represented by Chemical Formula 1 above may be represented by, e.g., one of Chemical Formula 1A to Chemical Formula 1D below:

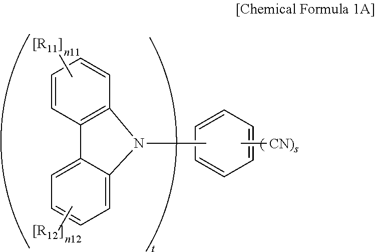

(in Chemical Formula 1A, R₁₁ and R₁₂ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, s is an integer of 1 or 2, t is an integer of 4 or 5, n11 and n12 are each independently an integer of 1 to 4, and if n11 and n12 are 2 or more, the structures in the brackets, are the same or different, respectively, R₁₁ and R₁₂ may bond to adjacent substituents to form a substituted or unsubstituted ring).

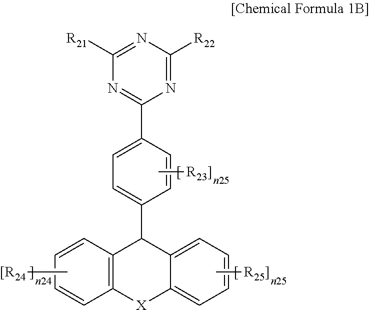

(in Chemical Formula 1B, X is a single bond, CR₂₆R₂₇, NR₂₈, O or S, R₂₁ to R₂₈ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, n23 to n25 are each independently an integer of 1 to 4, if n23 to n25 are 2 or more, the structures in the brackets, are the same or different, respectively, and R₂₃ to R₂₈ may bond to adjacent substituents to form a substituted or unsubstituted ring).

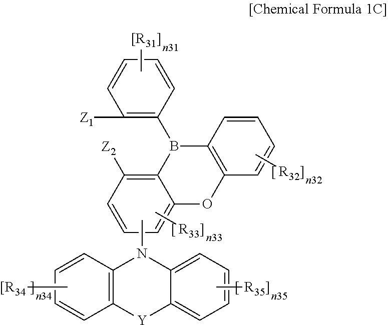

(in Chemical Formula 1C, Y is a single bond, CR₃₆R₃₇, NR₃₈, O or S, R₃₁ to R₃₈ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, Z₁ and Z₂ each independently correspond to at least one selected from the group consisting of hydrogen, a hydroxyl group, and a substituted or unsubstituted alkyl group, or are combined with each other to form a ring, n31, n32, n34 and n35 are each independently an integer of 1 to 4, n33 is an integer of 1 to 2, if n31 to n35 are 2 or more, the structures in the brackets, are the same or different, respectively, and R₃₁ to R₃₈ may bond to adjacent substituents to form a substituted or unsubstituted ring).

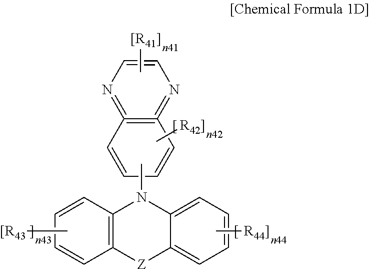

(in Chemical Formula 1D, Z is a single bond, CR₄₅R₄₆, NR₄₇, O or S, R₄₁ to R₄₇ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, n41 is an integer of 1 to 2, n42 is an integer of 1 to 3, n43 and n44 are each independently an integer of 1 to 4, if n41 to n44 are 2 or more, the structures in the brackets, are the same or different, respectively, and R₄₁ to R₄₇ may bond to adjacent substituents to form a substituted or unsubstituted ring).

The compound represented by Chemical Formula 1 above may be, for example, one or more selected from the group consisting of compounds T-1 to T-28 below, but the present invention is not limited thereto.

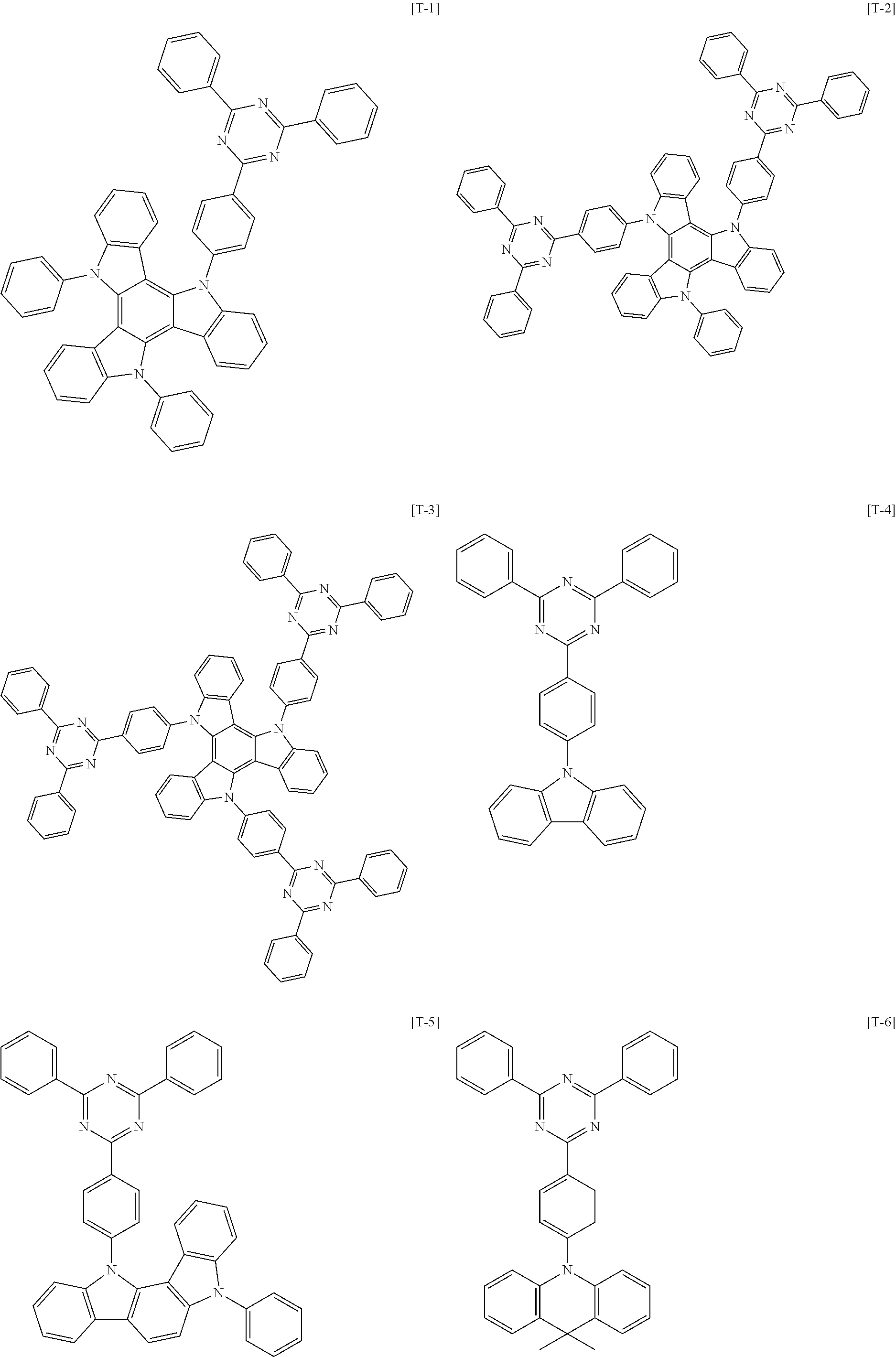

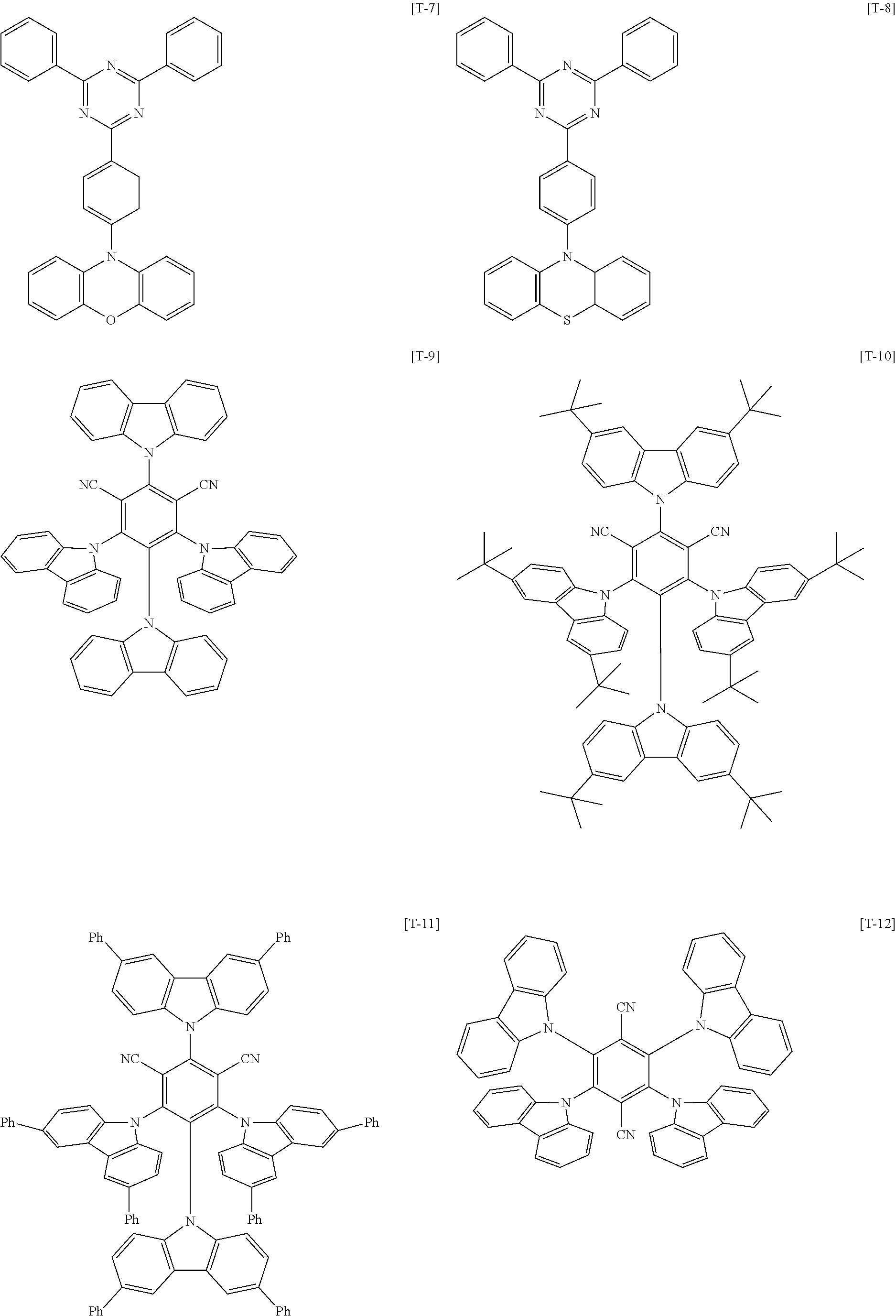

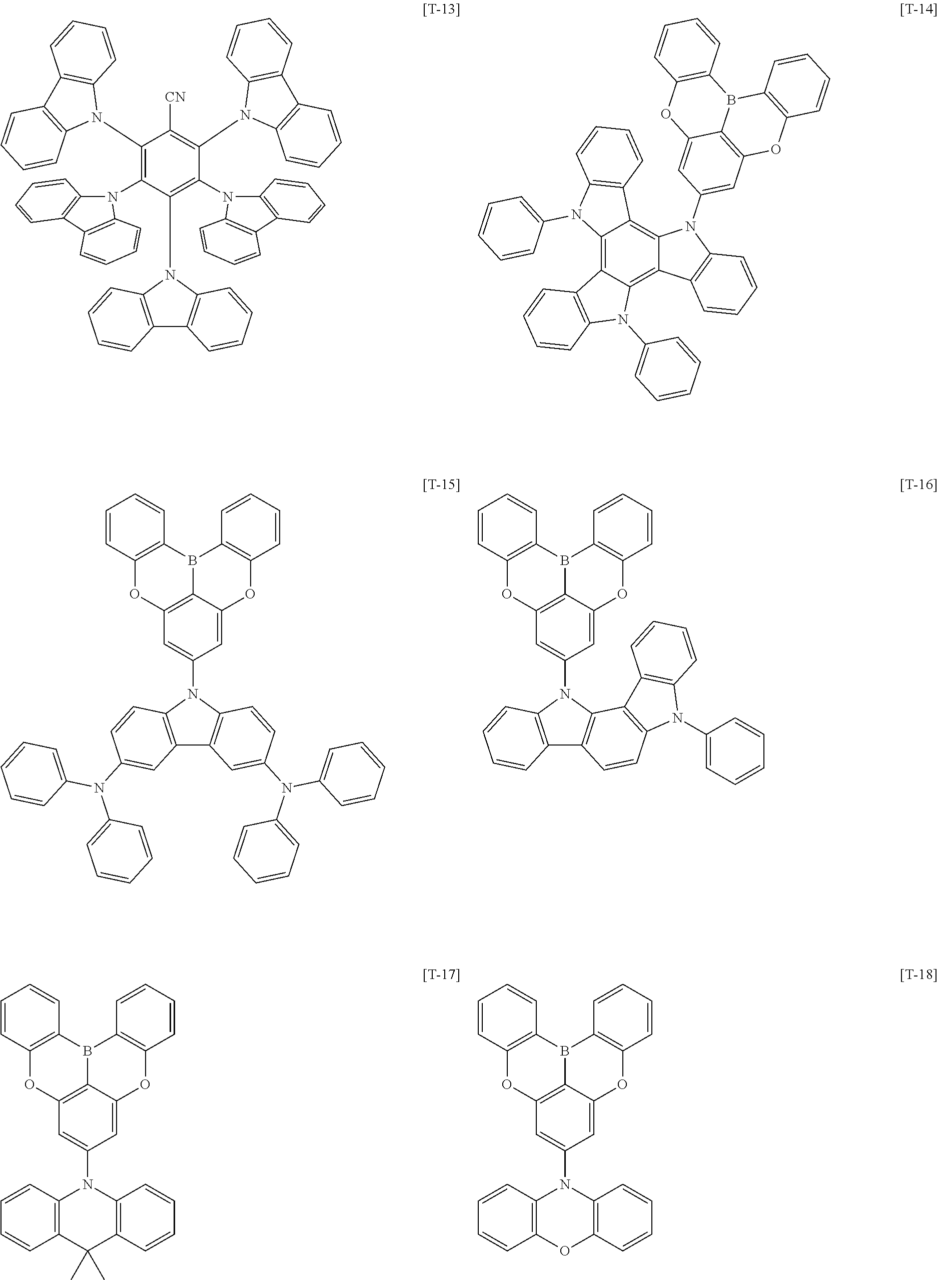

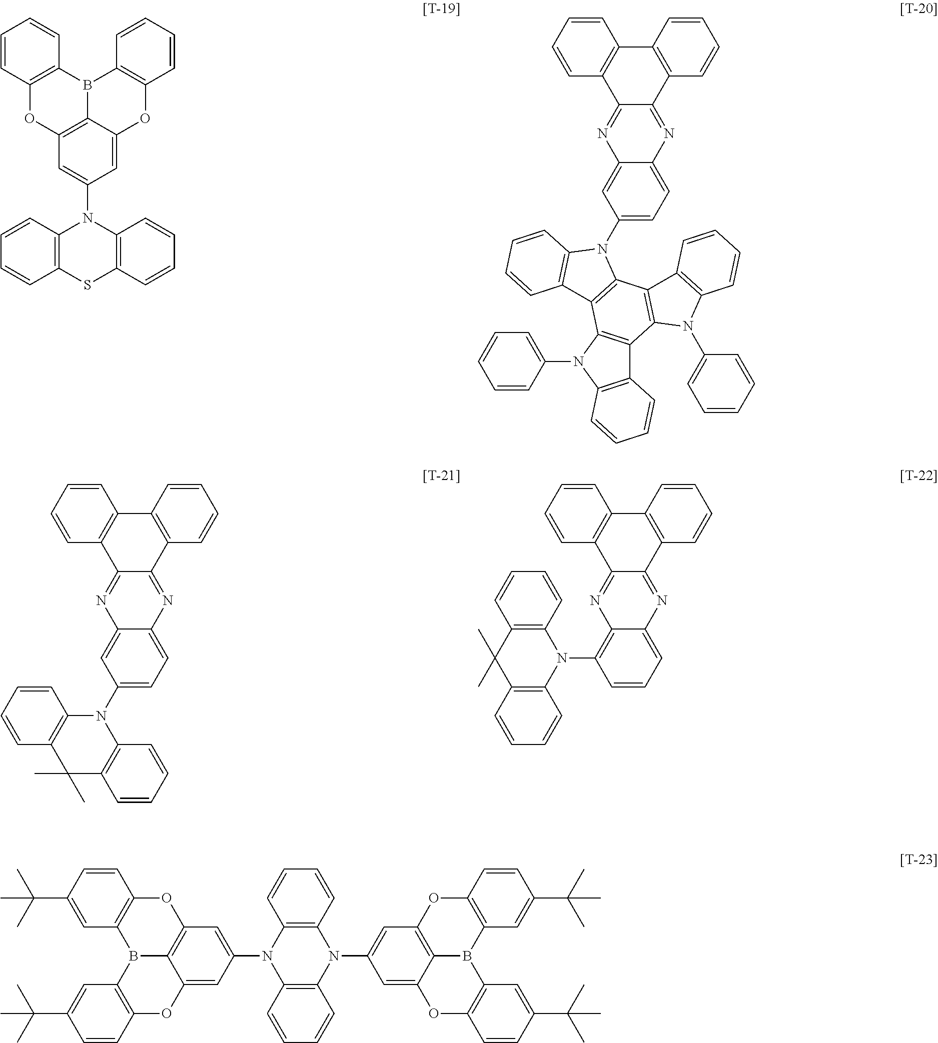

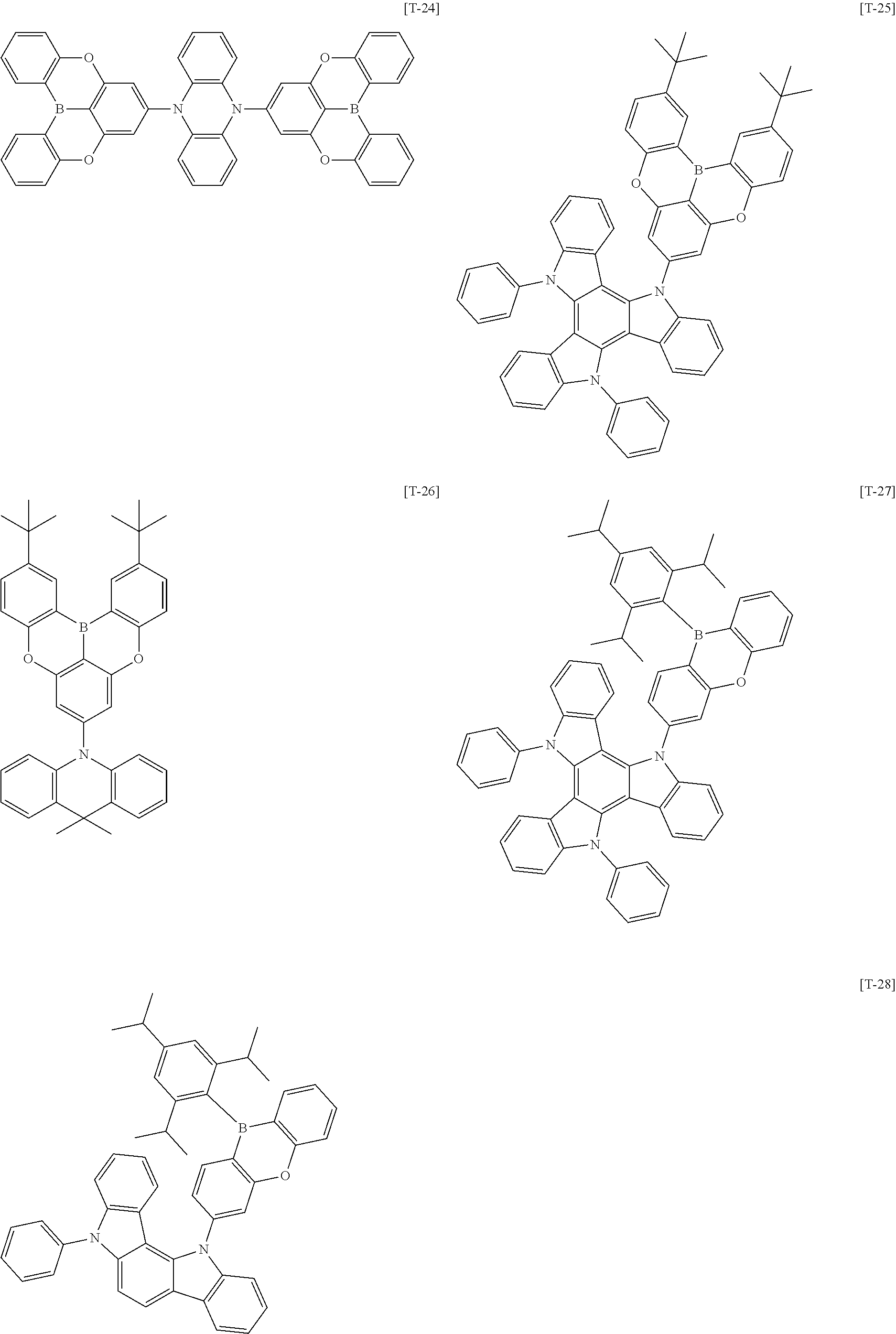

In the case of applying the light-emitting organic nanoparticles for use in a display, it is preferable to use a boron compound having a narrow FWHM for high color purity.

A boron compound suitable for use in a display is not particularly limited, and may be, for example, a boron compound represented by Chemical Formula 2 below.

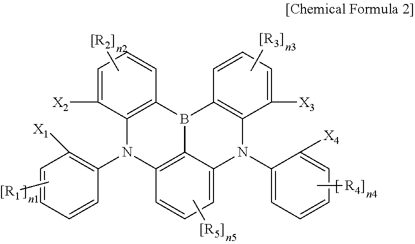

(In Chemical Formula 2 above, R₁ to R₅ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, X₁ to X₄ are each independently hydrogen, hydroxyl group or a substituted or unsubstituted alkyl group, n1 and n4 are each independently an integer of 1 to 4, n2, n3 and n5 are each independently an integer of 1 to 3, if n1 to n5 are 2 or more, the structures in the brackets, are the same or different, respectively, and R₁ to R₅ and X₁ to X₄ may bond to adjacent substituents to form a substituted or unsubstituted ring).

The boron compound represented by Chemical Formula 2 above may be, for example, one or more selected from the group consisting of compounds D-1 to D-30 below, but the present invention is not limited thereto.

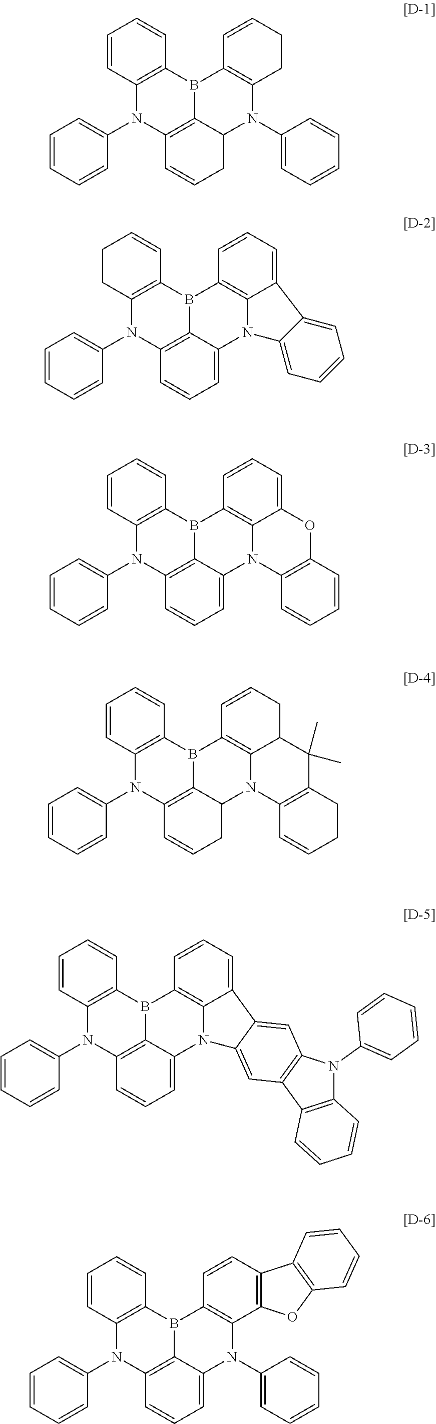 [SMILES: C1=CC2=C(CC1)N(c1ccccc1)C1CC=CC3=C1B2c1ccccc1N3c1ccccc1 ; C1=CC2=C(CC1)N(c1ccccc1)c1cccc3c1B2c1cccc2c4ccccc4n-3c12 ; c1ccc(N2c3ccccc3B3c4cccc5c4N(c4ccccc4O5)c4cccc2c43)cc1 ; CC1(C)C2=C(C=CCC2)N2C3=C(C=CCC31)B1C3=C(C=CCC32)N(c2ccccc2)c2ccccc21 ; c1ccc(N2c3ccccc3B3c4c2cccc4-n2c4cc5c6ccccc6n(-c6ccccc6)c5cc4c4cccc3c42)cc1 ; c1ccc(N2c3ccccc3B3c4ccc5c(oc6ccccc65)c4N(c4ccccc4)c4cccc2c43)cc1]

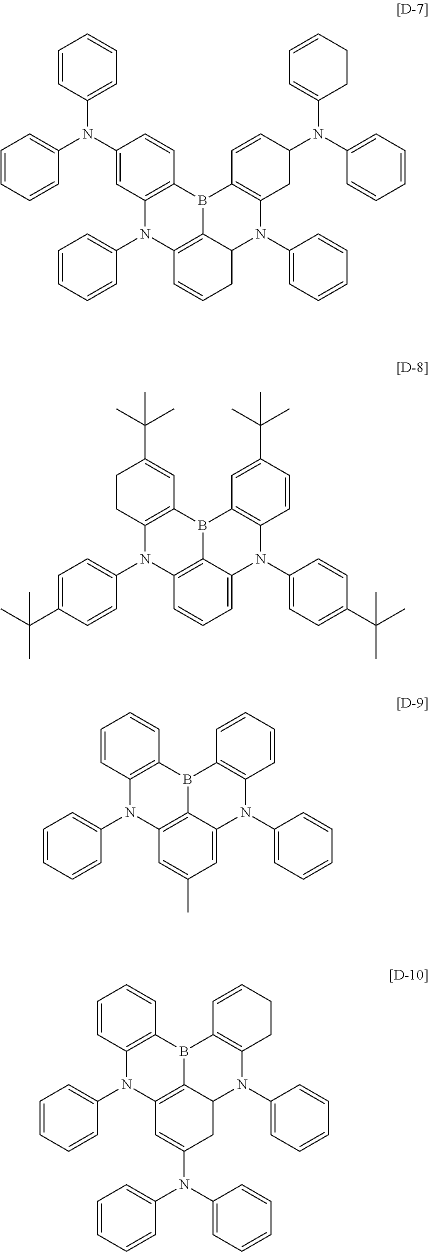 [SMILES: C1=CCCC(N(c2ccccc2)C2C=CC3=C(C2)N(c2ccccc2)C2CC=CC4=C2B3c2ccc(N(c3ccccc3)c3ccccc3)cc2N4c2ccccc2)=C1 ; CC(C)(C)C1=CC2=C(CC1)N(c1ccc(C(C)(C)C)cc1)c1cccc3c1B2c1cc(C(C)(C)C)ccc1N3c1ccc(C(C)(C)C)cc1 ; Cc1cc2c3c(c1)N(c1ccccc1)c1ccccc1B3c1ccccc1N2c1ccccc1 ; C1=CC2=C(CC1)N(c1ccccc1)C1CC(N(c3ccccc3)c3ccccc3)=CC3=C1B2c1ccccc1N3c1ccccc1]

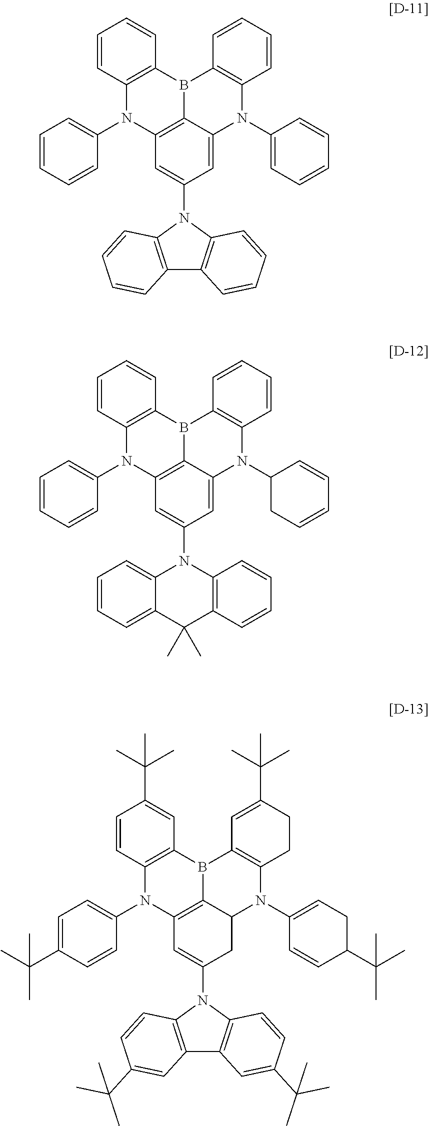 [SMILES: c1ccc(N2c3ccccc3B3c4ccccc4N(c4ccccc4)c4cc(-n5c6ccccc6c6ccccc65)cc2c43)cc1 ; CC1(C)c2ccccc2N(c2cc3c4c(c2)N(C2C=CC=CC2)c2ccccc2B4c2ccccc2N3c2ccccc2)c2ccccc21 ; CC(C)(C)C1=CC2=C(CC1)N(C1=CCC(C(C)(C)C)C=C1)C1CC(n3c4ccc(C(C)(C)C)cc4c4cc(C(C)(C)C)ccc43)=CC3=C1B2c1cc(C(C)(C)C)ccc1N3c1ccc(C(C)(C)C)cc1]

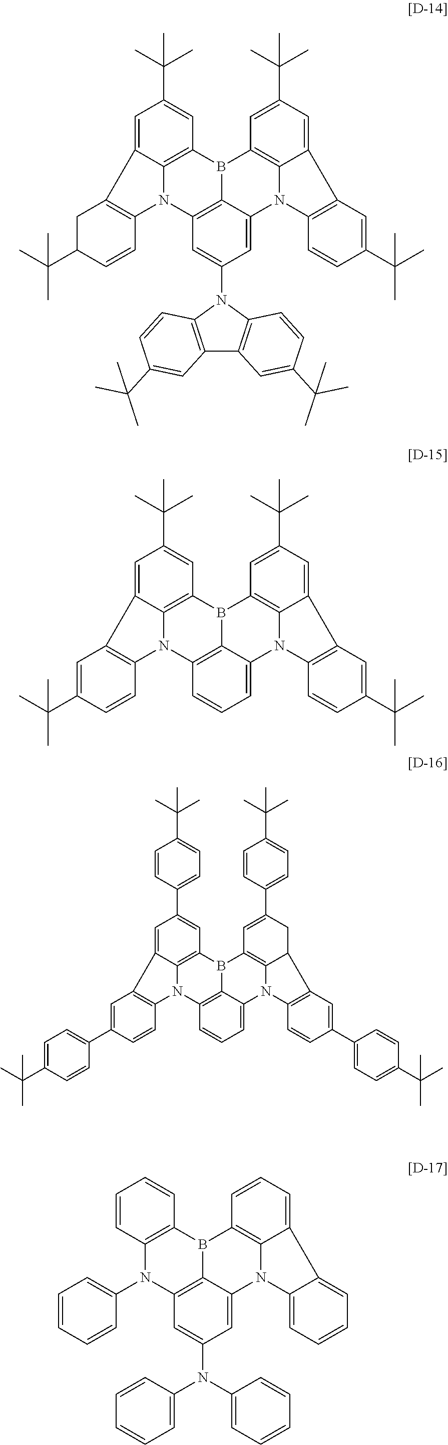

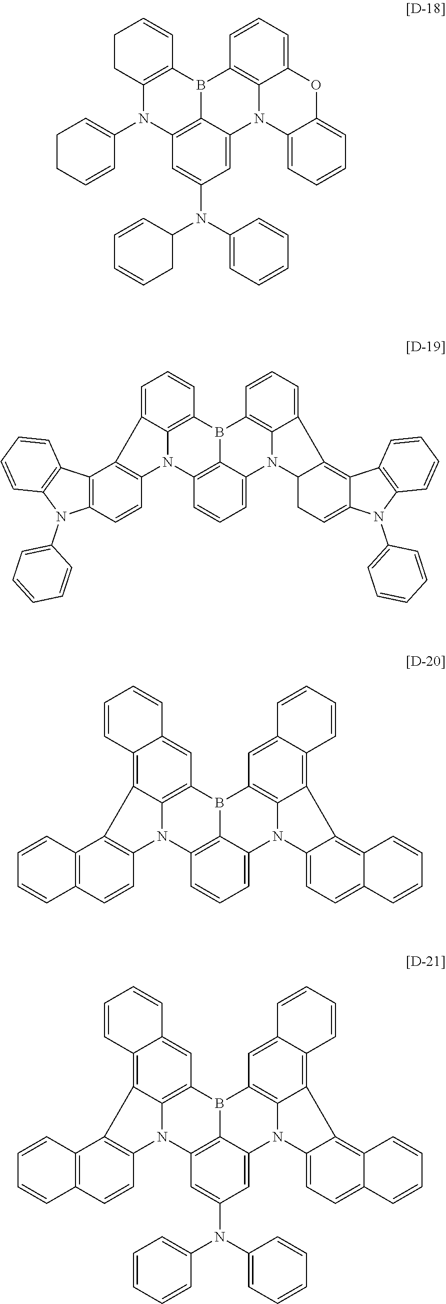 [SMILES: C1=CCC(N(c2ccccc2)c2cc3c4c(c2)N2c5ccccc5Oc5cccc(c52)B4C2=C(CCC=C2)N3C2=CCCC=C2)C=C1 ; C1=c2c(c3ccccc3n2-c2ccccc2)=C2c3cccc4c3N(c3cccc5c3B4c3cccc4c6c7c8ccccc8n(-c8ccccc8)c7ccc6n-5c34)C2C1 ; c1cc2c3c(c1)-n1c4ccc5ccccc5c4c4c5ccccc5cc(c41)B3c1cc3ccccc3c3c4c5ccccc5ccc4n-2c13 ; c1ccc(N(c2ccccc2)c2cc3c4c(c2)-n2c5ccc6ccccc6c5c5c6ccccc6cc(c52)B4c2cc4ccccc4c4c5c6ccccc6ccc5n-3c24)cc1]

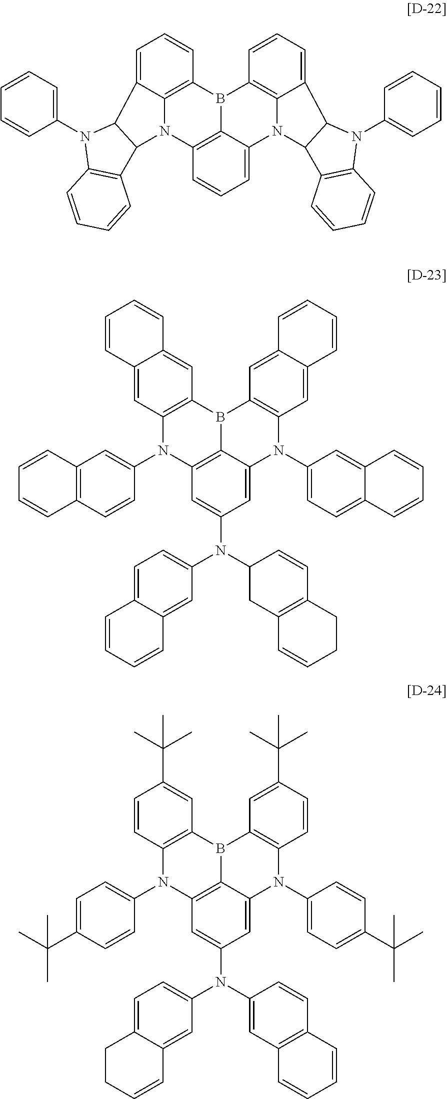 [SMILES: c1ccc(N2c3ccccc3C3C2c2cccc4c2N3c2cccc3c2B4c2cccc4c2N3C2c3ccccc3N(c3ccccc3)C42)cc1 ; C1=CC2=C(C=CC(N(c3cc4c5c(c3)N(c3ccc6ccccc6c3)c3cc6ccccc6cc3B5c3cc5ccccc5cc3N4c3ccc4ccccc4c3)c3ccc4ccccc4c3)C2)CC1 ; CC(C)(C)c1ccc(N2c3ccc(C(C)(C)C)cc3B3c4cc(C(C)(C)C)ccc4N(c4ccc(C(C)(C)C)cc4)c4cc(N(c5ccc6c(c5)C=CCC6)c5ccc6ccccc6c5)cc2c43)cc1]

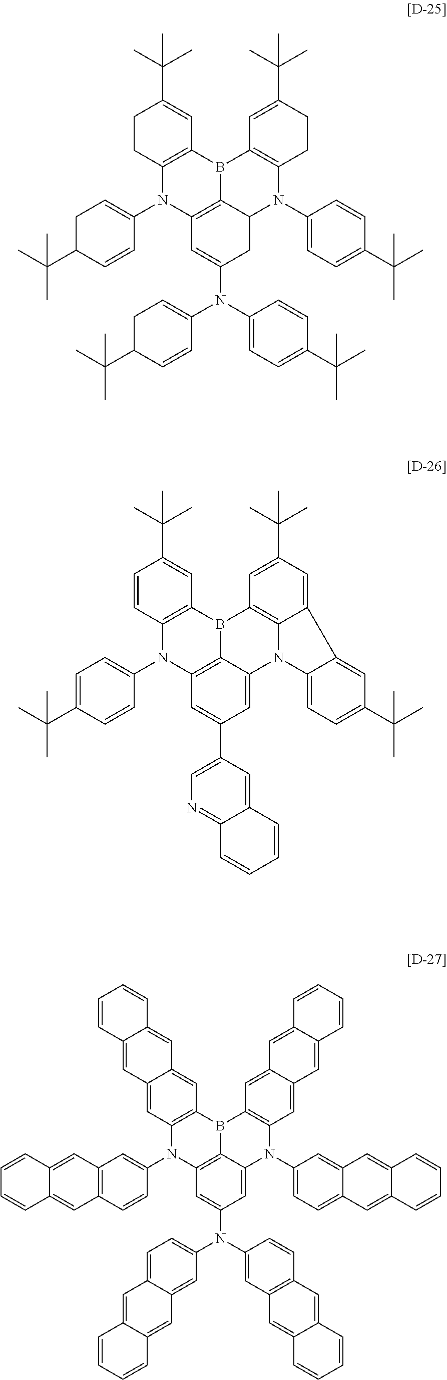

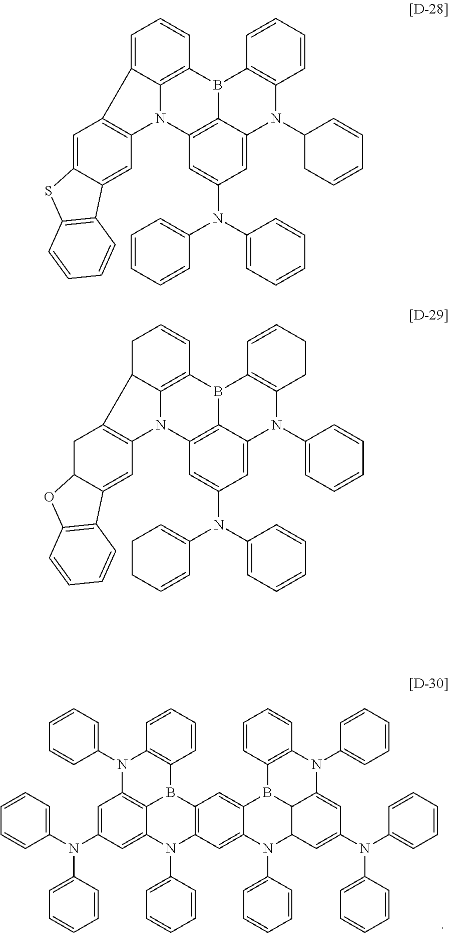

Further, a boron compound suitable for use in a display may be, for example, a boron compound represented by Chemical Formula 3 below.

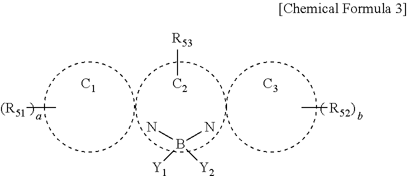

(In Chemical Formula 3 above, C₁ to C₃ each have a five-membered or six-membered ring structure, R₅₁ and R₅₂ each independently correspond to at least any one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted thioether group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, R₅₃ corresponds to any one selected from the group consisting of hydrogen, deuterium, a halogen group, a hydroxyl group, a cyano group, a nitro group, an amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted thioether group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, Y₁ and Y₂ are each independently a fluorine group or an alkoxy group, a and b are each independently an integer of 1 to 4, if a and b are 2 or more, the structures in the brackets, are the same or different, respectively, R₅₁ and R₅₂ may bond to adjacent substituents to form a substituted or unsubstituted ring).

The boron compound represented by Chemical Formula 3 above may be represented by, e.g., Chemical Formula 3A below:

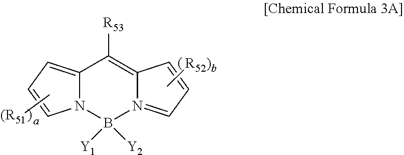

(in Chemical Formula 3A, R₅₁ to R₅₃, Y₁ and Y₂ may be defined the same as those described above, a and b are each independently an integer of 1 to 3).

The boron compound represented by Chemical Formula 3 above may be, for example, one or more selected from the group consisting of compounds B-1 to B-33 below, but the present invention is not limited thereto.

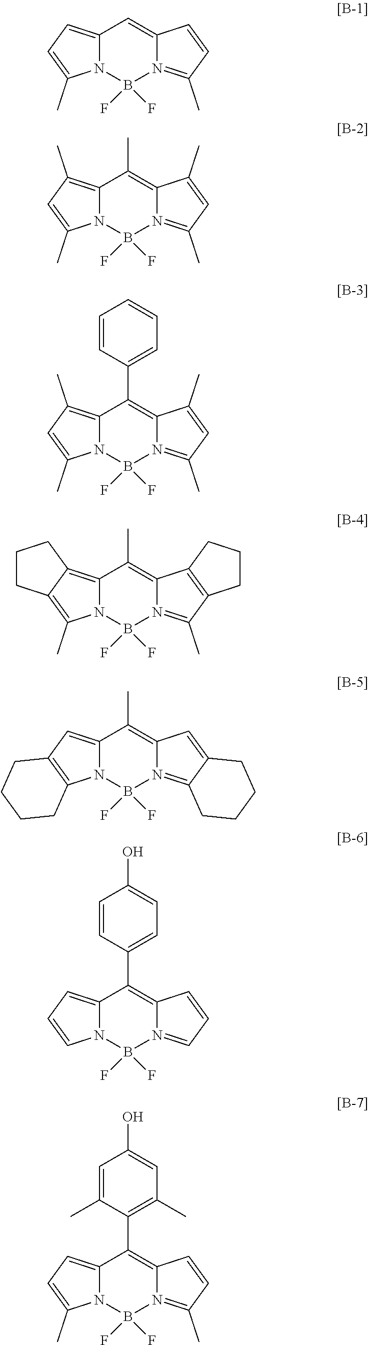

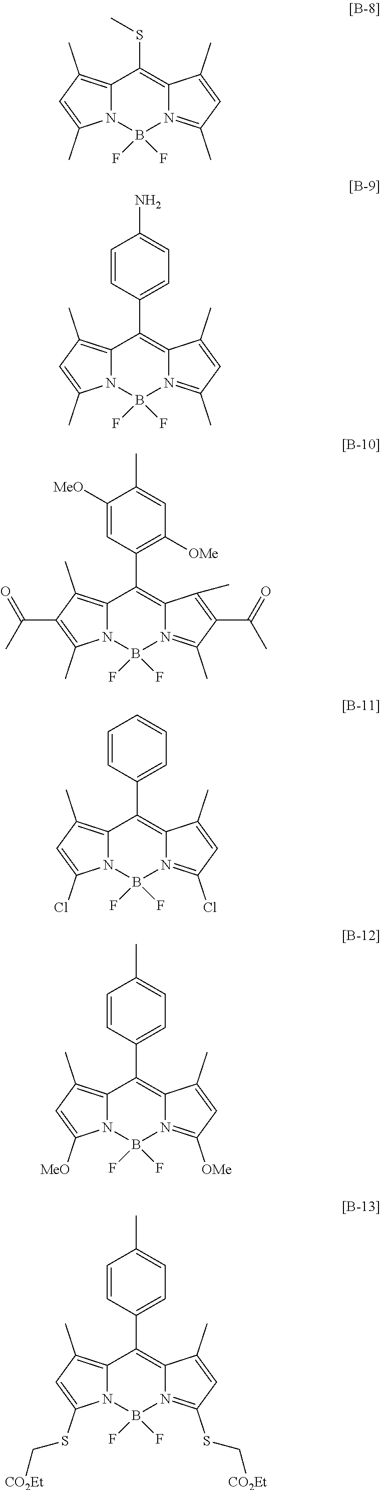

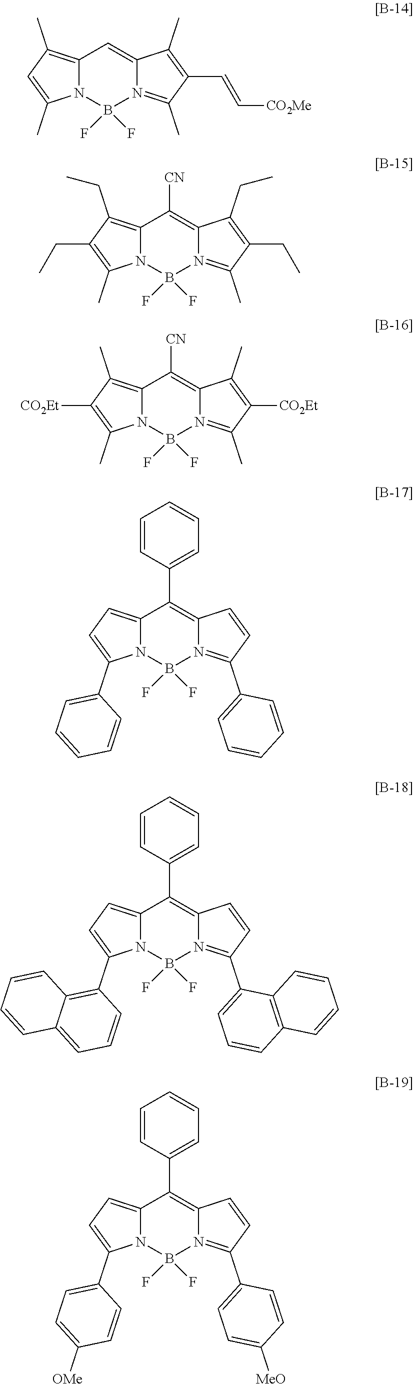

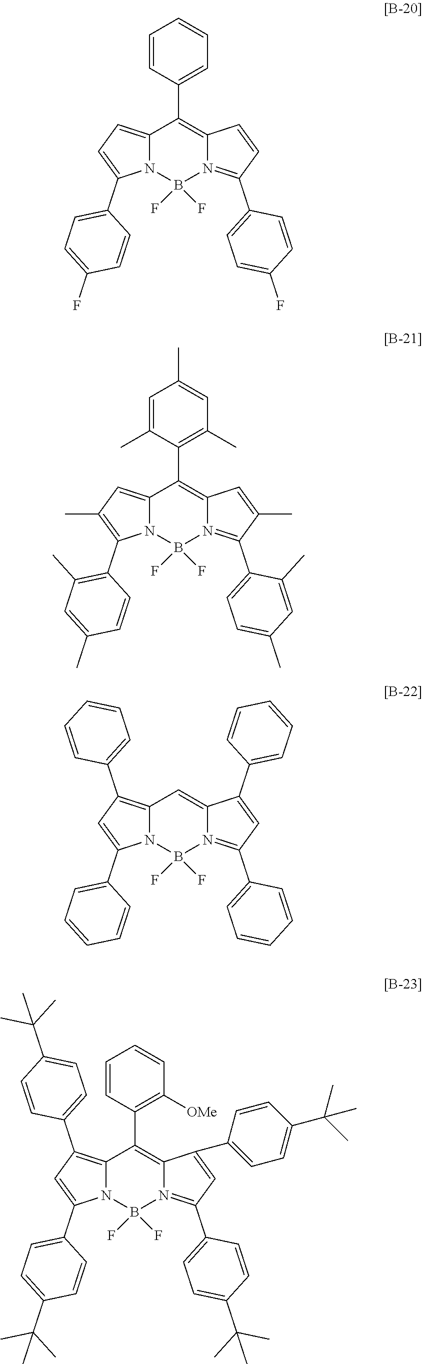

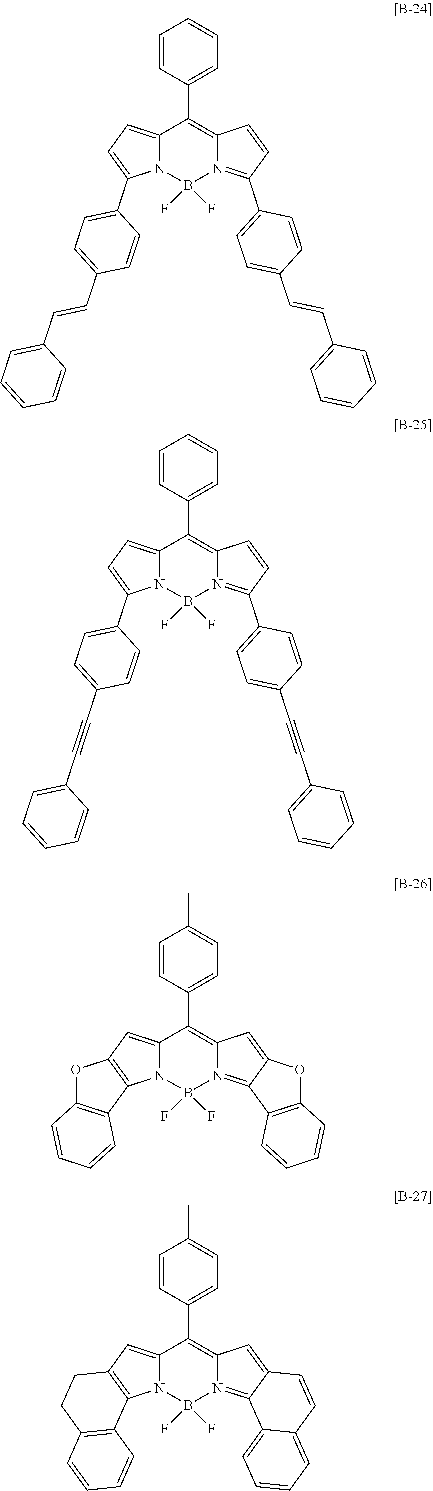

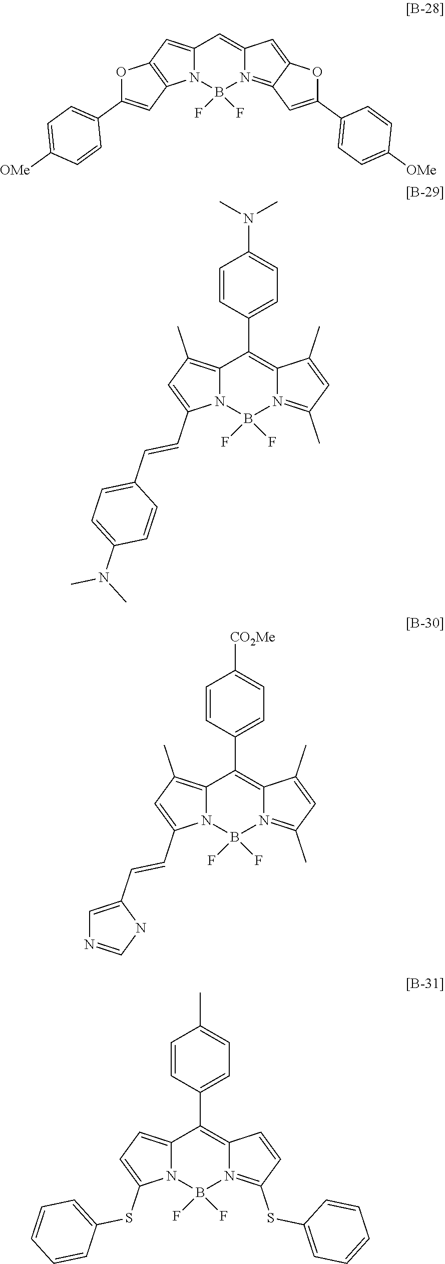

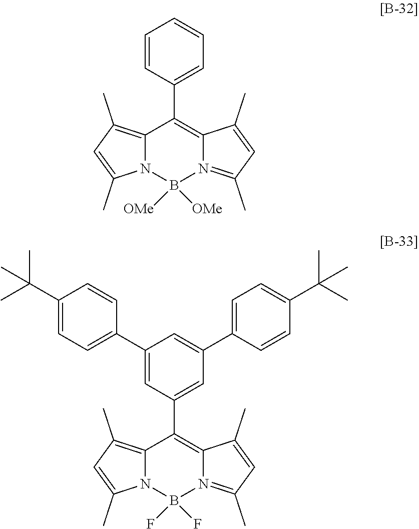

The organic nanoparticles may have a core-shell structure in which an organic phosphor is surrounded by a surfactant, and in this case, the shape and size of the organic nanoparticles may become uniform, thereby improving the yield of the organic nanoparticles, and the size of light-emitting organic nanoparticles may be adjusted by adjusting the concentration of the surfactant, thereby improving the properties of the color conversion film, but the present invention is not limited thereto.

The surfactant may be one or more selected from the group consisting of an anionic surfactant, a cationic surfactant, an amphoteric surfactant, and a nonionic surfactant, but the present invention is not limited thereto.

The anionic surfactant is a surfactant whose hydrophilic group exhibits an anion when dissolved in water, and the hydrophilic group of the anionic surfactant may be at least one selected from the group consisting of carboxylates, sulfates, sulfonates, and phosphates, but the present invention is not limited thereto.

The cationic surfactant is a surfactant whose hydrophilic group exhibits a cation when dissolved in water, and may include a nitrogen atom having a positive charge, and specifically, may be tetrabutylammonium oleate (TBAOleate), but the present invention is not limited thereto.

The amphoteric surfactant is a surfactant having properties of an anionic surfactant in an alkaline range and properties of a cationic surfactant in an acidic range when dissolved in water.

The nonionic surfactant is a surfactant having a hydrophilic group that is not ionized when dissolved in water, and is a surfactant that does not exhibit electric charges even when dissolved in water and may be, for example, Triton X100 having a hydrophilic polyethylene oxide chain and a lipophilic or hydrophobic aromatic hydrocarbon group, but the present invention is not limited thereto.

In the present invention, a method of preparing light-emitting organic nanoparticles is not particularly limited and, for example, the light-emitting organic nanoparticles may be prepared using a method including an operation S1 of mixing an organic phosphor and a surfactant and preparing a first mixture, an operation S2 of adding an anti-solvent for the organic phosphor to the first mixture and preparing a dispersion, and an operation S3 of dialyzing the dispersion and drying the dialyzed dispersion.

### Operation S1

The description of the organic phosphor and the surfactant constituting the first mixture in operation S1 is as described above.

In operation S1, a mixing ratio (molar ratio) of the organic phosphor and the surfactant may be 1:20 to 1:1,000, preferably, 1:200 to 1:800, and more preferably, 1:400 to 1:600, but the present invention is not limited thereto. When the mixing ratio (molar ratio) of the organic phosphor and the surfactant satisfies the above range, uniform light-emitting organic nanoparticles having a small particle size may be obtained.

When the concentration of the surfactant exceeds a critical micelle concentration, a hydrophobic portion of the surfactant surrounds the organic nanoparticles to form micelles, and the micelles are dispersed in a solvent. This makes the shape and size of the light-emitting organic nanoparticles uniform, thereby improving the yield of the light-emitting organic nanoparticles. Meanwhile, since the particle size of the light-emitting organic nanoparticles is adjusted by adjusting the concentration of the surfactant, the properties of the color conversion film may be further improved.

### Operation S2

The anti-solvent added in operation S2 may be at least one selected from the group consisting of an aqueous solvent, an alcohol-based solvent, a ketone-based solvent, an ether-based solvent, a sulfoxide-based solvent, and an ester-based solvent, but the present invention is not limited thereto.

The aqueous solvent may be, for example, any one of water, an aqueous hydrochloric acid solution, and an aqueous sodium hydroxide solution, the alcohol-based solvent may be, for example, at least one selected from the group consisting of methanol, ethanol, isopropyl alcohol, n-propyl alcohol, and 1-methoxy-2-propanol, the ketone-based solvent may be, for example, at least one selected from the group consisting of acetone, methyl ethyl ketone, methyl isobutyl ketone, and cyclohexanone, the ether-based solvent may be, for example, at least one selected from the group consisting of dimethyl ether, diethyl ether, and tetrahydrofuran, the sulfoxide-based solvent may be, for example, dimethyl sulfoxide, and the ester-based solvent may be, for example, an alkyl ester, but the present invention is not limited thereto.

### Operation S3

Operation S3 is an operation performed to improve the yield of the light-emitting organic nanoparticles by removing excess surfactant from the dispersion.

A dialysis device used in operation S3 may be, for example, a dialysis tube made of cellulose acetate, but the present invention is not limited thereto.

Drying the dispersion dialyzed in operation S3 may be concentrating the dispersion under vacuum for 10 to 12 hours, but the present invention is not limited thereto.

### Composition for Color Conversion Film

According to another aspect of the present invention, a composition for a color conversion film including the above-described light-emitting organic nanoparticles and a water-soluble polymer resin is provided.

The water-soluble polymer resin may have a weight average molecular weight of 5,000 to 100,000 g/mol and a degree of hydration of 70 to 100%, and in this case, the water-soluble polymer resin may exhibit appropriate surfactant and the properties of the color conversion film may be further improved, but the present invention is not limited thereto.

The water-soluble polymer resin may be at least one selected from the group consisting of a nonionic water-soluble polymer, an anionic water-soluble polymer, and a cationic water-soluble polymer, but the present invention is not limited thereto.

The nonionic water-soluble polymer may be, for example, one or more polymers or copolymers selected from the group consisting of polyvinyl alcohol (PVA), polyethylene oxide (PEO), polyacrylamide (PAM), and polyvinylpyrrolidone (PVP), the anionic water-soluble polymer may be, for example, one or more polymers or copolymers selected from the group consisting of polyacrylic acid (PAA) and its derivatives, poly(styrene sulfonic acid) (PSSA), poly(silicic acid) (PSiA), poly (phosphoric acid) (PPA), poly(ethylenesulfinic acid) (PESA), poly[3-(vinyloxy)propane-1-sulfonic acid], poly(4-vinylphenol), poly(4-vinylphenol sulfuric acid), poly(ethylenephosphoric acid), poly(maleic acid), poly(2-methacryloxyethane-1-sulfonic acid), poly(3-methacryloyloxypropane-1-sulfonic acid), and poly(4-vinylbenzoic acid), and the cationic water-soluble polymer may be, for example, one or more polymers or copolymers selected from the group consisting of polyethyleneimine (PEI), polyamines, polyamideamine (PAMAM), poly(diallyldimethyl ammonium chloride) (PDADMAC), poly(4-vinylbenzyltrimethylammonium salt), poly[(dimethylimino)trimethylene(dimethylimino)hexamethylenedibromide] (polybrene), poly(2-vinylpiperidine salt), poly(vinylamine salt), and poly(2-vinylpyridine) and derivatives thereof, but the present invention is not limited thereto.

The description of the light-emitting organic nanoparticles is as described above.

The content of the light-emitting organic nanoparticles may be 1 to 20 parts by weight based on 100 parts by weight of the water-soluble polymer resin, but the present invention is not limited thereto. When the content of the light-emitting organic nanoparticles is too small, CCE may be lowered, and conversely, when the content of the organic nanoparticles is too large, the properties of aggregation between nanoparticles may become stronger so that the size of the particles may increase, and quenching may occur.

The composition for a color conversion film may further include a crosslinking agent in order to secure high thermal stability of the color conversion film and prevent discoloration (decrease in transmittance) due to heat, but the present invention is not limited thereto.

The crosslinking agent may be, for example, one or more selected from the group consisting of glutaraldehyde, glyoxal, maleic acid, citric acid, trisodium trimetaphosphate, sodium hexametaphosphate, dianhydrides, succinic acid, suberic acid, sulfosuccinic acid, and a radical crosslinking agent, K₂S₂O₈, but the present invention is not limited thereto.

When the water-soluble polymer resin is PVA, it is preferable to use suberic acid or the radical crosslinking agent, K₂S₂O₈, as a crosslinking agent to improve thermal stability and transmittance maintenance, but the present invention is not limited thereto.

The content of the crosslinking agent may be 0.01 to 20 parts by weight based on 100 parts by weight of the water-soluble polymer resin, but the present invention is not limited thereto.

The composition for a color conversion film may further include a light scattering agent in order to generate a light scattering effect to increase light absorption efficiency, improve dispersibility, and secure high thermal stability and incombustibility, but the present invention is not limited thereto.

The light scattering agent may be, for example, one or more types of inorganic oxide particles selected from the group consisting of TiO₂, ZnO, Fe₃O₄, CeO₂, MoO₂, Ag₂O, CuO, and NiO, and may be inorganic oxide particles having an average particle size of 200 to 400 nm, but the present invention is not limited thereto.

The content of the light scattering agent may be 1 to 20 parts by weight based on 100 parts by weight of the water-soluble polymer resin, but the present invention is not limited thereto.

### Color Conversion Film

According to still another aspect of the present invention, a color conversion film manufactured using the above-described composition for a color conversion film is provided.

The color conversion film may be manufactured using the above-described composition for a color conversion film by a bar coating method, a sol-gel method, inkjet printing, roll coating, spin coating, drop casting, or the like.

For example, in the case in which the color conversion film is manufactured using a bar coating method, the above-described composition for a color conversion film may be sprayed on a glass substrate, then a film may be formed by a bar coating method, and annealing may be performed in an oven at 50 to 70° C. for several hours in order to remove the solvent to manufacture the color conversion film, but the present invention is not limited thereto.

A thickness of the color conversion film may be 200 μm or less, preferably, 180 μm or less, and more preferably, 150 μm, but the present invention is not limited thereto.

### Display Device

According to yet another aspect of the present invention, a display device including the above-described color conversion film is provided.

The display device according to the present invention may include a liquid-crystal display (LCD) device, an organic light-emitting display device, a micro-LED display device, or the like.

An organic phosphor used in the display device should have a narrow FWHM for high color purity. Therefore, the organic phosphor used in the display device may be a boron compound having the luminous efficiency of 80% or more described above, but the present invention is not limited thereto.

Generally, a LCD device includes two substrates. Specifically, the LCD device includes a lower substrate having a switching element including a thin film transistor, an upper substrate facing the lower substrate and having a common electrode, and liquid crystals injected between the upper and lower substrates.

In contrast, an organic LED (OLED) and a micro-LED may each be formed on a single substrate. A switching element including a thin film transistor at a lower portion thereof may be formed, and an OLED or a micro-LED turned on/off by the corresponding switching element may be formed at an upper portion of the switching element. Although the OLED or the micro-LED may be formed using a single substrate, the OLED or the micro-LED generally includes an upper substrate and is used by forming an antireflection film or the like on the corresponding upper substrate.

The display device according to the present invention may typically include an upper substrate including a base film, an antireflection film, and a color conversion film, and the color conversion film may be formed using the light-emitting organic nanoparticles according to the present invention.

In the case of a LCD device, light emitted from a backlight is converted into three primary colors using a color conversion film, and in the case of a display device to which an OLED or a micro-LED is applied, a monochromatic OLED or micro-LED is applied and light is emitted in three primary colors using the color conversion film according to the present invention.

### LED Device

According to yet another aspect of the present invention, a LED device including the above-described color conversion film is provided.

The LED device is a LED that emits light by applying a voltage to a PN junction diode of a compound semiconductor, and the LED device corresponds to a LED in which energy generated when holes and electrons move between p and n and are combined with each other is emitted in the form of light, and should be understood as a concept including an OLED.

An organic phosphor used in a LED device should have a wide FWHM to implement a high color rendering index (CRI). Therefore, the organic phosphor used in the LED device may be a delayed fluorescence material having the luminous efficiency of 80% or more described above, but the present invention is not limited thereto.

Generally, LED devices are divided into chip LEDs with features of high brightness, an ultra-small size, and a thin shape, top LEDs, lamp LEDs used for outdoor displays, electric signboards, or the like having ultra-high brightness, high moisture resistance, and heat resistance, or the like according to the purpose of use.

The LED device according to the present invention may include a substrate, and a LED chip disposed on the substrate. The color conversion film according to the present invention may absorb light emitted from the LED chip (or LED backlight) using the light-emitting organic nanoparticles according to the present invention to convert the absorbed light into light of a different long wavelength.

Hereinafter, examples in this specification will be described in more detail. However, the following experimental results are only representative experimental results among the above examples, and cannot be interpreted as the scope and contents of the present specification are reduced or limited by the examples. Each effect of various examples in this specification that is not explicitly presented below will be described in detail in the corresponding section.

### Preparation Examples: Preparation of Organic Phosphor

### Preparation Example 1: Preparation of Compound T-3

### (1) Synthesis of Compound T-3

2-(4-bromophenyl)-4,6-diphenyl-1,3,5-triazine (Trz, 8.85 mmol) and 10,15-dihydro-5H-diindolo[3,2-a:3′,2′-c]carbazole (fused carbazole, 2.95 mmol) were added at a molar ratio of 3:1 into a mixture in which tris(dibenzylideneacetone)dipalladium(0) (Pd₂(dba)₃, 0.08 mmol), tri-tert-butylphosphine ((t-Bu)3P, 1.86 mmol), sodium tert-butoxide (NaOt-Bu, 5.15 mmol), and anhydrous o-xylene were mixed. The mixture to which Trz and fused carbazole were added was flushed with nitrogen and an inert atmosphere was generated under vacuum conditions. Thereafter, a reaction proceeded constantly while refluxing at 135° C. for 12 hours. The mixture for which the reaction was completed was washed several times with dichloromethane and deionized water. Water was discarded from the washed mixture and a dichloromethane layer was dried over anhydrous sodium sulfate. The mixture on which the drying process was performed was filtered through a filter, and the remaining solvent was evaporated using a rotary evaporator to synthesize a final product, 5,10,15-tris(4-(4,6-diphenyl-1,3,5-triazin-2-yl)phenyl)-10,15-dihydro-5H-diindolo[3,2-a:3′,2′-c]carbazole (hereinafter, referred to as “Ttrz-DI”) purified using silica column chromatography.

The reaction in which the final product is synthesized is summarized in the following reaction scheme.

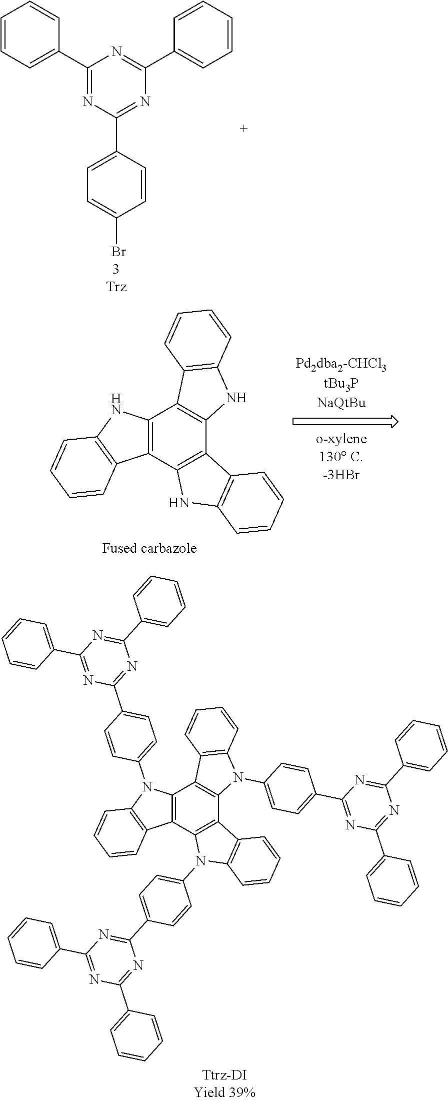 [SMILES: Brc1ccc(-c2nc(-c3ccccc3)nc(-c3ccccc3)n2)cc1 ; c1ccc2c(c1)[nH]c1c2c2[nH]c3ccccc3c2c2[nH]c3ccccc3c12 ; c1ccc(-c2nc(-c3ccccc3)nc(-c3ccc(-n4c5ccccc5c5c4c4c6ccccc6n(-c6ccc(-c7nc(-c8ccccc8)nc(-c8ccccc8)n7)cc6)c4c4c6ccccc6n(-c6ccc(-c7nc(-c8ccccc8)nc(-c8ccccc8)n7)cc6)c54)cc3)n2)cc1]

### (2)¹H-NMR Data of Compound T-3

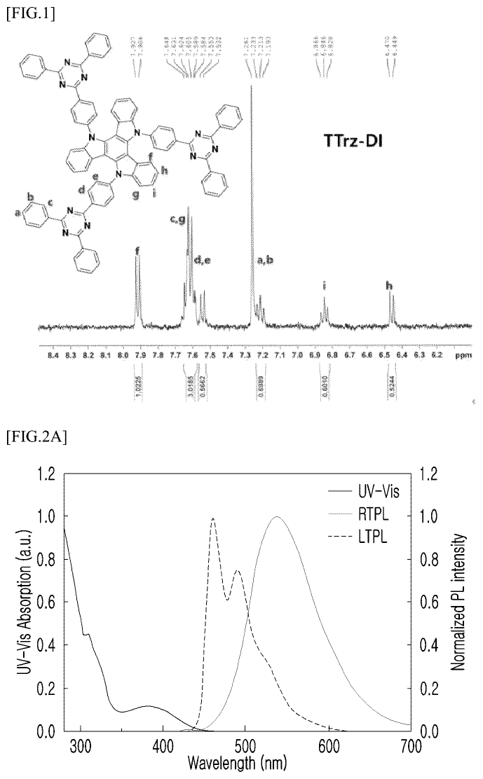

FIG. 1 shows the ¹H-NMR data of Ttrz-DI. The ¹H-NMR data was measured using a 400 MHz Bruker NMR spectrometer.

Referring to FIG. 1, it can be seen that Ttrz-DI was synthesized by reacting Trz and fused carbazole at a molar ratio of 3:1.

### (3) Analysis of Photophysical Properties of Compound T-3

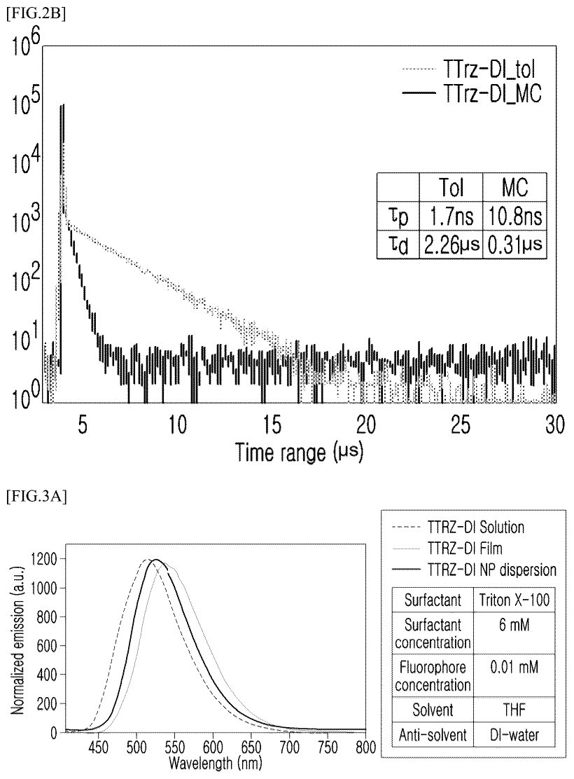

FIG. 2A shows the UV-visible spectroscopy (UV-Vis) and room temperature photoluminescence (RTPL) and low temperature photoluminescence (LTPL) spectra of Ttrz-DI in toluene.

Referring to FIG. 2A, an initial value of RTPL indicates that energy in a singlet state of Ttrz-DI is 2.83 eV at on-set, and an initial value of LTPL in a 77 K toluene solution indicates that energy in a triplet state of Ttrz-DI is 2.80 eV at on-set. Therefore, a difference between the energy in the triplet state of Ttrz-DI and the energy in the singlet state of Ttrz-DI corresponds to 0.03 eV.

FIG. 2B shows the time resolved photoluminescence (TRPL) of Ttrz-DI in a solvent. The solvent is toluene (Tol) or dichloromethane (MC).

Referring to FIG. 2B, it can be seen that Ttrz-DI has two decays, which are prompt decay and delayed decay, and exhibits TADF properties.

### Preparation Example 2: Preparation of Compound T-9

A compound T-9 (hereinafter, referred to as “4CzIPN”) having the following structural formula was synthesized with reference to Nature 492, pp. 234-238 (2012).

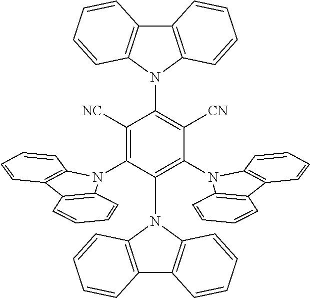 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

### Preparation Example 3: Preparation of Compound D-23

### (1) Synthesis of Intermediate

A mixture of 1,3,5-tribromobenzene (1 g, 3.18 mmol), di(naphthalen-2-yl)amine (2.74 g, 10.17 mmol), P(t-Bu)₃ (0.8 ml, 3.17 mmol), and NaOtBu (1.84 g, 19.15 mmol) in anhydrous toluene (60 mL) was substituted with argon gas, and Pd₂(dba)₃ (0.26 g, 0.28 mmol) was added into the mixture, and then the mixture was stirred at temperature of 160° C. for 18 hours. After the reaction was completed, the compound was filtered, washed using dichloromethane and hexane, concentrated, and then recrystallized with dichloromethane and hexane to obtain the following intermediate (2.6 g, 93%).

The reaction in which the intermediate is synthesized is summarized in the following reaction scheme.

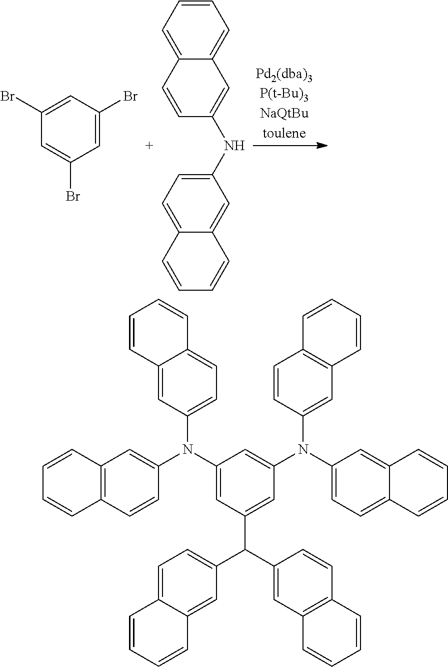

### (2) Synthesis of Compound D-23

A mixture of the intermediate (1 g, 1.14 mmol) in o-dichlorobenzene (15 ml) was substituted with argon, and then BBr₃ (0.31 ml, 2.5 mmol) was slowly added into the mixture at room temperature. After 10 minutes, the reaction mixture was refluxed at 200° C. for 20 hours. After the reaction was completed, the reaction product was diluted using toluene, filtered through a silica pad, and concentrated. The residue was purified with hexane and dichloromethane using column chromatography to obtain a compound D-23 (0.2 g, 20%).

The reaction in which the compound D-23 (hereinafter, referred to as “TANP”) is synthesized is summarized in the following reaction scheme.

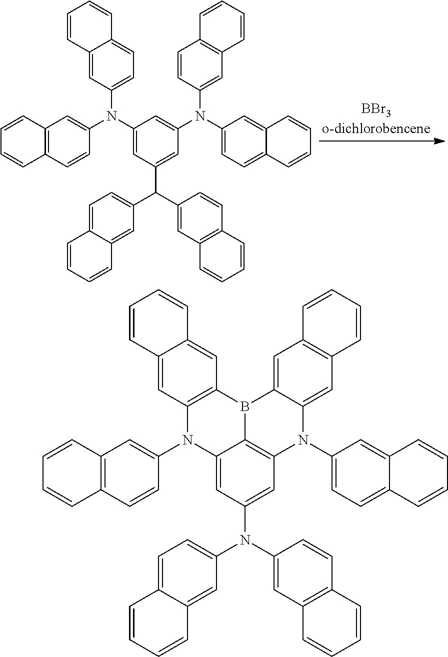

### Preparation Example 4: Preparation of Compound D-13

A compound D-13 (hereinafter, referred to as “CzDABNA”) having the following structural formula was synthesized with reference to Angew. Chem. Int. Ed. 57, pp 11316-11320 (2018).

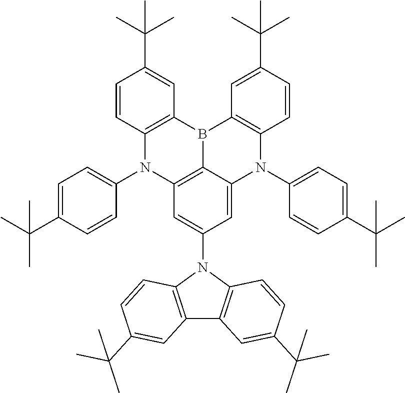 [SMILES: CC(C)(C)c1ccc(N2c3ccc(C(C)(C)C)cc3B3c4cc(C(C)(C)C)ccc4N(c4ccc(C(C)(C)C)cc4)c4cc(-n5c6ccc(C(C)(C)C)cc6c6cc(C(C)(C)C)ccc65)cc2c43)cc1]

### Preparation Example 5: Preparation of Compound B-23

A compound B-23 (hereinafter, referred to as “4tBuMB”) having the following structural formula was synthesized with reference to ACS Appl. Mater. Interfaces 13, pp 17882-17891 (2021).

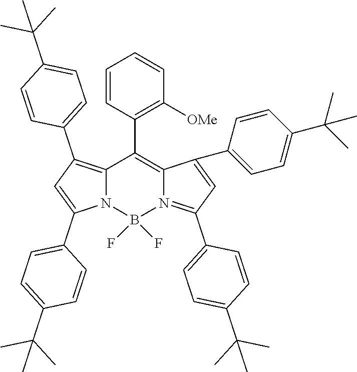

### Preparation Example 6: Preparation of Compound B-33

A compound B-33 (hereinafter, referred to as “tPhBODIPY”) having the following structural formula was synthesized with reference to Adv. Optical Mater. 8, 2000483 (2020).

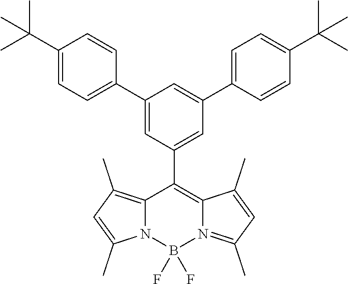

### Manufacturing Example 1: Manufacture of Light-Emitting Organic Nanoparticles

### Manufacturing Example 1-1

Ttrz-DI was dissolved in tetrahydrofuran to prepare a solution (0.5 mM). In addition, a nonionic surfactant (Triton X-100) was dissolved in separate tetrahydrofuran to prepare a solution (0.1 M). The surfactant solution (0.36 mL) and tetrahydrofuran (0.14 mL) were added to the Ttrz-DI solution (0.10 mL) to prepare a first mixture. The first mixture and 5.40 mL of deionized water were mixed to prepare a dispersion. The dispersion was dialyzed with a cellulose acetate tube for 12 hours to remove residual surfactant, and the residue was concentrated under vacuum to prepare green organic nanoparticles (hereinafter, referred to as “Ttrz-DI NP”).

### Manufacturing Example 1-2

Green Ttrz-DI NP was prepared in the same manner as in Manufacturing Example 1-1, except that tert-butyl ammonium oleate (TBAOleate) was used instead of Triton X-100 as a surfactant.

### Manufacturing Example 1-3

Green organic nanoparticles were prepared in the same manner as in Manufacturing Example 1-1, except that 4CzIPN was used instead of Ttrz-DI as an organic phosphor.

### Manufacturing Example 1-4

Green organic nanoparticles were prepared in the same manner as in Manufacturing Example 1-1, except that TNAP was used instead of Ttrz-DI as an organic phosphor.

### Manufacturing Example 1-5

Green organic nanoparticles were prepared in the same manner as in Manufacturing Example 1-1, except that tPhBODIPY was used instead of Ttrz-DI as an organic phosphor.

### Manufacturing Example 1-6

Blue organic nanoparticles were prepared in the same manner as in Manufacturing Example 1-1, except that CzDABNA was used instead of Ttrz-DI as an organic phosphor.

### Manufacturing Example 1-7

Blue organic nanoparticles were prepared in the same manner as in Manufacturing Example 1-6, except that TBAOleate was used instead of Triton X-100 as a surfactant.

### Manufacturing Example 1-8

Red organic nanoparticles were prepared in the same manner as in Manufacturing Example 1-1, except that 4tBuMB was used instead of Ttrz-DI as an organic phosphor.

### Manufacturing Example 1-9

Red organic nanoparticles were prepared in the same manner as in Manufacturing Example 1-8, except that TBAOleate was used instead of Triton X-100 as a surfactant.

### Comparative Manufacturing Example 1-1

Green Ttrz-DI NP was prepared in the same manner as in Manufacturing Example 1-1, except that the surfactant solution was not mixed.

### Comparative Manufacturing Example 1-2

Blue organic nanoparticles were prepared in the same manner as in Manufacturing Example 1-6, except that the surfactant solution was not mixed.

### Comparative Manufacturing Example 1-3

Red organic nanoparticles were prepared in the same manner as in Manufacturing Example 1-8, except that the surfactant solution was not mixed.

### Experimental Example 1: Particle Size of Organic Nanoparticles

The particle sizes of the organic nanoparticles prepared according to Manufacturing Example 1 were measured, and results of the measurement are shown in Table 1 below.

TABLE 1

| | Average | Standard deviation | Minimum | Maximum |
|---|---|---|---|---|
| | (μm) | (μm) | (μm) | (μm) |
| Manufacturing | 0.12 | 0.08 | 0.05 | 0.48 |
| Example 1-1 | | | | |
| Manufacturing | 0.14 | 0.12 | 0.11 | 0.59 |
| Example 1-2 | | | | |
| Manufacturing | 0.13 | 0.24 | 0.05 | 1.53 |
| Example 1-6 | | | | |
| Manufacturing | 0.13 | 0.25 | 0.05 | 1.57 |
| Example 1-7 | | | | |
| Manufacturing | 0.16 | 0.07 | 0.04 | 0.41 |
| Example 1-8 | | | | |
| Manufacturing | 0.17 | 0.10 | 0.06 | 0.52 |
| Example 1-9 | | | | |
| Comparative | 14.14 | 10.99 | 1.62 | 98.22 |
| Manufacturing | | | | |
| Example 1-1 | | | | |
| Comparative | 15.24 | 11.50 | 1.65 | 99.89 |
| Manufacturing | | | | |
| Example 1-2 | | | | |
| Comparative | 17.38 | 4.25 | 10.70 | 32.34 |
| Manufacturing | | | | |
| Example 1-3 | | | | |

From Table 1, it can be seen that when no surfactant was used, the phosphor was aggregated and the average particle size became about 100 times larger than that when the surfactant was used, and thus organic particles in micro units were obtained, whereas, when the surfactant was used, nanoparticles in which organic particles were much more uniform and smaller were obtained.

### Experimental Example 2: Evaluation of Particle Size and Optical Properties According to State of Organic Nanoparticles

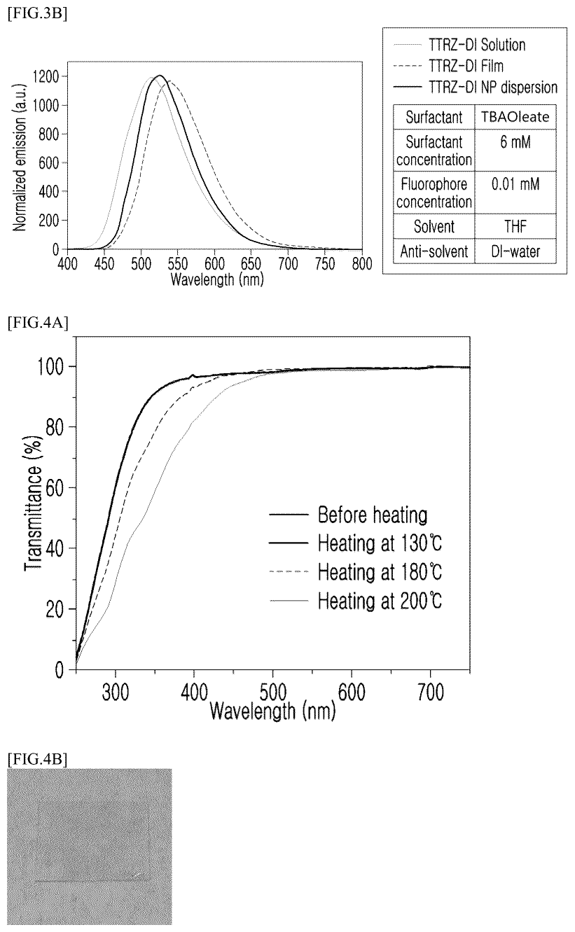

FIG. 3A is a graph showing the sizes and emission wavelengths of particles that vary depending on a state of Ttrz-DI when Triton X-100 is used as a surfactant, and FIG. 3B is a graph showing the sizes and emission wavelengths of particles that vary depending on a state of Ttrz-DI when TBAOleate is used as a surfactant. Referring to FIGS. 3A and 3B, it can be seen that the positions of peaks in emission spectra vary depending on the state of Ttrz-DI. Such a difference occurs as the particle size of the phosphor particles is changed. Specifically, when Ttrz-DI is in a solution state, the organic phosphor particles have a size distribution in A (Angstrom) units, and in a bulk film state, the particles form large aggregations and become larger, and the emission spectra shift toward a long wavelength. In contrast, it can be seen that when Ttrz-DI is a dispersion, the particle sizes are uniformly distributed on the m to nm scale, and the peaks in the emission spectra are positioned between the solution state and the film state.

A solution in which the organic nanoparticles prepared according to Manufacturing Example 1 and 50 to 100 mg of green quantum dots (QDs) was dispersed in octene (1 ml) was prepared, then the optical properties and the average particle size were measured, and results of the measurement are shown in Table 2 below. In this case, room temperature photoluminescence spectra were measured using JASCO-FP 8500 equipment, absolute photoluminescence quantum yield (PLQY) values were measured using an integrating sphere built in the JASCO-FP 8500 equipment for the prepared solution, and the average particle sizes were measured using an optical microscope.

TABLE 2

| | Maximum | | | Average particle |
|---|---|---|---|---|
| | emission | | | size (nm) of |
| | spectrum | FWHM | | organic |
| | (nm) | (nm) | PLQY | nanoparticles |
| Manufacturing | 517 | 91 | 0.43 | 120 |
| Example 1-1 | | | | |
| Manufacturing | 513 | 63 | 0.77 | 130 |
| Example 1-3 | | | | |
| Manufacturing | 524 | 26 | 0.75 | 165 |
| Example 1-4 | | | | |
| Manufacturing | 526 | 26 | 0.51 | 150 |
| Example 1-5 | | | | |
| Manufacturing | 454 | 20 | 0.39 | 110 |
| Example 1-6 | | | | |
| Manufacturing | 621 | 31 | 0.99 | 162 |
| Example 1-8 | | | | |
| Green | 525 | 35 | 0.70 | <20 |
| QDInP/ZnSe/ZnS | | | | |

From Table 2, it can be seen that the phosphor particles prepared using the surfactant had nanoscale average particle sizes and had sizes about 10 times larger than that of the green QD particles.

### Manufacturing Example 2: Manufacture of Base Film

### Manufacturing Example 2-1

0.49 g of polyvinyl alcohol (PVA, weight average molecular weight of 13,000 to 23,000 g/mol and degree of hydration of 87 to 89%) and 0.01 g of suberic acid (SA) were mixed in 5.0 mL of deionized water to prepare a mixed solution, and the mixed solution was heated at 80° C. for 2 hours. The mixed solution was cooled, about 1 mL of the mixed solution was sprayed on a glass substrate, and then a film was formed by a bar coating method. In order to remove the solvent, the formed film was kept in an oven at 60° C. for 4 hours, and a crosslinking reaction was carried out at 120° C. for 2 hours to manufacture a base film. As a result of measuring the thickness of the manufactured film by Alpha-Step, the thickness was 10.0 m.

### Manufacturing Example 2-2

A base film was manufactured in the same manner as in Manufacturing Example 2-1, except that 1.0 g of PVA and 0.05 g of SA were used. As a result of measuring the thickness of the manufactured film by Alpha-Step, the thickness was 10.0 μm.

### Manufacturing Example 2-3

A base film was manufactured in the same manner as in Manufacturing Example 2-1, except that 0.4 g of PVA, 0.1 g of polyvinylpyrrolidone (PVP), and 0.01 g of SA were mixed in 3.0 mL of deionized water to prepare a mixed solution. As a result of measuring the thickness of the manufactured film by Alpha-Step, the thickness was 10.0 μm.

### Manufacturing Example 2-4

A base film was manufactured in the same manner as in Manufacturing Example 2-1, except that 0.4 g of PVA, 0.2 g of PVP, and 0.01 g of SA were mixed in 3.5 mL of deionized water to prepare a mixed solution. As a result of measuring the thickness of the manufactured film by Alpha-Step, the thickness was 10.0 μm.

### Manufacturing Example 2-5

A base film was manufactured in the same manner as in Manufacturing Example 2-1, except that 1.0 g of PVA, 1.0 g of PVP, and 0.05 g of SA were mixed in 5.0 mL of deionized water to prepare a mixed solution. As a result of measuring the thickness of the manufactured film by Alpha-Step, the thickness was 10.0 μm.

### Manufacturing Example 2-6

A base film was manufactured in the same manner as in Manufacturing Example 2-1, except that 0.5 g of PVA, 1.0 g of PVP, and 0.05 g of SA were mixed in 5.0 mL of deionized water to prepare a mixed solution. As a result of measuring the thickness of the manufactured film by Alpha-Step, the thickness was 10.0 μm.

### Manufacturing Example 2-7

A base film was manufactured in the same manner as in Manufacturing Example 2-1, except that 0.5 g of PVA, 0.5 g of PVP, 0.001 g of a radical crosslinking agent, K₂S₂O₈, were mixed in 5.0 mL of deionized water to prepare a mixed solution. As a result of measuring the thickness of the manufactured film by Alpha-Step, the thickness was 10.0 μm.

### Comparative Manufacturing Example 2-1

A base film was manufactured in the same manner as in Manufacturing Example 2-1, except that 2.0 g of PVA was mixed in 10 mL of deionized water to prepare a mixed solution.

As a result of measuring the thickness of the manufactured film by Alpha-Step, the thickness was 10.0 m.

### Experimental Example 3: Evaluation of Transparency of Base Film

The base films manufactured according to Manufacturing Example 2 were left at each of room temperature (25° C.), 130° C., 180° C., and 200° C. for 1 hour, and then transparency was measured, and results of the measurement are shown in Table 3 below.

TABLE 3

| | Composition ratio (wt %) | Decrease in transparency (425 nm) | | |
|---|---|---|---|---|
| | of mixed solution | 130° C. | 180° C. | 200° C. |
| Manufacturing | PVA(98.0) + SA(2.0) | 0.0% | 3.2% | 16.0% |
| Example 2-1 | | | | |
| Manufacturing | PVA(95.2) + SA(4.8) | 0.0% | 1.0% | 7.8% |
| Example 2-2 | | | | |
| Manufacturing | PVA(78.0) + PVP(20.0) + SA(2.0) | 0.0% | 4.7% | — |
| Example 2-3 | | | | |
| Manufacturing | PVA(65.5) + PVP(32.8) + SA(1.6) | 0.0% | 5.4% | — |
| Example 2-4 | | | | |
| Manufacturing | PVA(48.8) + PVP(48.8) + SA(2.4) | 0.0% | 10.3% | — |
| Example 2-5 | | | | |
| Manufacturing | PVA(32.3) + PVP(64.5) + SA(3.2) | 0.0% | 25.3% | — |
| Example 2-6 | | | | |
| Manufacturing | PVA(50) + PVP(50) + K₂S₂O₈(0.01) | 0.0% | 2.5% | 5.5% |
| Example 2-7 | | | | |
| Comparative | PVA(100.0) | 3.4% | 28.3% | 89.1% |
| Manufacturing | | | | |
| Example 2-1 | | | | |

From Table 3, it can be seen that the base film manufactured using SA as a crosslinking agent had excellent thermal stability and ability to maintain transmittance compared to a base film manufactured without using a crosslinking agent. In particular, the base films of Manufacturing Examples 2-2 and 2-7 had the most excellent thermal stability and ability to maintain transmittance, and a change in color of the film was hardly observed even after the base film was left at a temperature of 200° C. for 1 hour. FIG. 4A shows the results of measuring transparency after leaving the base film according to Manufacturing Example 2-2 at each of room temperature (25° C.), 130° C., 180° C., and 200° C. for 1 hour, and FIG. 4B is a photograph of the base film according to Manufacturing Example 2-2 after the base film was left at a temperature of 200° C. for 1 hour.

### Experimental Example 4: Evaluation of Hardness of Base Film

Pencil hardnesses of the base films manufactured according to Manufacturing Example 2 were measured, and when no scratches were visible, it was evaluated as “◯,” when a scratch was weakly visible, it was evaluated as “Δ,” and when a scratch was deep, it was evaluated as “X.” Results of the measurement are shown in Table 4 below.

TABLE 4

| | |
|---|---|
| Composition ratio (wt %) | Pencil hardness |

| | of mixed solution | 2B | 2H | 4H |
|---|---|---|---|---|
| Manufacturing | PVA(98.0) + SA(2.0) | ◯ | ◯ | Δ |
| Example 2-1 | | | | |
| Comparative | PVA(100.0) | ◯ | X | X |
| Manufacturing | | | | |
| Example 2-1 | | | | |

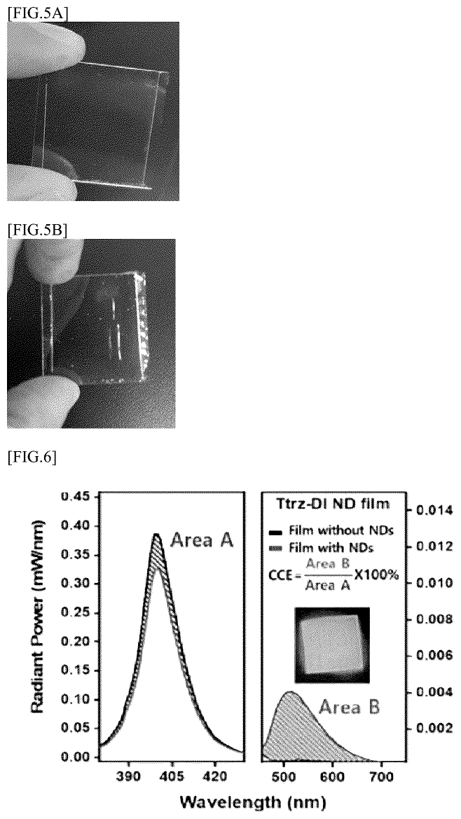

Referring to Table 4, in the case of the base films manufactured using SA as a crosslinking agent, film damage did not occur at hardnesses of 2B and 2H, and weak damage occurred only at a hardness of 4H, whereas, in the case of the base films manufactured without using a crosslinking agent, film damage occurred at a hardness of 2H as well as a hardness of 4H. From this, it can be seen that the hardness of the base films may be improved due to the crosslinking agent. FIG. 5A is a photograph of the base film according to Manufacturing Example 2-1 after measuring the pencil hardness of the base film, and FIG. 5B is a photograph of the base film according to Comparative Manufacturing Example 2-1 after measuring the pencil hardness of the base film.

### Manufacturing Example 3: Manufacture of Color Conversion Film (1)

### Manufacturing Example 3-1

1 g of PVA (weight average molecular weight of 13,000 to 23,000 g/mol and degree of hydration of 87 to 89%) was dissolved in 9 g of deionized water to prepare an aqueous 10 wt % PVA solution. The Ttrz-DI NP (0.3 g of dispersion) of Manufacturing Example 1-1 was mixed with the aqueous PVA solution (2.7 g). About 1 mL of the mixed solution was sprayed on a glass substrate and then a film was formed by a bar coating method. In order to remove the solvent, annealing was performed in an oven at 60° C. for 4 hours to manufacture a color conversion film.

### Manufacturing Example 3-2

A color conversion film was manufactured in the same manner as in Manufacturing Example 3-1, except that the 4CzIPN organic nanoparticles of Manufacturing Example 1-3 were used instead of the Ttrz-DI NP of Manufacturing Example 1-1.

### Manufacturing Example 3-3

A color conversion film was manufactured in the same manner as in Manufacturing Example 3-1, except that the TNAP organic nanoparticles of Manufacturing Example 1-4 were used instead of the Ttrz-DI NP of Manufacturing Example 1-1.

### Manufacturing Example 3-4

A color conversion film was manufactured in the same manner as in Manufacturing Example 3-1, except that the 4tBuMB organic nanoparticles of Manufacturing Example 1-8 were used instead of the Ttrz-DI NP of Manufacturing Example 1-1.

### Comparative Manufacturing Example 3-1

Polymethyl methacrylate (PMMA, weight average molecular weight of 120,000 g/mol, 5 g) was dissolved in 5 mL of chloroform to prepare an aqueous 10 wt % PMMA solution. An InP/ZnSe/ZnS-based QD solution (1 mM/chloroform, 0.3 g), which is an inorganic green light-emitting particle, was mixed into the above solution (2.7 g). About 1 mL of the mixed solution was sprayed on a glass substrate and then a film was formed by a bar coating method.

In order to remove the solvent, the solvent was removed in an oven at 40° C. for 3 hours to manufacture a color conversion film.

### Comparative Manufacturing Example 3-2

A color conversion film was manufactured in the same manner as in Manufacturing Example 3-1, except that the same amount of Ttrz-DI dissolved in THF was used instead of the Ttrz-DI NP of Manufacturing Example 1-1.

### Experimental Example 5: Evaluation of Optical Properties of Color Conversion Films

The optical properties of the color conversion film of Manufacturing Example 3 were evaluated, and specifically, UV-Vis absorption spectra were measured using JASCO V-750, and room temperature photoluminescence spectra were measured using JASCO-FP 8500 equipment. Further, PLQY values and CCE were measured using an integrating sphere built in the JASCO-FP 8500 equipment, and results of the measurement are shown in Table 5 below. Here, the CCE was measured by exciting each color conversion film using a blue LED having a 400 nm emission wavelength as an excitation light source. A method of measuring the CCE will be described in more detail with reference to FIG. 6. FIG. 6 shows a method of calculating the optical properties and the CCE of the color conversion film of Manufacturing Example 3-1, wherein a ratio (%) of a green light-emitting area B to a blue light-emitting area A corresponds to the CCE, the blue light-emitting area A corresponds to blue incident light absorbed by the color conversion film, and the green light-emitting area B is a green light-emitting area emitted by the color conversion film.

TABLE 5

| | Maximum emission | FWHM | | CCE |
|---|---|---|---|---|
| | spectrum (nm) | (nm) | PLQY | (%) |
| Manufacturing | 511 | 83 | 0.86 | 12.8 |
| Example 3-1 | | | | |
| Manufacturing | 506 | 72 | 0.95 | 19.3 |
| Example 3-2 | | | | |
| Manufacturing | 522 | 27 | 0.93 | 31.1 |
| Example 3-3 | | | | |
| Manufacturing | 619 | 39 | 0.99 | 27.8 |
| Example 3-4 | | | | |
| Comparative | 525 | 35 | 0.28 | 21.0 |
| Manufacturing | | | | |
| Example 3-1 | | | | |

Comparing Tables 5 and 2, it can be seen that the PLQY of the color conversion films according to Manufacturing Examples 3-1 to 3-4 tended to be higher than that in solution, whereas, the PLQY of the color conversion film according to Comparative Manufacturing Example 3-1 tended to be significantly lower than that in solution. This is a result of large QD-QD quenching.

### Experimental Example 6: Evaluation of UV Stability of Color Conversion Films

The color conversion films of Manufacturing Example 3 were continuously exposed to UV (wavelength: 365 nm) for 120 hours, and then the luminescence intensity was measured using room temperature photoluminescence spectra using JASCO-FP 8500 equipment. Results of the measurement are shown in Table 6 below.

TABLE 6

| | Maximum | Luminescence | Luminescence |
|---|---|---|---|
| | emission | intensity (a.u) | intensity (a.u) |
| | spectrum | before UV | after UV |
| | (nm) | exposure | exposure |
| Manufacturing | 511 | 1 | 0.39 |
| Example 3-1 | | | |
| Manufacturing | 506 | 1 | 0.57 |
| Example 3-2 | | | |
| Manufacturing | 522 | 1 | 0.38 |
| Example 3-3 | | | |
| Manufacturing | 619 | 1 | 0.82 |
| Example 3-4 | | | |
| Comparative | 525 | 1 | 0.20 |
| Manufacturing | | | |
| Example 3-1 | | | |
| Comparative | 511 | 1 | 0.25 |
| Manufacturing | | | |
| Example 3-2 | | | |

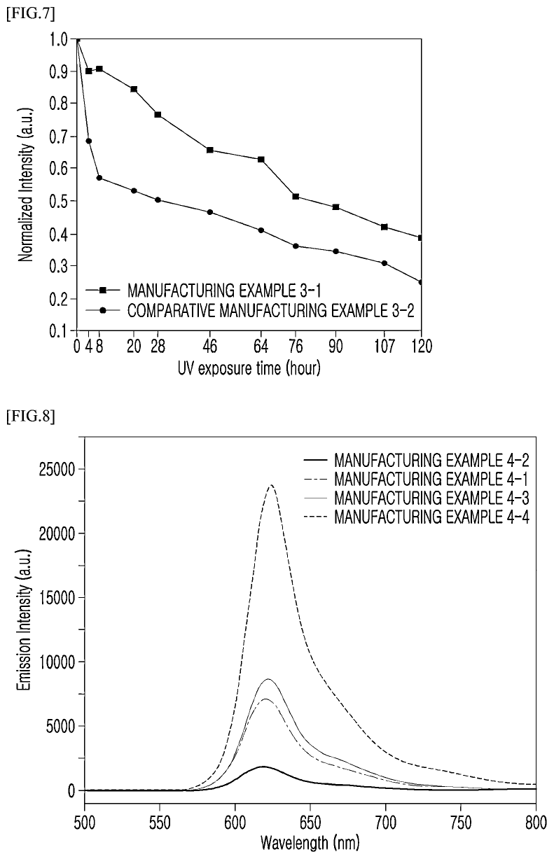

From Table 6, it can be seen that the color conversion films manufactured using the organic nanoparticles of the present invention had excellent UV stability compared to the conventional QD film. Further, from the comparison between Manufacturing Example 3-1 and Comparative Manufacturing Example 3-2, it can be seen that the UV stability of the color conversion film manufactured using the organic nanoparticles of the present invention increased about 1.6 times compared to the color conversion film manufactured using the organic material itself. FIG. 7 is a graph showing the results of light resistance evaluation after exposing the color conversion films of Manufacturing Example 3-1 and Comparative Manufacturing Example 3-2 to UV for 120 hours.

### Experimental Example 7: Evaluation of Room Temperature Stability of Color Conversion Films

The color conversion films of Manufacturing Example 3 were left at room temperature for 1 month and then the amount of change in CCE was measured. Results of the measurement are shown in Table 7 below.

TABLE 7

| | Maximum | CCE (%) | CCE (%) | Amount (%) |
|---|---|---|---|---|
| | emission | before | after | of change |
| | spectrum (nm) | keeping | keeping | in CCE |
| Manufacturing | 511 | 12.8 | 12.7 | 0.8 |
| Example 3-1 | | | | |
| Manufacturing | 506 | 19.3 | 19.2 | 0.5 |
| Example 3-2 | | | | |
| Manufacturing | 522 | 31.1 | 30.9 | 0.6 |
| Example 3-3 | | | | |
| Manufacturing | 619 | 27.8 | 27.7 | 0.4 |
| Example 3-4 | | | | |
| Comparative | 525 | 21.0 | 10.9 | 48.1 |
| Manufacturing | | | | |
| Example 3-1 | | | | |

From Table 7, it can be seen that the amount of change in CCE of the color conversion films manufactured using the organic nanoparticles of the present invention was 1% or less, and the durability of the CCE of the color conversion films manufactured using the organic nanoparticles of the present invention was very excellent compared to the conventional QD film.

### Manufacturing Example 4: Manufacture of Color Conversion Film (2)

### Manufacturing Example 4-1

PVA and SA were mixed in deionized water at a weight ratio of 49:1 to prepare an aqueous 15 wt % polyvinyl alcohol solution (PVA-SA, 15 wt %), and then heated at 80° C. for 3 hours. The 4tBuMB organic nanoparticles (4.0 wt % dispersion, 0.08 mL) of Manufacturing Example 1-8 and a TiO₂ solution (6.0 wt % aqueous solution, 0.05 mL) were mixed with the aqueous PVA-SA solution (15 wt %, 1.0 mL). About 1 mL of the mixed solution was sprayed on a glass substrate and then a film was formed by a bar coating method. In order to remove the solvent, the formed film was kept in an oven at 60° C. for 4 hours, and a crosslinking reaction was carried out at 120° C. for 2 hours to manufacture a color conversion film.

### Manufacturing Example 4-2

A color conversion film was manufactured in the same manner as in Manufacturing Example 4-1, except that no TiO₂ solution was used.

### Manufacturing Example 4-3

A color conversion film was manufactured in the same manner as in Manufacturing Example 4-1, except that 0.19 mL of organic nanoparticles and 0.10 mL of a TiO₂ solution were mixed with the aqueous PVA-SA solution (15 wt %, 1.0 mL).

### Manufacturing Example 4-4

A color conversion film was manufactured in the same manner as in Manufacturing Example 4-1, except that 0.19 mL of organic nanoparticles and 0.17 mL of aTiO₂ solution were mixed with the aqueous PVA-SA solution (15 wt %, 1.0 mL).

### Manufacturing Example 4-5

A color conversion film was manufactured in the same manner as in Manufacturing Example 4-1, except that 0.35 mL of organic nanoparticles and 0.18 mL of a TiO₂ solution were mixed with the aqueous PVA-SA solution (15 wt %, 1.0 mL).

### Manufacturing Example 4-6

A color conversion film was manufactured in the same manner as in Manufacturing Example 4-1, except that 0.46 mL of organic nanoparticles and 0.18 mL of a TiO₂ solution were mixed with the aqueous PVA-SA solution (15 wt %, 1.0 mL).

### Experimental Example 8: Comparison of Optical Properties According to Light Scattering Agent

The color conversion films of Manufacturing Example 4 were excited using a blue LED having an emission wavelength of 450 nm as an excitation light source to measure a blue light reduction rate and CCE. Results of the measurement are shown in Table 8 below. A method of measuring the CCE is as described in Experimental Example 5, and a method of measuring the blue light reduction rate will be described in detail with reference to FIG. 6. In FIG. 6, the blue light-emitting area A corresponds to blue incident light absorbed by the color conversion film, and coincides with the blue light reduction rate.

TABLE 8

| | Organic | | | Blue light | |
|---|---|---|---|---|---|
| | nanoparticles | TiO₂ | Thickness | reduction | CCE |
| | (wt %) | (wt %) | (μm) | rate (%) | (%) |
| Manufacturing | 2 | 1.93 | 14.50 | 24.00 | 64 |
| Example 4-1 | | | | | |
| Manufacturing | 2 | — | 15.00 | 18.64 | 34 |
| Example 4-2 | | | | | |
| Manufacturing | 4.5 | 3.5 | 15.00 | 20.25 | 69 |
| Example 4-3 | | | | | |
| Manufacturing | 4.5 | 6.0 | 15.50 | 34.35 | 51 |
| Example 4-4 | | | | | |

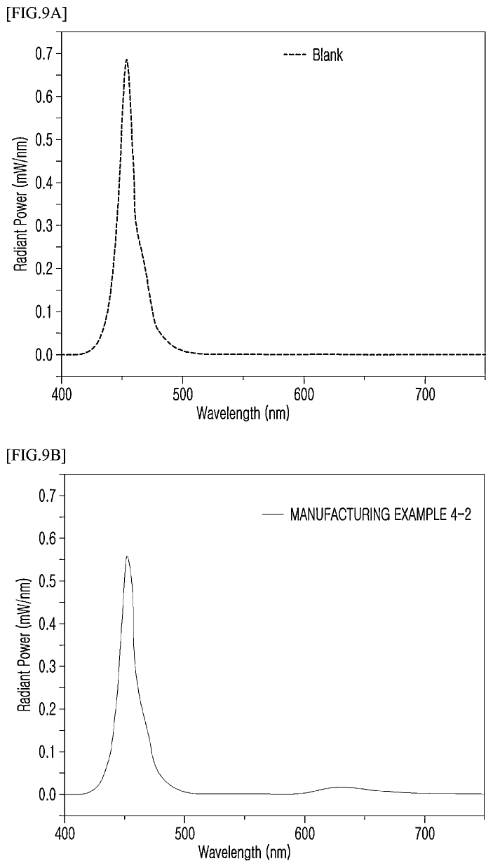

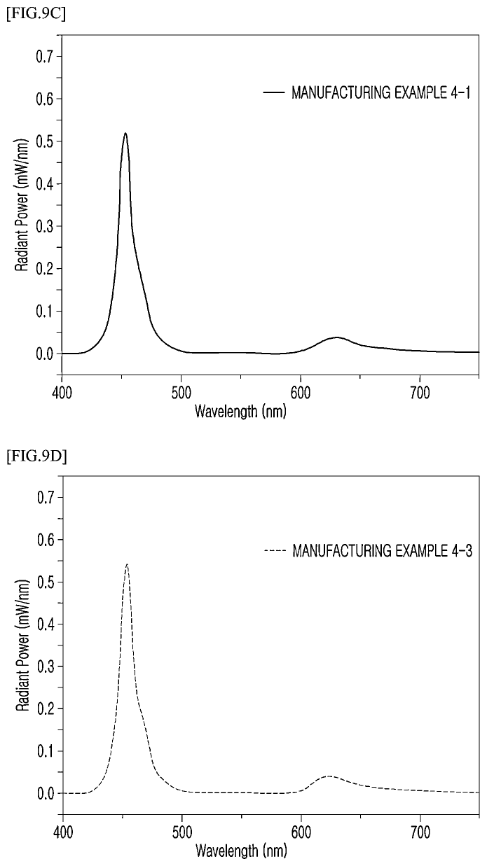

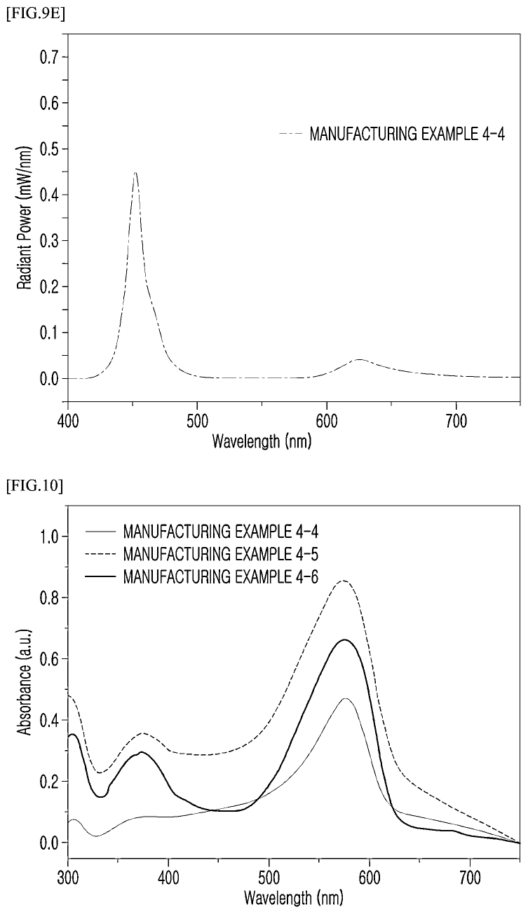

FIG. 8 is a graph showing the emission intensity according to wavelength of the color conversion films of Manufacturing Examples 4-1 to 4-4, and FIGS. 9A to 9E are graphs showing the radiant power according to wavelength of the color conversion films of Manufacturing Examples 4-1 to 4-4. As confirmed in Table 8 and FIGS. 8 and 9A to 9E, the light scattering agent generates a light scattering effect to increase light absorption efficiency, and as a result, the CCE is improved. Under the same conditions, the CCE of Manufacturing Example 4-1 in which TiO₂ was used improved about 1.9 times compared to that of Manufacturing Example 4-2 in which no TiO₂ was used. Further, under the same conditions, the blue light reduction rate of Manufacturing Example 4-1 in which TiO₂ was used improved about 1.3 times compared to that of Manufacturing Example 4-2 in which no TiO₂ was used.

### Experimental Example 9: Comparison of Optical Properties According to Lamination of Color Conversion Film

For the color conversion films of Manufacturing Example 4, when one color conversion film is formed as a single layer (1L) and when two color conversion films are laminated (2L), the blue light reduction rate and CCE were measured. Results of the measurement are shown in Table 9 below. In Table 9 below, 1L represents a case in which one color conversion film is formed as a single layer, and 2L represents a case in which two color conversion films are laminated.

TABLE 9

| | | | | 1L | | 2L | |
|---|---|---|---|---|---|---|---|
| | Organic | | | Blue light | | Blue light | |
| | nanoparticles | TiO₂ | PLQY | reduction | CCE | reduction | CCE |
| | (wt %) | (wt %) | (λₑₓ = 44O) | rate (%) | (%) | rate (%) | (%) |
| Manufacturing | 4.5 | 6.0 | 0.73 | 34.35 | 51.00 | 49.00 | 45.14 |
| Example 4-4 | | | | | | | |
| Manufacturing | 8.0 | 6.0 | 0.35 | 35.00 | 64.00 | 76.07 | 48.15 |
| Example 4-5 | | | | | | | |
| Manufacturing | 10.0 | 6.0 | 0.27 | 27.94 | 67.70 | 55.77 | 65.15 |
| Example 4-6 | | | | | | | |

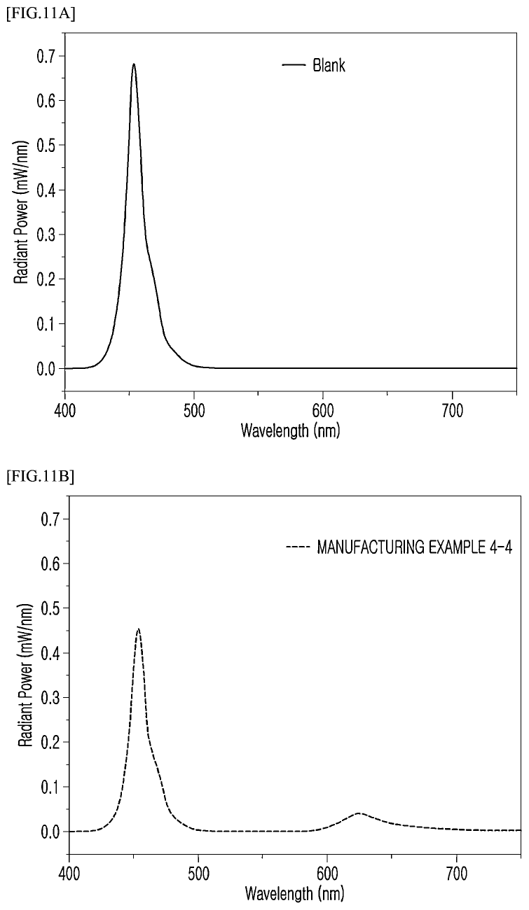

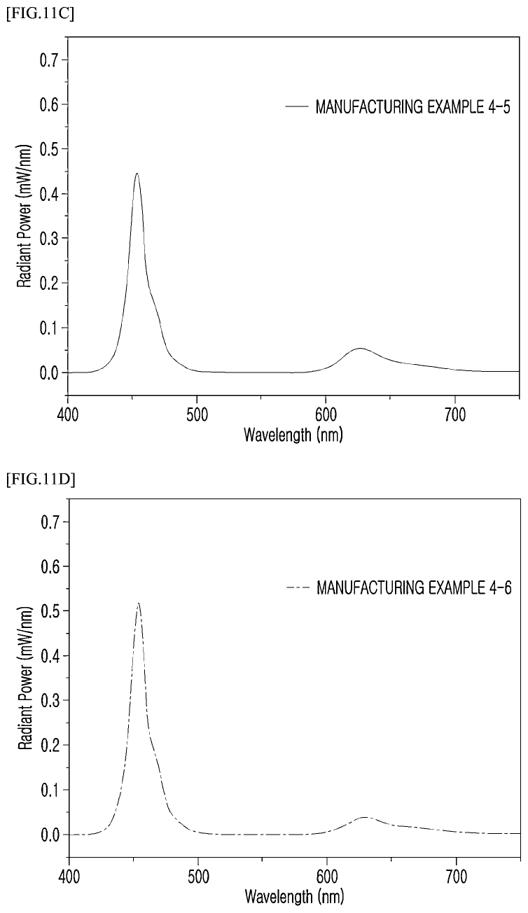

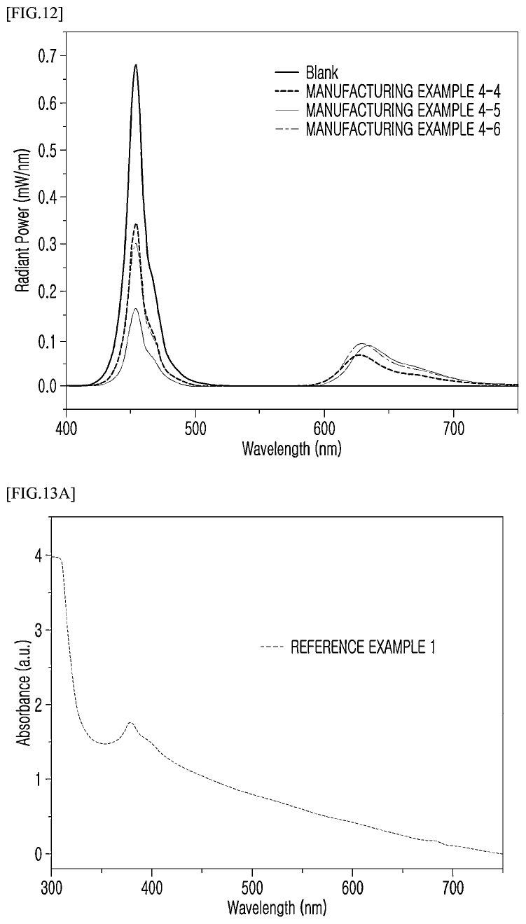

FIG. 10 is a graph showing the absorbance of the color conversion films of Manufacturing Examples 4-4 to 4-6, FIGS. 11A to 11D are graphs showing the radiant power of films made of a single layer of the respective color conversion films of Manufacturing Examples 4-4 to 4-6, and FIG. 12 is a graph showing the radiant power of films manufactured by laminating two color conversion films of Manufacturing Examples 4-4 to 4-6. As confirmed in Table 9, when the content of the organic nanoparticles was increased in the state in which the content of the light scattering agent was fixed at 6.0%, the CCE increased, and the CCE was slightly lowered when the laminated layers 2L were formed compared to when the single layer 1L was formed. However, the blue light reduction rate showed a better reduction rate when the laminated layers 2L were formed compared to when the single layer 1L was formed. When the content of organic nanoparticles was 8.0 wt % in both the single layer 1L and the laminated layers 2L, the blue light blocking effect was most excellent.

### Experimental Example 10: Comparison of Light Emission Properties and Color Conversion Film Properties with Those of Commercial Color Conversion Films

The light emission properties and color conversion film properties of the color conversion film of Manufacturing Example 4-5 and the light emission properties and color conversion film properties of IS22E73001 (hybrid, Reference Example 1), IS22E131003 (hybrid, Reference Example 2), and IS22E273002 (InP, Reference Example 3), which are commercial quantum dot films sold by Inno QD Co., Ltd., were measured. Results of the measurement are shown in Tables 10 and 11 below.

TABLE 10

| | | | Maximum emission | | | |
|---|---|---|---|---|---|---|
| | | Thickness | wavelength (nm) | | FWHM (nm) | |
| | | (μm) | Green | Red | Green | Red |
| Manufacturing Example 4-5 | | 20 | — | 622 | — | 41 |
| Reference | Measurement | 300 | 532 | 629 | 22 | 41 |
| Example 1 | value | | | | | |
| | Manufacturer | 309 | 537 | 629 | 23 | 43 |
| | measurement | | | | | |
| | value | | | | | |
| Reference | Measurement | 190 | 532 | 629 | 23 | 40 |
| Example 2 | value | | | | | |
| | Manufacturer | 200 | 538 | 629 | 23 | 43 |
| | measurement | | | | | |
| | value | | | | | |
| Reference | Measurement | 280 | 536 | 633 | 36 | 33 |
| Example 3 | value | | | | | |
| | Manufacturer | 285 | 544 | 633 | 39 | 36 |
| | measurement | | | | | |
| | value | | | | | |

TABLE 11

| | | Blue light | Green emission | Red emission |
|---|---|---|---|---|
| | CCE | reduction | intensity | intensity |
| | (%) | rate (%) | (%) | (%) |
| Manufacturing | 64.00 | 35.00 | — | 8.16 |
| Example 4-5 | | | | |
| Reference | 70.20 | 45.46 | 13.13 | 5.98 |
| Example 1 | | | | |
| Reference | 75.34 | 45.64 | 13.53 | 5.70 |
| Example 2 | | | | |
| Reference | 64.28 | 50.10 | 7.89 | 7.06 |
| Example 3 | | | | |

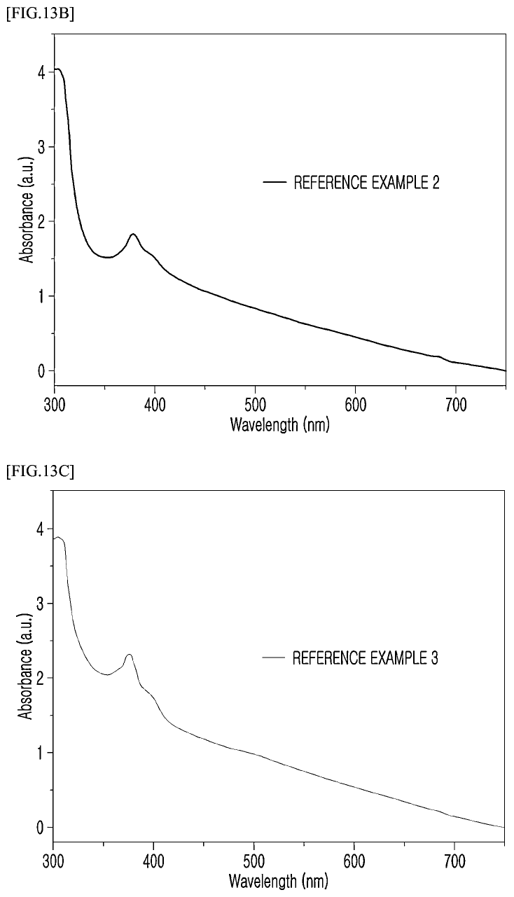

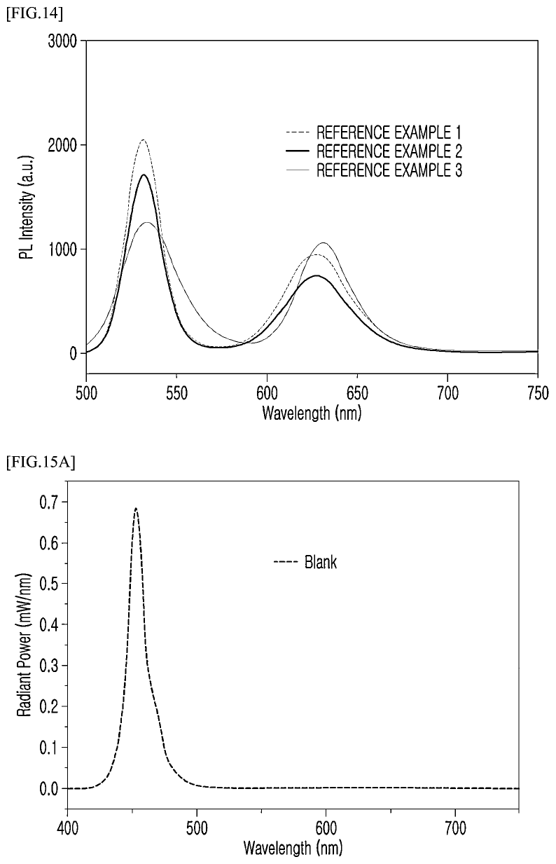

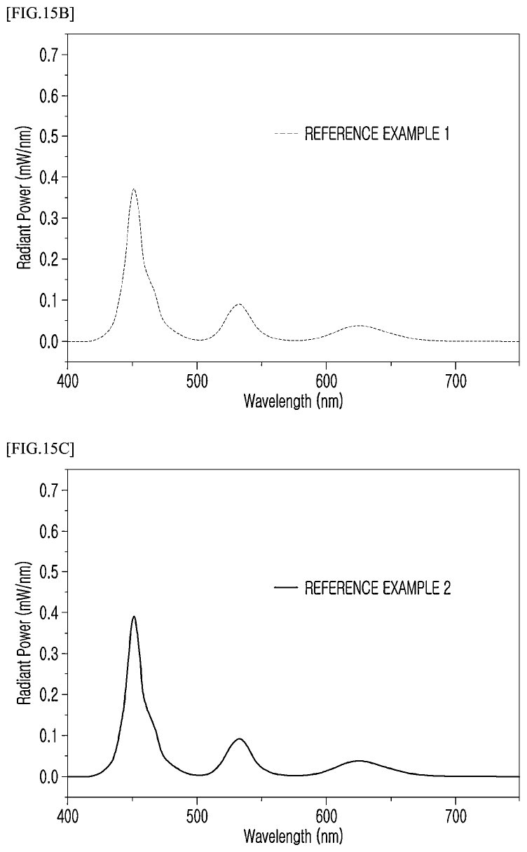

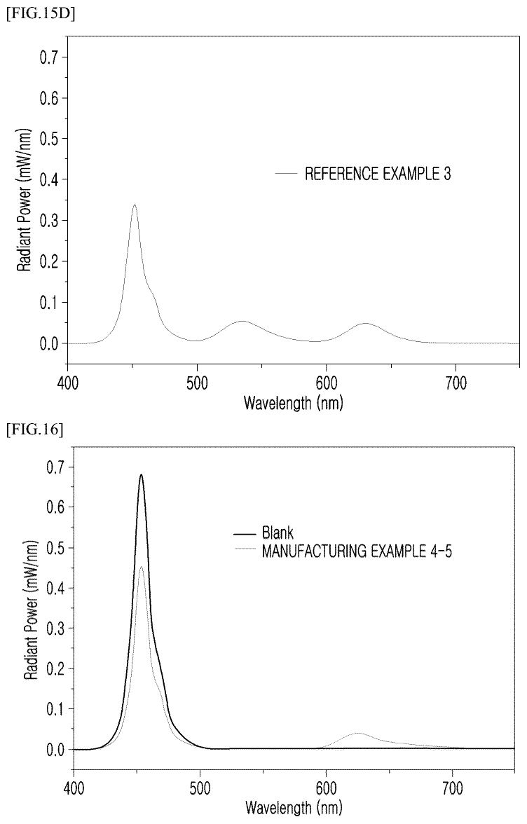

FIGS. 13A to 13C are graphs showing the absorbance of color conversion films of Reference Examples 1 to 3, FIG. 14 is a graph showing the photoluminescence intensity of the color conversion films of Reference Examples 1 to 3, FIGS. 15A to 15D are graphs showing the radiant intensity of the color conversion films of Reference Examples 1 to 3, and FIG. 16 is a graph showing the radiant power of the color conversion film of Manufacturing Example 4-5. From Tables 10 and 11 and FIGS. 13A to 16, it can be seen that the color conversion films according to the present invention may be formed with a very thin thickness compared to the commercial films. In particular, in the case of the commercial film, the commercial film uses a quantum dot material, and thus a barrier film is applied because the commercial film is weak against oxygen and moisture, and as a result, there is a certain limit in reducing the film thickness.

As confirmed in Tables 10 and 11, the color conversion films according to the present invention exhibited a high blue light blocking rate of 35% despite being formed in a thin thickness, and also exhibited relatively high red emission intensity.

Further, as confirmed in Table 11, the color conversion films manufactured according to the present invention exhibit a similar level of red FWHM and similar CCE to those of Reference Example 3, which is a commercial film formed of a quantum dot material.

### Experimental Example 11: Comparison of Constant Temperature and Humidity Properties with Those of Commercial Color Conversion Films

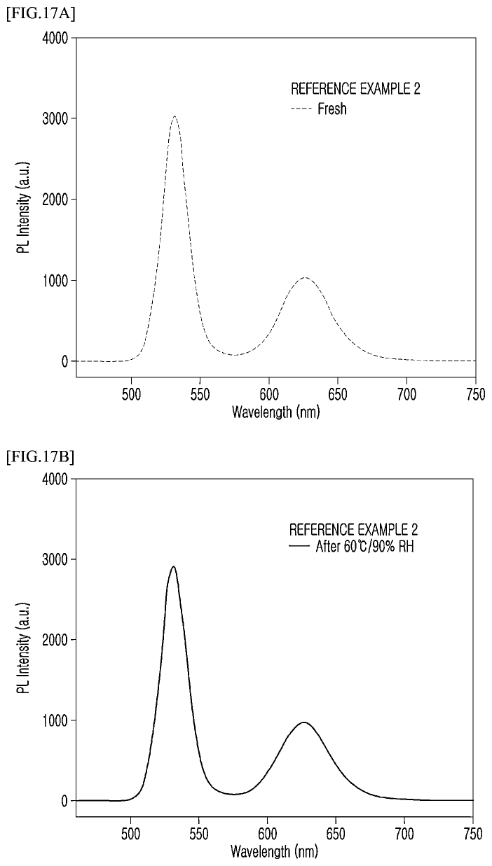

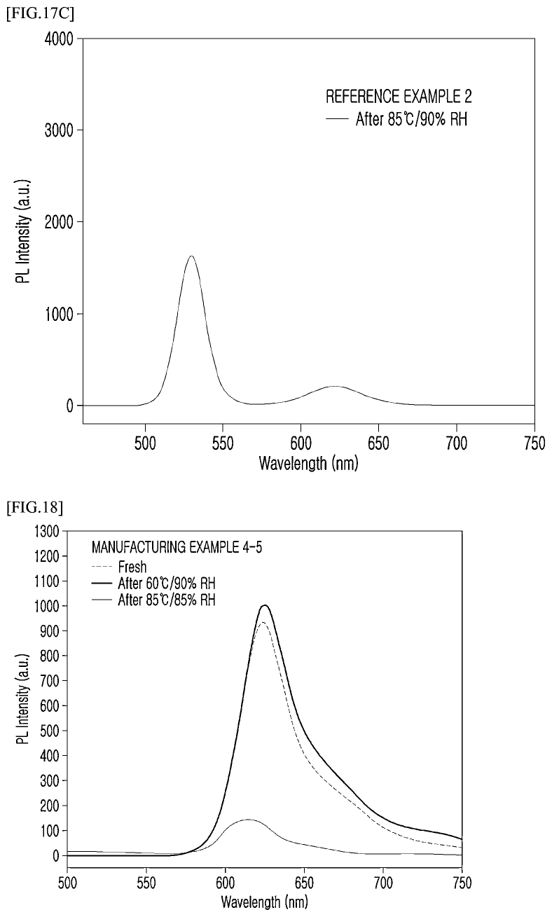

In order to evaluate the constant temperature and humidity properties, the color conversion films were exposed to a 90% relative humidity (RH) and 60° C. environment for 480 hours and then photoluminescence intensity was measured, and the color conversion films were exposed to an 85% RH and 85° C. environment for 480 hours and then photoluminescence intensity was measured. Results of the measurement are shown in FIGS. 17A, 17B, 17C and 18. Specifically, FIGS. 17A to 17C are graphs showing the results of constant temperature and humidity evaluation for the color conversion film of Reference Example 2, and FIG. 18 is a graph showing the results of constant temperature and humidity evaluation for the color conversion film of Manufacturing Example 4-5.

From FIGS. 17A, 17B, 17C and 18, it can be seen that the color conversion film according to the present invention was formed in a very thin thickness and exhibited constant temperature and humidity properties equal to or similar to those of Reference Example 2 to which a barrier film was applied, even when no barrier film is applied.

### Experimental Example 12: Comparison of Light Resistance Properties with Those of Commercial Color Conversion Films

In order to evaluate light resistance, the color conversion films were exposed to UV light for an additional 312 hours from the state in which the color conversion films were exposed to UV light for 168 hours, and then photoluminescence intensity was measured and the amount of reduction was compared.

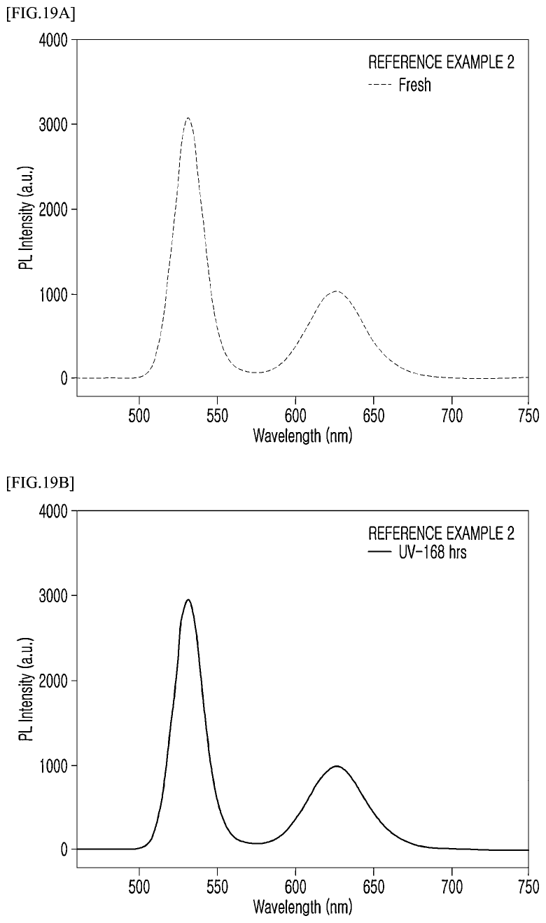

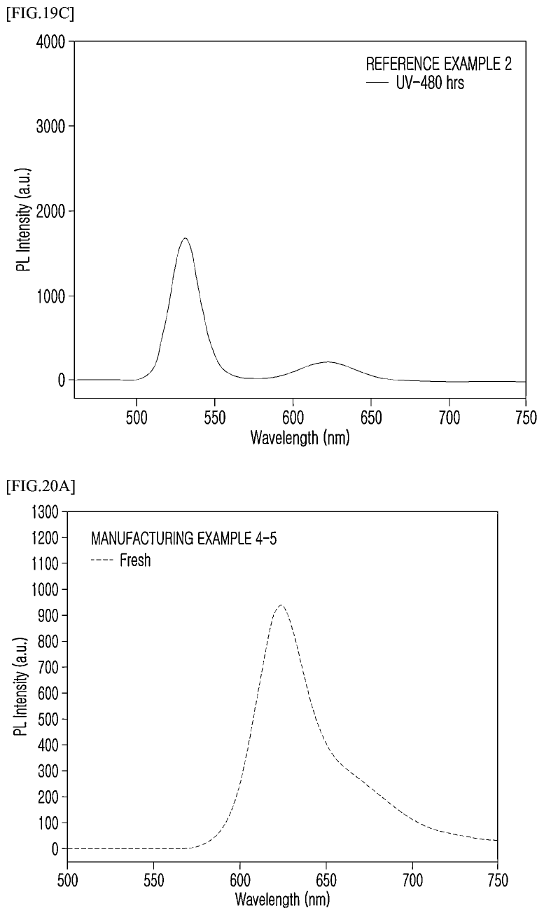

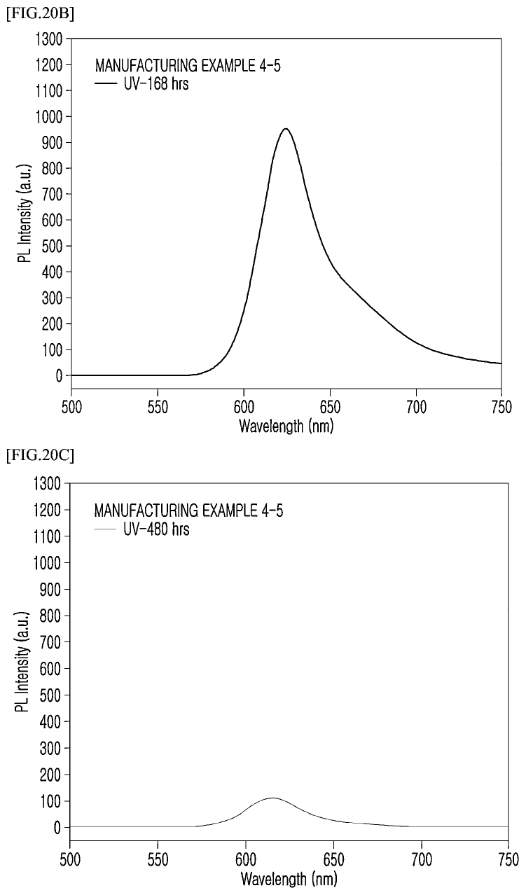

FIGS. 19A to 19C are graphs showing the results of light resistance evaluation for the color conversion film of Reference Example 2, and FIGS. 20A to 20C are graphs showing the results of light resistance evaluation for the color conversion film of Manufacturing Example 4-5.

From FIGS. 19A to 19C and 20A to 20C, it can be seen that the color conversion film according to the present invention exhibited high light resistance for about 200 hours even when the color conversion film was formed with a very thin thickness.

### Manufacturing Example 5: Manufacture of Color Conversion Film (3)

### Manufacturing Example 5-1

PVA and SA were mixed in deionized water at a weight ratio of 49:1 to prepare an aqueous 20 wt % polyvinyl alcohol solution (PVA-SA, 20 wt %), and then heated at 80° C. for 3 hours. The tPhBODIPY organic nanoparticles (2.13 wt % dispersion, 0.10 mL) of Manufacturing Example 1-5 and a TiO₂ solution (15.0 wt % aqueous solution, 0.01 mL) were mixed with the aqueous PVA-SA solution (20.0 wt %, 0.51 mL). The mixed solution was sprayed on a glass substrate and then a film was formed by a bar coating method. In order to remove the solvent, the formed film was kept in an oven at 60° C. for 4 hours, and a crosslinking reaction was carried out at 120° C. for 2 hours to manufacture a color conversion film.

### Manufacturing Example 5-2

A color conversion film was manufactured in the same manner as in Manufacturing Example 5-1, except that 0.12 mL of organic nanoparticles and 0.017 mL of a TiO₂ solution were mixed with the aqueous PVA-SA solution (20.0 wt %, 0.5 mL).

### Manufacturing Example 5-3

A color conversion film was manufactured in the same manner as in Manufacturing Example 5-1, except that 0.16 mL of organic nanoparticles and 0.033 mL of a TiO₂ solution were mixed with the aqueous PVA-SA solution (20.0 wt %, 0.51 mL).

### Manufacturing Example 5-4

A color conversion film was manufactured in the same manner as in Manufacturing Example 5-1, except that 0.23 mL of organic nanoparticles and 0.04 mL of a TiO₂ solution were mixed with the aqueous PVA-SA solution (20.0 wt %, 0.51 mL).

### Manufacturing Example 5-5

A color conversion film was manufactured in the same manner as in Manufacturing Example 5-1, except that 0.32 mL of organic nanoparticles and 0.05 mL of a TiO₂ solution were mixed with the aqueous PVA-SA solution (20.0 wt %, 0.6 mL).

### Experimental Example 13: Comparison of Optical Properties

The blue light reduction rate and the CCE of the color conversion films of Manufacturing Example 5 were measured. Results of the measurement are shown in Table 12 below.

TABLE 12

| | | Organic | | Blue light | |
|---|---|---|---|---|---|
| | | nanoparticles | TiO₂ | reduction | CCE |
| | | (wt %) | (wt %) | rate (%) | (%) |
| Manufacturing | 1L | 2.0 | 1.4 | 39.34 | 92.0 |
| Example 5-1 | | | | | |
| Manufacturing | 1L | 2.4 | 2.4 | 54.4 | 78.4 |
| Example 5-2 | | | | | |
| Manufacturing | 1L | 3.1 | 4.5 | 59.7 | 78.0 |
| Example 5-3 | | | | | |
| Manufacturing | 1L | 4.1 | 5.0 | 63.5 | 73.0 |
| Example 5-4 | 2L | | | 78.6 | 66.0 |
| Manufacturing | 1L | 5.1 | 5.6 | 74.2 | 64.2 |
| Example 5-5 | 2L | | | 78.6 | 65.9 |

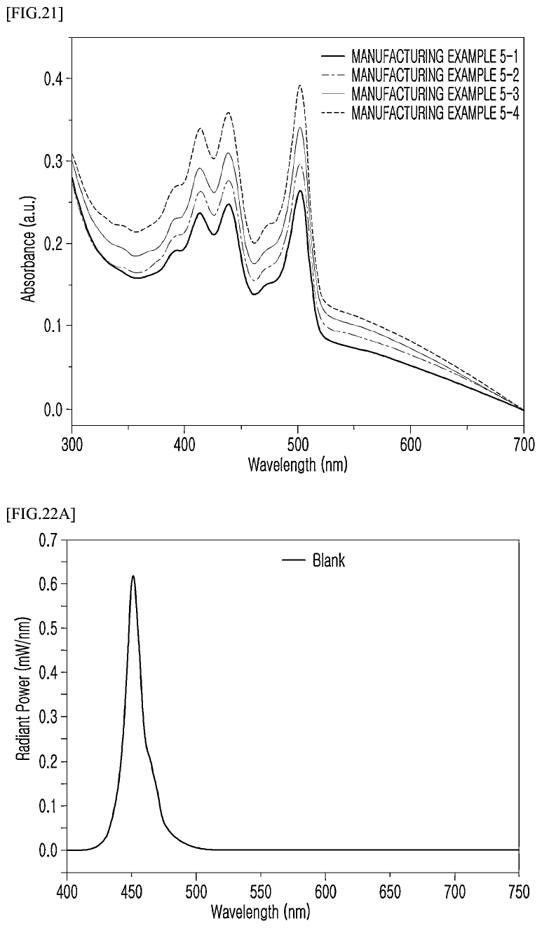

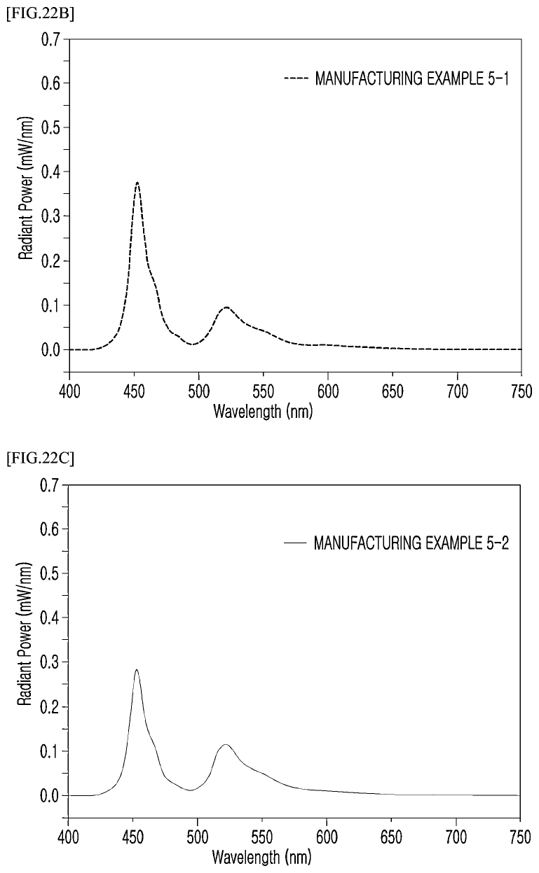

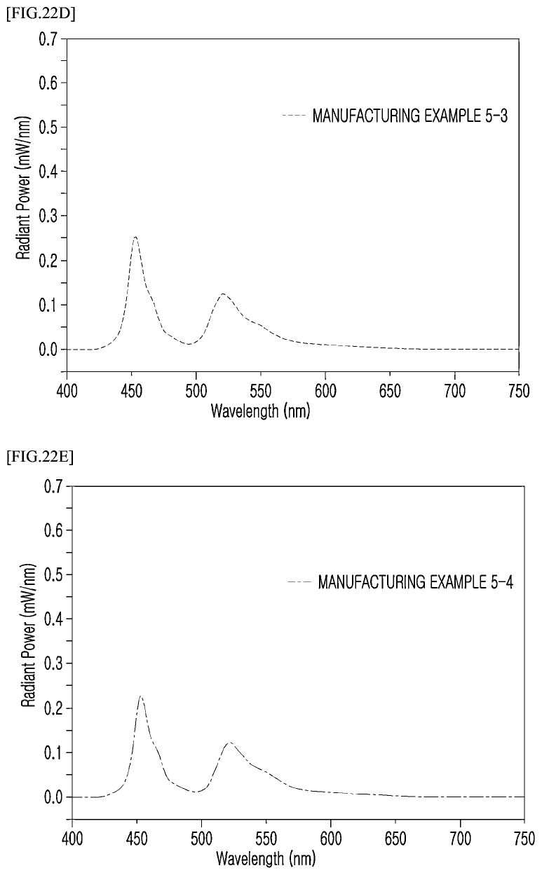

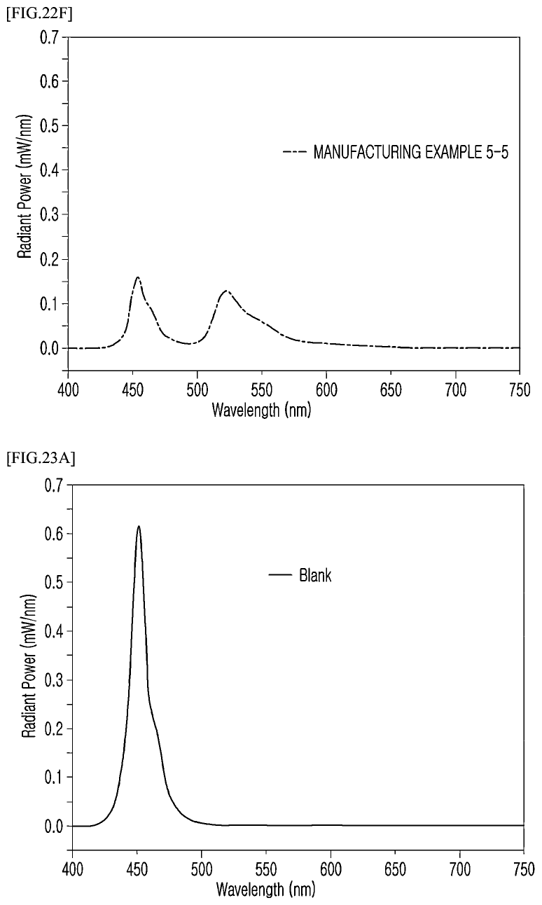

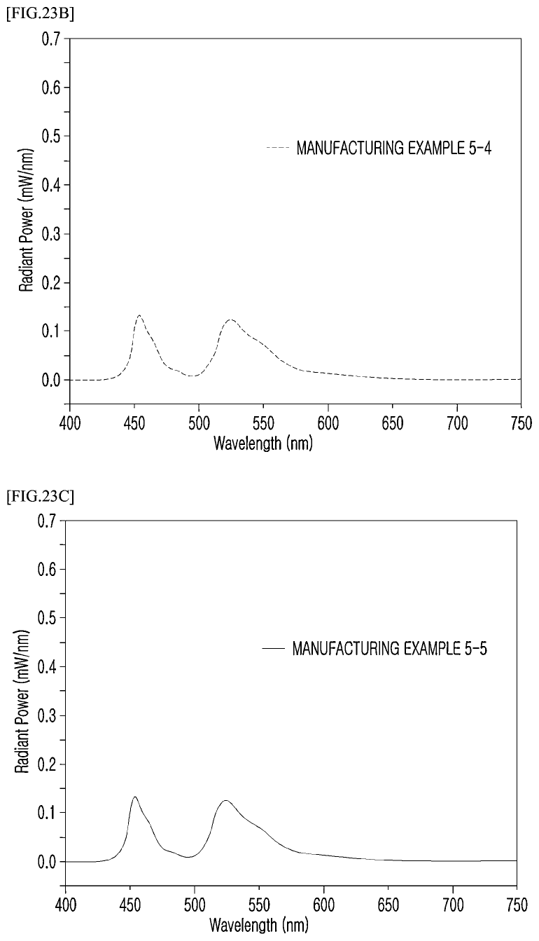

FIG. 21 is a graph showing the absorbance of the color conversion films of Manufacturing Examples 5-1 to 5-4, FIGS. 22A to 22F are graphs showing the radiant power of films made of a single layer of the respective color conversion films of Manufacturing Examples 5-1 to 5-5, and FIGS. 23A to 23C are graphs showing the radiant power of films manufactured by laminating two color conversion films of Manufacturing Examples 5-4 and 5-5.

Referring to Table 12, in the case of a green film, the highest CCE (92%) is shown in the case of Manufacturing Example 5-1 in which 2.0 wt % of organic nanoparticles and 1.4 wt % of TiO₂ were used. Referring to Manufacturing Examples 5-4 and 5-5, it can be seen that when a double layer was used like a red film, the CCE was slightly reduced, but the blue light reduction rate increased to 78.6%. It can be seen that, since an OLED or a micro-LED using red-green-blue (RGB) tricolor light had its own blue light, the color conversion films of the present invention may be applied for various purposes as necessary in consideration that it is better to reduce excitation blue light so that it remains small and it is better to have about 50% of blue light remaining in a LCD using the blue LED.

According to the present invention, it is possible to provide a color conversion film having excellent photochemical stability, high color conversion efficiency, high heat resistance, high film hardness, high uniformity, and long-lasting performance using light-emitting organic nanoparticles. In particular, light-emitting organic nanoparticles that do not use quantum dots are used in the color conversion film of the present invention, and thus environmental pollution problems can be prevented from occurring.

Effects of the present invention are not limited to the above-described effects, and it should be understood that all possible effects deduced from the configuration of the present invention described in detailed descriptions and the claims are included.

The above description of this specification is only exemplary, and it will be understood by those skilled in the art to which one aspect of this specification pertains that various modifications can be made without departing from the technical scope of the present invention and without changing essential features described in this specification. Therefore, the above-described embodiments should be considered in a descriptive sense only and not for purposes of limitation. For example, each component described as a single type may be implemented in a distributed manner, and similarly, components that are described as being distributed may be implemented in a coupled manner.

The scope of the present invention is defined not by the detailed description but by the appended claims and encompasses all modifications or alterations derived from meanings, the scope, and equivalents of the appended claims.

What is claimed is:

1. Light-emitting organic nanoparticles containing an organic phosphor having a luminous efficiency of 80% or more,
wherein the light-emitting organic nanoparticles has an average particle size of 100 to 170 nm and a standard deviation of particle sizes of 500 nm or less.

2. The light-emitting organic nanoparticles of claim 1, wherein the light-emitting organic nanoparticles have a core-shell structure in which the organic phosphor is surrounded by a surfactant.

3. The light-emitting organic nanoparticles of claim 1, wherein the organic phosphor is a delayed fluorescence material.

4. The light-emitting organic nanoparticles of claim 3, wherein the delayed fluorescence material includes a compound represented by Chemical Formula 1 below: 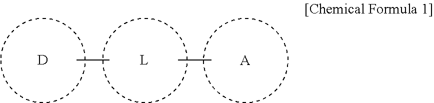
(In Chemical Formula 1 above,
L is any one selected from the group consisting of an aryl group, an arylene group, and a carbon-nitrogen single bond,
when L is an aryl group, A is a cyano group mono- or di-substituted on the aryl group, and D is a substituent tetra- or penta-substituted on the aryl group, wherein each substituent is independently a heteroaryl group containing a nitrogen atom substituted or unsubstituted with a heteroaryl group having 1 to 10 carbon atoms,
when L is an arylene group, A is a substituted or unsubstituted triazine group, and D is a substituted or unsubstituted multi-fused ring, including a conjugated or non-conjugated five-membered or six-membered ring containing a nitrogen atom bonded to the arylene group, wherein the multi-fused ring may further comprise 1 to 9 nitrogen atoms or one Group 16 element as ring-forming elements, in addition to the nitrogen atom boned to the arylene group,
when L is a carbon-nitrogen single bond, D is a fused ring having 10 to 40 carbon atoms, including a conjugated or non-conjugated five-membered or six-membered ring containing the nitrogen atom of the L, wherein the conjugated or non-conjugated five-membered or six-membered ring is a substituted or unsubstituted ring, does not contain or contains a Group 16 element as ring-forming elements, and contains 1 or 2 nitrogen atoms as ring-forming elements, and A is a heterocyclic ring having 10 to 40 carbon atoms, including an aryl group containing a carbon atom bonded to the L, wherein the heterocyclic ring includes a ring structure forming a fused ring with the aryl group containing a carbon atom bonded to the L, and wherein the ring structure is a ring structure containing a boron atom and an oxygen atom as ring-forming elements, or is a five-membered or six-membered ring structure containing two conjugated nitrogen atoms).

5. The light-emitting organic nanoparticles of claim 4, wherein the compound represented by Chemical Formula 1 above is one or more selected from the group consisting of compounds T-1 to T-28 below:

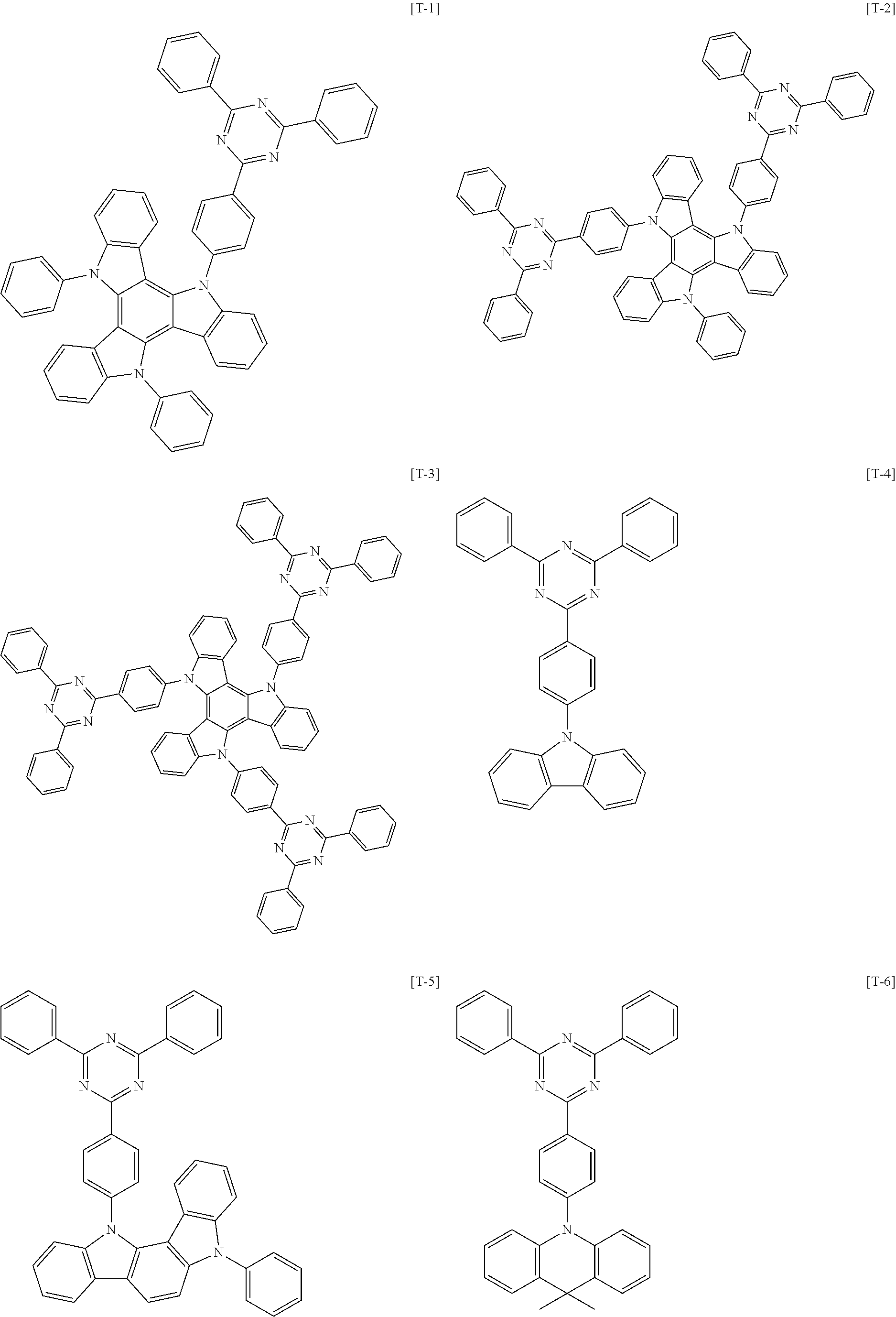

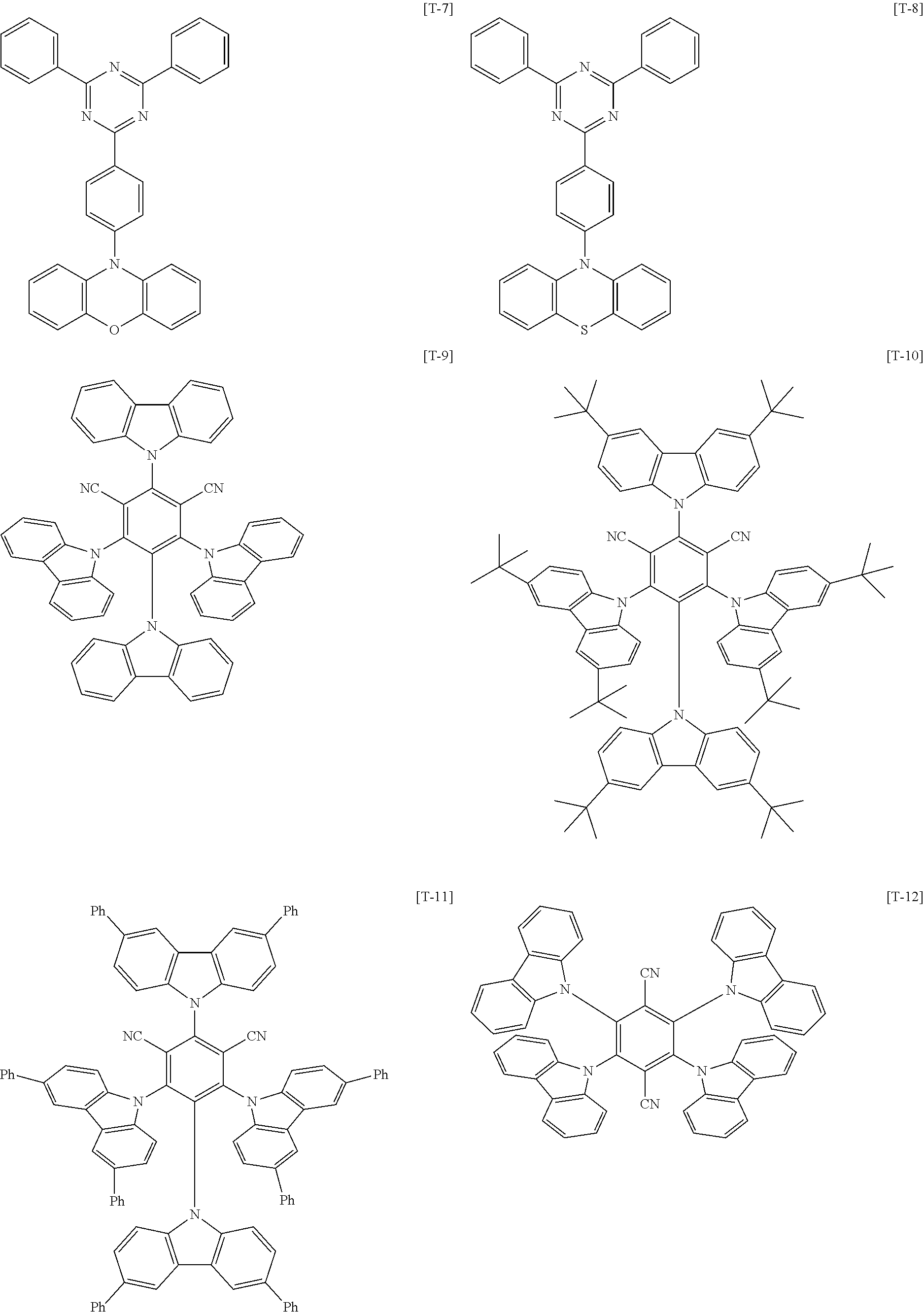

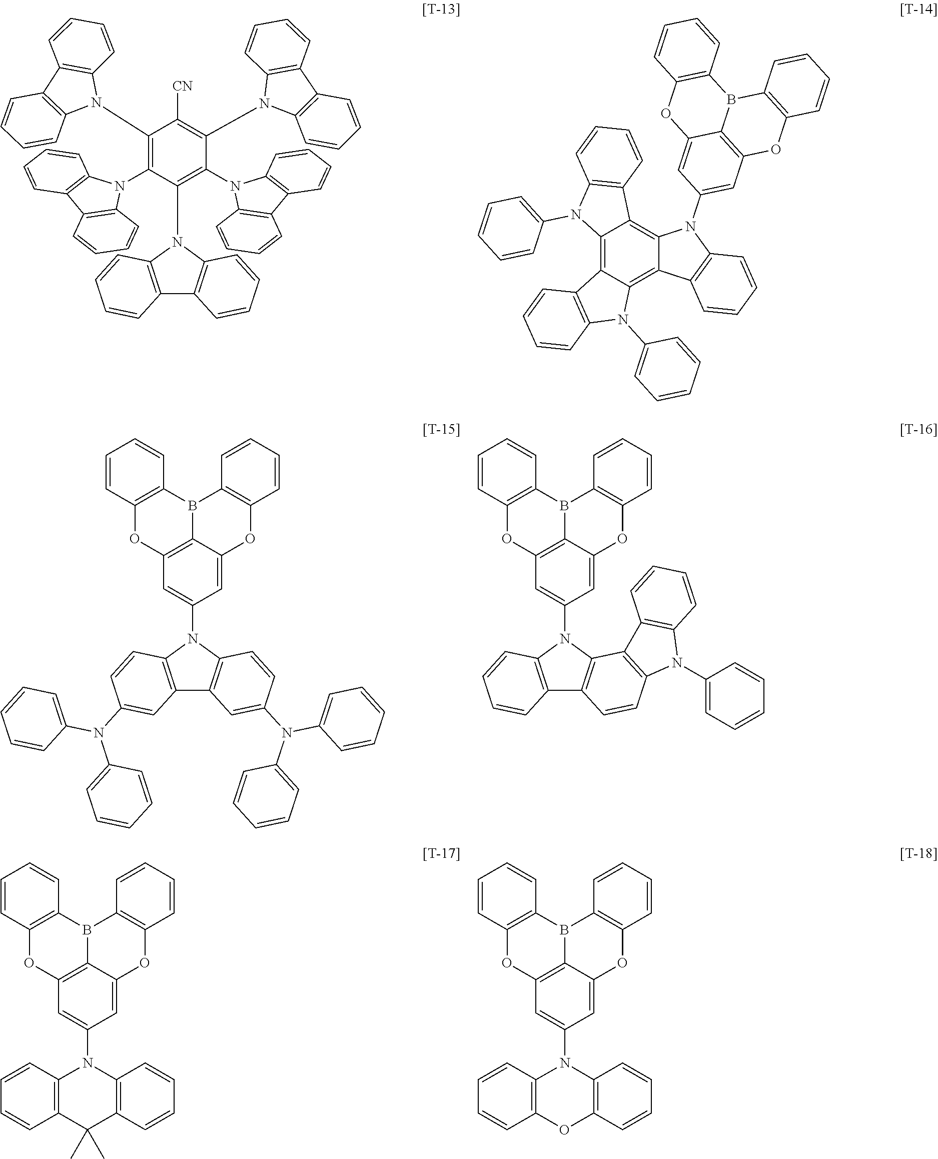

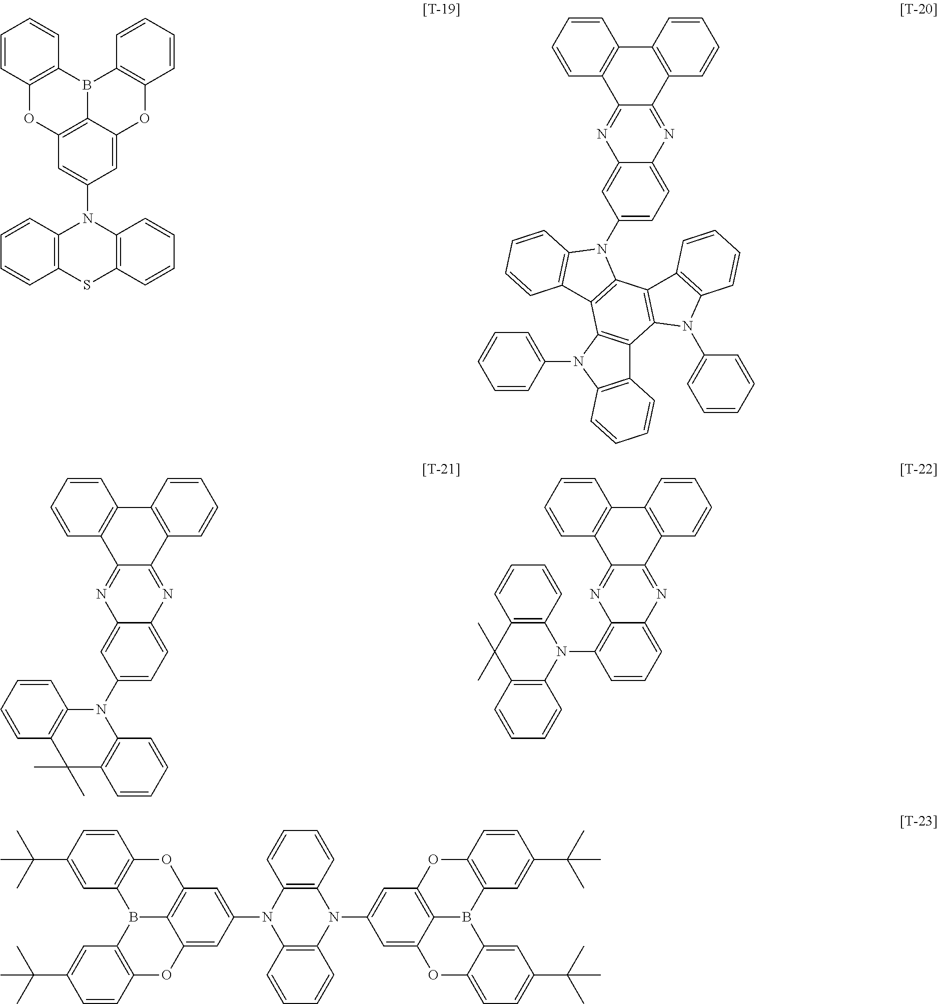

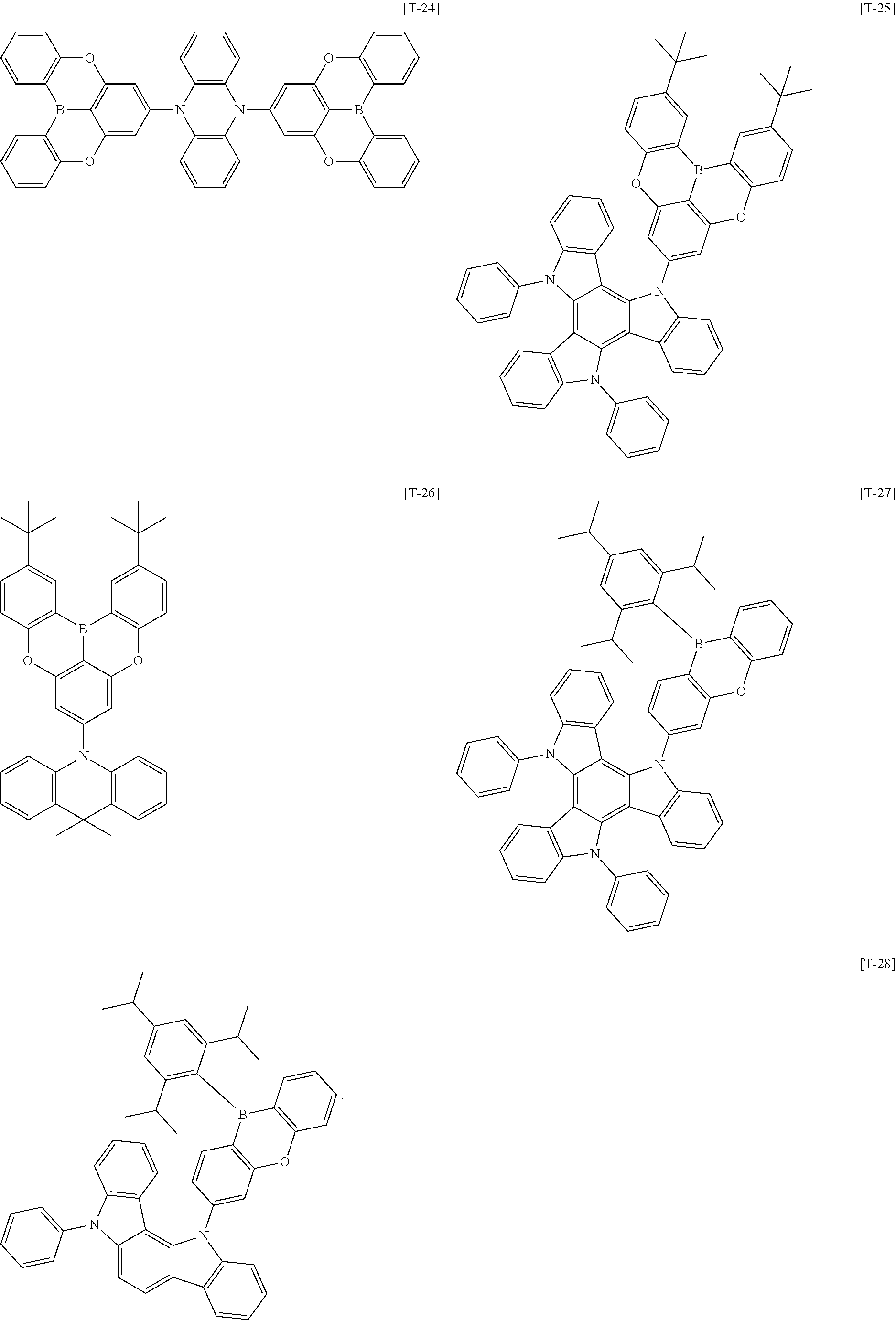

6. The light-emitting organic nanoparticles of claim 1, wherein the organic phosphor includes a boron compound represented by Chemical Formula 2 below: 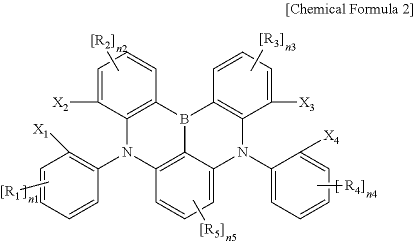
(In Chemical Formula 2 above, R₁ to R₅ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group,
X₁ to X₄ are each independently hydrogen, hydroxyl group or a substituted or unsubstituted alkyl group,
n1 and n4 are each independently an integer of 1 to 4,
n2, n3 and n5 are each independently an integer of 1 to 3,
if n1 to n5 are 2 or more, the structures in the brackets, are the same or different, respectively,
R₁ to R₅ and X₁ to X₄ may bond to adjacent substituents to form a substituted or unsubstituted ring).

7. The light-emitting organic nanoparticles of claim 6, wherein the boron compound represented by Chemical Formula 2 above is one or more selected from the group consisting of compounds D-1 to D-30 below:

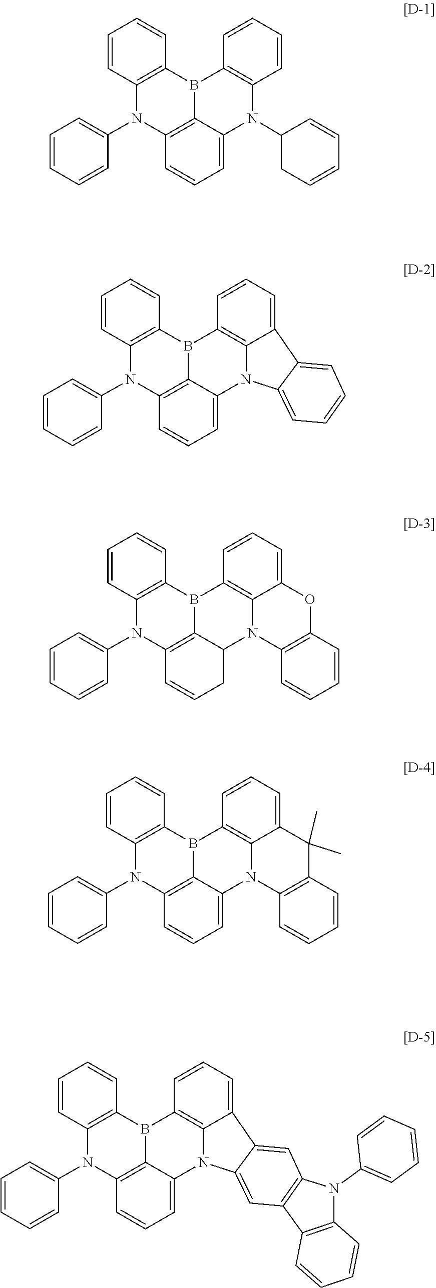 [SMILES: C1=CCC(N2c3ccccc3B3c4ccccc4N(c4ccccc4)c4cccc2c43)C=C1 ; c1ccc(N2c3ccccc3B3c4c2cccc4-n2c4ccccc4c4cccc3c42)cc1 ; C1=CC2=C3B(c4ccccc4N2c2ccccc2)c2cccc4c2N(c2ccccc2O4)C3C1 ; CC1(C)c2ccccc2N2c3cccc4c3B(c3ccccc3N4c3ccccc3)c3cccc1c32 ; c1ccc(N2c3ccccc3B3c4c2cccc4-n2c4cc5c6ccccc6n(-c6ccccc6)c5cc4c4cccc3c42)cc1]

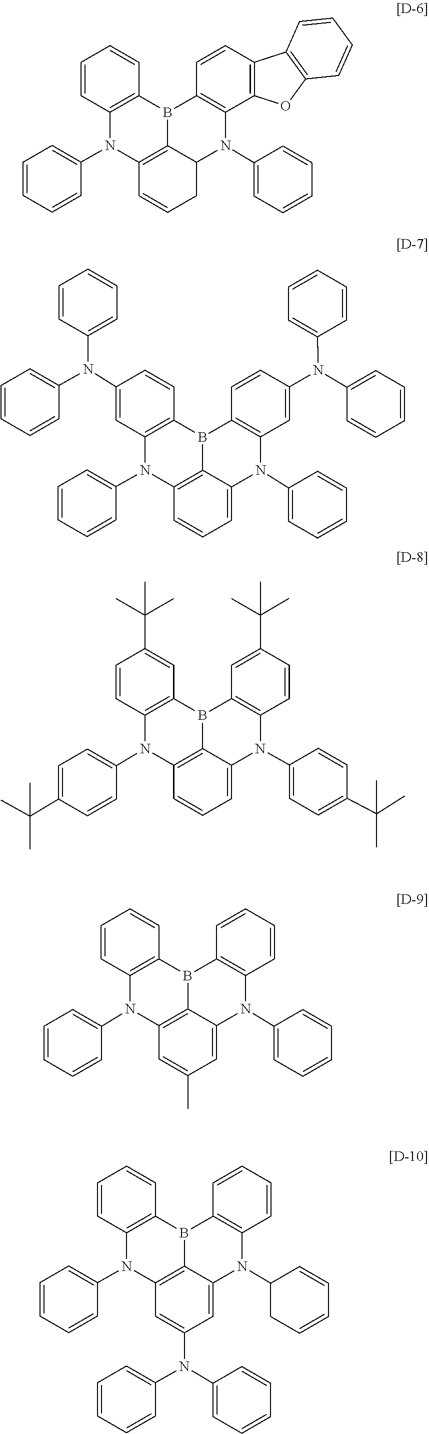 [SMILES: C1=CC2=C3B(c4ccccc4N2c2ccccc2)c2ccc4c(oc5ccccc54)c2N(c2ccccc2)C3C1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1 ; Cc1cc2c3c(c1)N(c1ccccc1)c1ccccc1B3c1ccccc1N2c1ccccc1 ; C1=CCC(N2c3ccccc3B3c4ccccc4N(c4ccccc4)c4cc(N(c5ccccc5)c5ccccc5)cc2c43)C=C1]

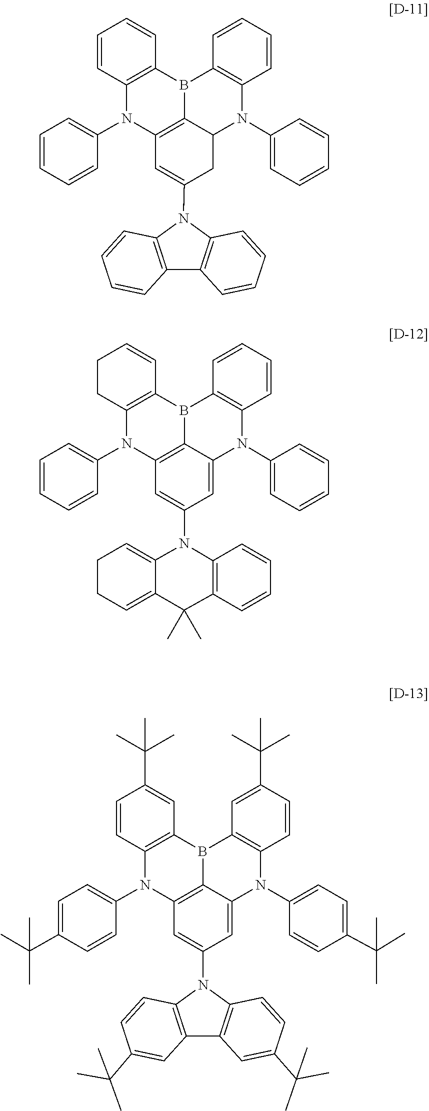 [SMILES: C1=C(n2c3ccccc3c3ccccc32)CC2C3=C1N(c1ccccc1)c1ccccc1B3c1ccccc1N2c1ccccc1 ; CC1(C)C2=CCCC=C2N(c2cc3c4c(c2)N(c2ccccc2)c2ccccc2B4C2=C(CCC=C2)N3c2ccccc2)c2ccccc21 ; CC(C)(C)c1ccc(N2c3ccc(C(C)(C)C)cc3B3c4cc(C(C)(C)C)ccc4N(c4ccc(C(C)(C)C)cc4)c4cc(-n5c6ccc(C(C)(C)C)cc6c6cc(C(C)(C)C)ccc65)cc2c43)cc1]

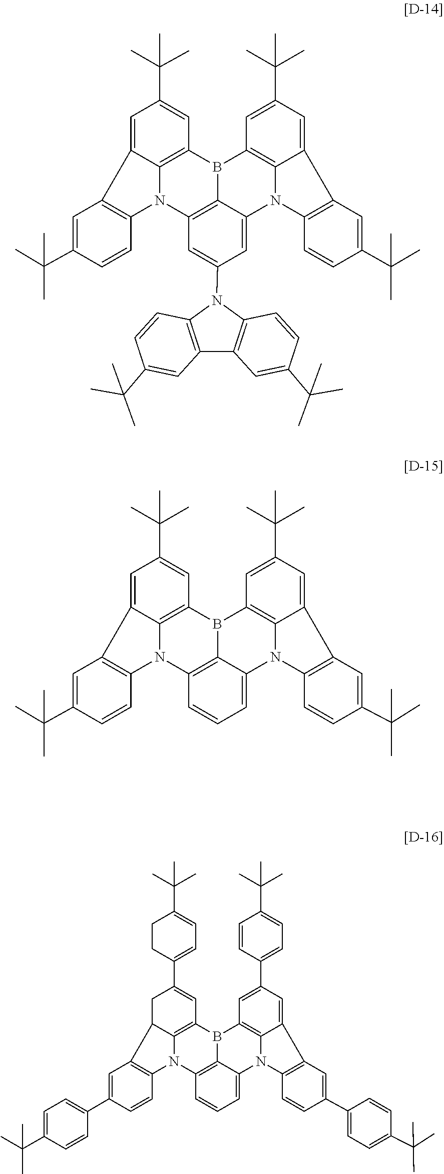

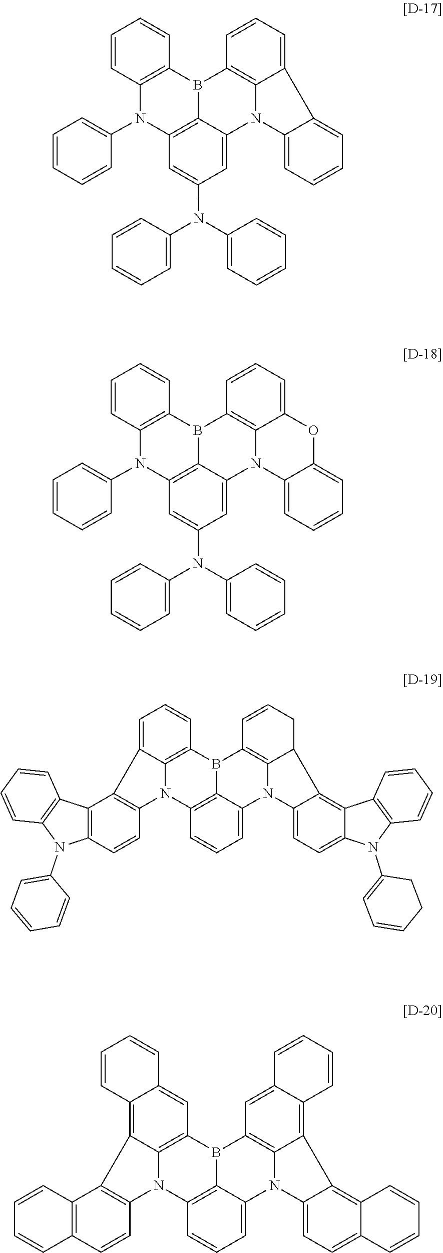 [SMILES: c1ccc(N(c2ccccc2)c2cc3c4c(c2)-n2c5ccccc5c5cccc(c52)B4c2ccccc2N3c2ccccc2)cc1 ; c1ccc(N(c2ccccc2)c2cc3c4c(c2)N2c5ccccc5Oc5cccc(c52)B4c2ccccc2N3c2ccccc2)cc1 ; C1=CCCC(n2c3ccccc3c3c4c(ccc32)N2C3=C(C=CCC34)B3c4c2cccc4-n2c4ccc5c(c6ccccc6n5-c5ccccc5)c4c4cccc3c42)=C1 ; c1cc2c3c(c1)-n1c4ccc5ccccc5c4c4c5ccccc5cc(c41)B3c1cc3ccccc3c3c4c5ccccc5ccc4n-2c13]

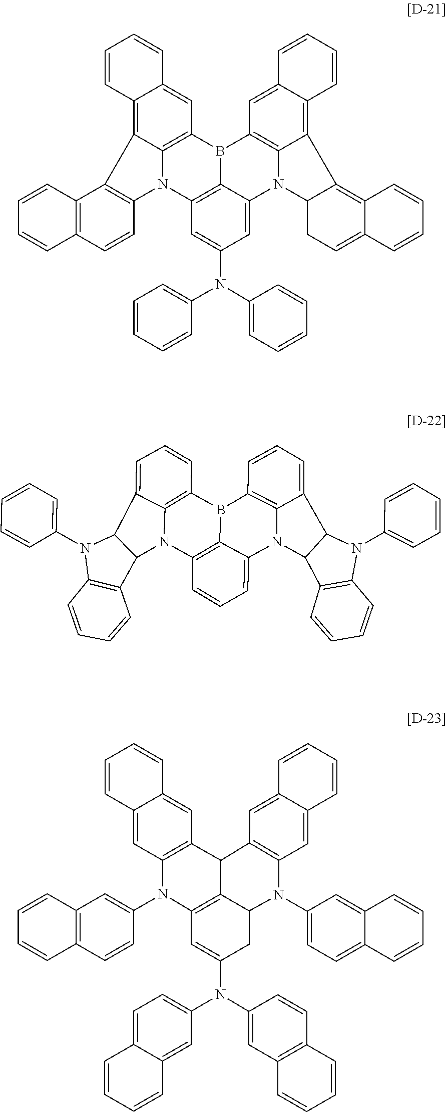 [SMILES: C1=c2ccccc2=C2c3c4c(cc5ccccc35)B3c5c(cc(N(c6ccccc6)c6ccccc6)cc5-n5c6ccc7ccccc7c6c6c7ccccc7cc3c65)N4C2C1 ; c1ccc(N2c3ccccc3C3C2c2cccc4c2N3c2cccc3c2B4c2cccc4c2N3C2c3ccccc3N(c3ccccc3)C42)cc1 ; C1=C(N(c2ccc3ccccc3c2)c2ccc3ccccc3c2)CC2C3=C1N(c1ccc4ccccc4c1)c1cc4ccccc4cc1C3c1cc3ccccc3cc1N2c1ccc2ccccc2c1]

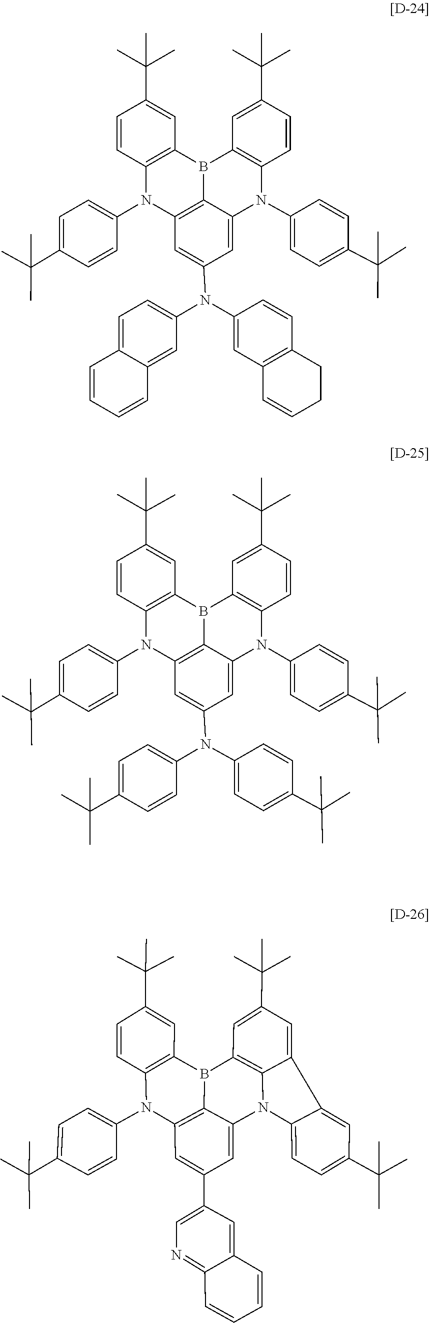

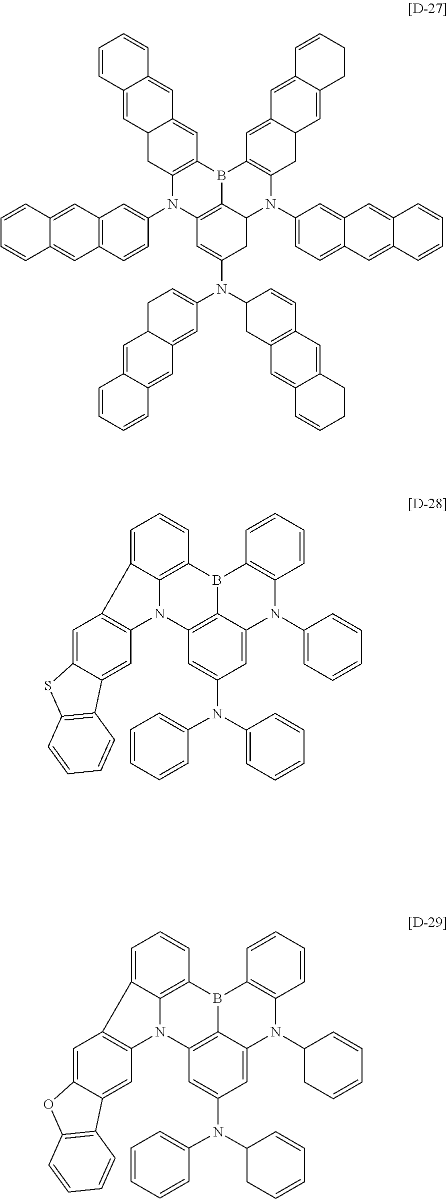 [SMILES: C1=CC2=CC3=CC4=C(CC3C=C2CC1)N(c1ccc2cc3ccccc3cc2c1)C1CC(N(C2=CCC3C=c5ccccc5=CC3=C2)C2C=Cc3cc5c(cc3C2)C=CCC5)=CC2=C1B4C1=C(CC3C=c4ccccc4=CC3=C1)N2c1ccc2cc3ccccc3cc2c1 ; c1ccc(N(c2ccccc2)c2cc3c4c(c2)-n2c5cc6c(cc5c5cccc(c52)B4c2ccccc2N3c2ccccc2)sc2ccccc26)cc1 ; C1=CCC(N(c2ccccc2)c2cc3c4c(c2)-n2c5cc6c(cc5c5cccc(c52)B4c2ccccc2N3C2C=CC=CC2)oc2ccccc26)C=C1]

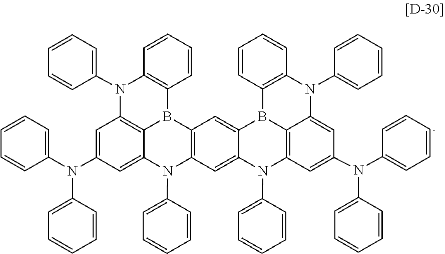 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

8. The light-emitting organic nanoparticles of claim 1, wherein the organic phosphor includes a boron compound represented by Chemical Formula 3 below: 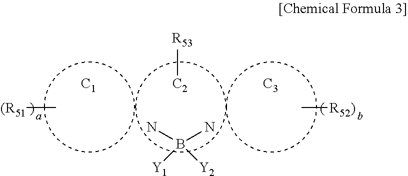
(In Chemical Formula 3 above,
C₁ to C₃ each have a five-membered or six-membered ring structure,
R₅₁ and R₅₂ each independently correspond to at least any one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted thioether group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group,
R₅₃ corresponds to any one selected from the group consisting of hydrogen, deuterium, a halogen group, a hydroxyl group, a cyano group, a nitro group, an amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted thioether group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group,
Y₁ and Y₂ are each independently a fluorine group or an alkoxy group,
a and b are each independently an integer of 1 to 4,
if a and b are 2 or more, the structures in the brackets, are the same or different, respectively,
R₅₁ and R₅₂ may bond to adjacent substituents to form a substituted or unsubstituted ring).

9. The light-emitting organic nanoparticles of claim 8, wherein the boron compound represented by Chemical Formula 3 above is one or more selected from the group consisting of compounds B-1 to B-33 below:

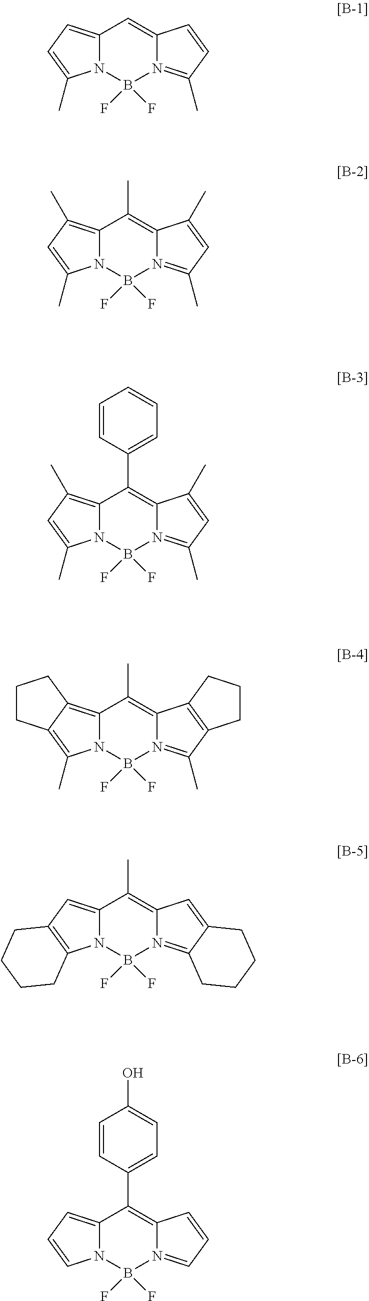

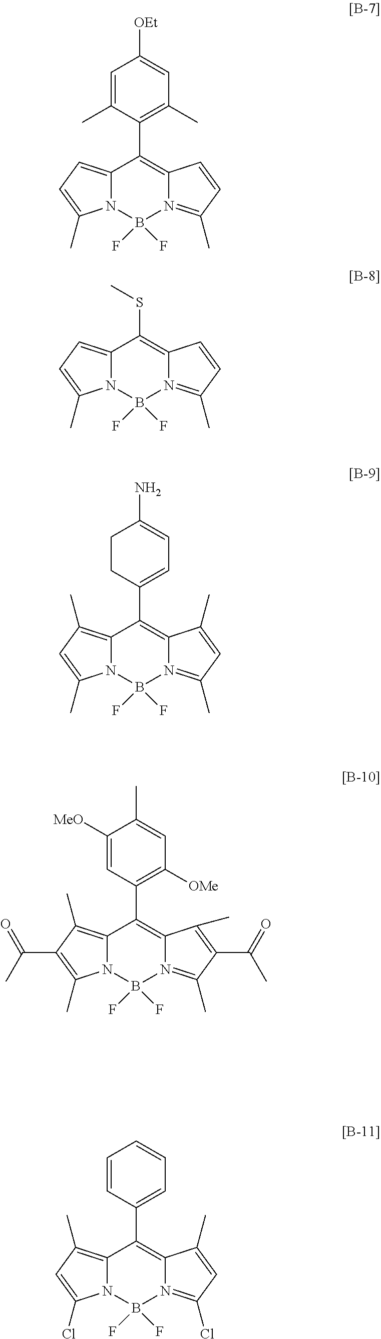

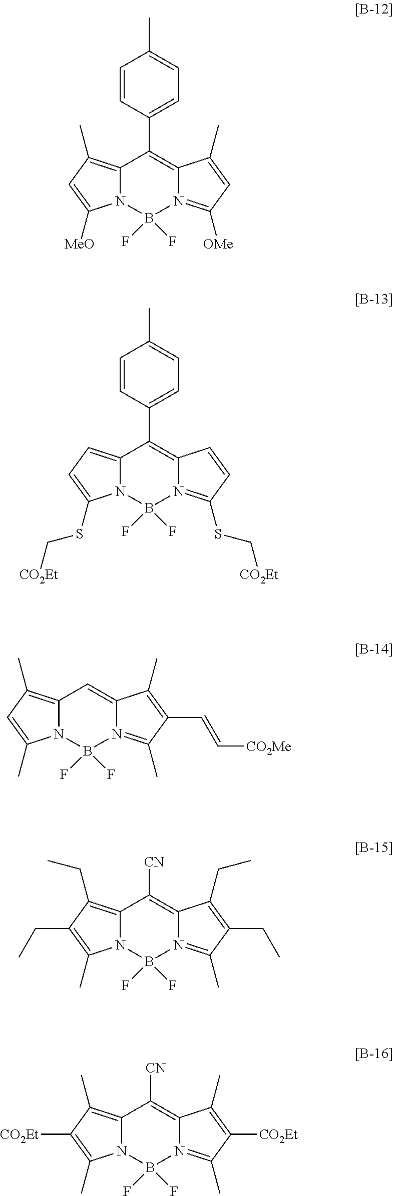

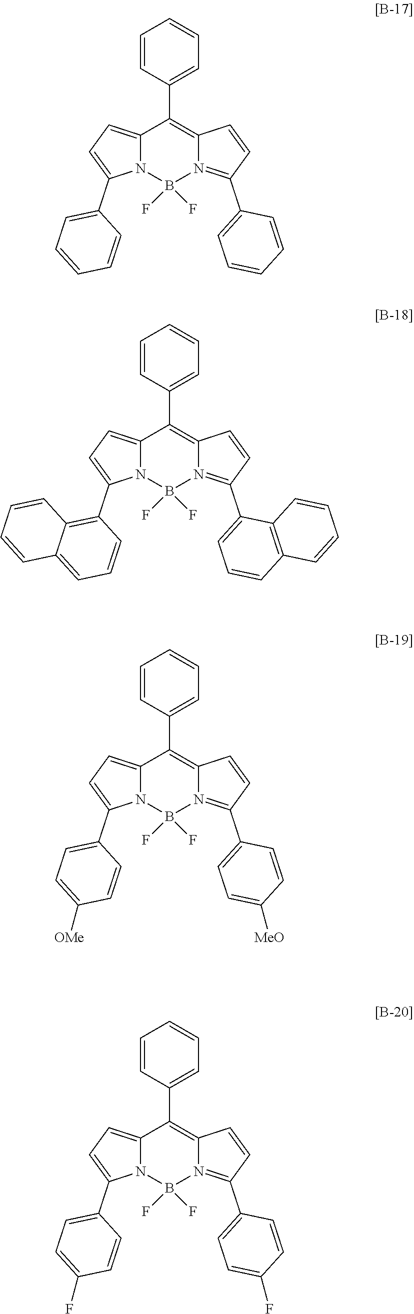

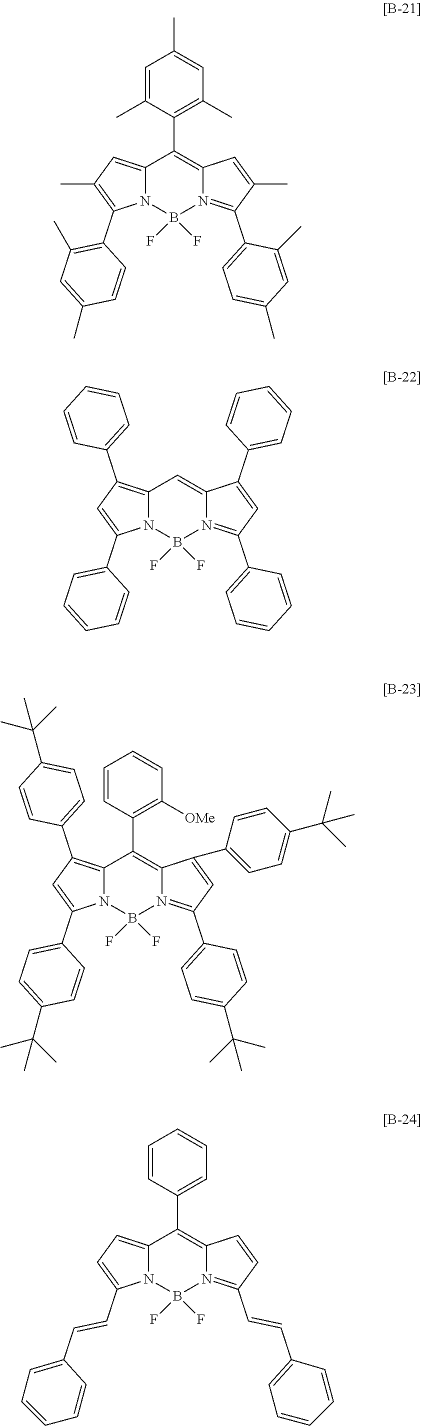

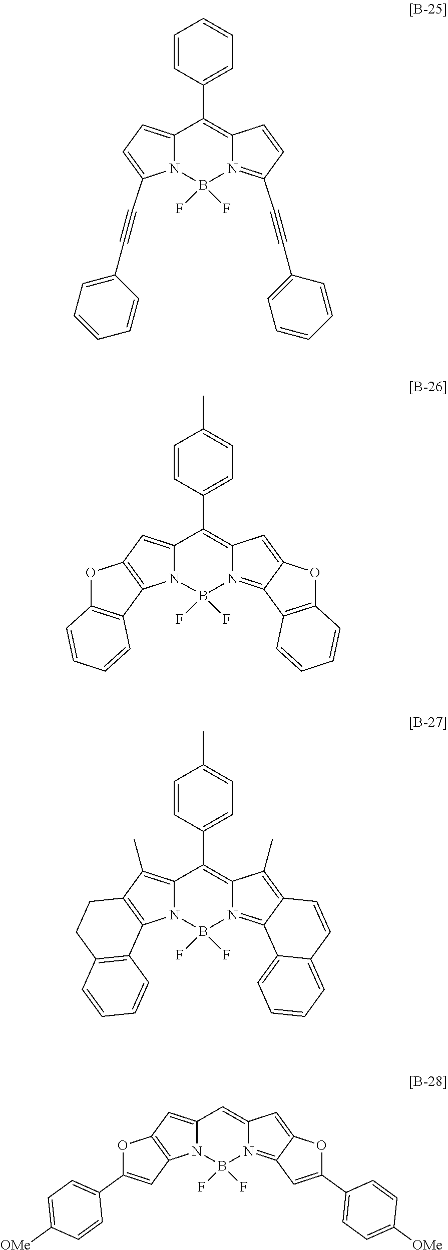

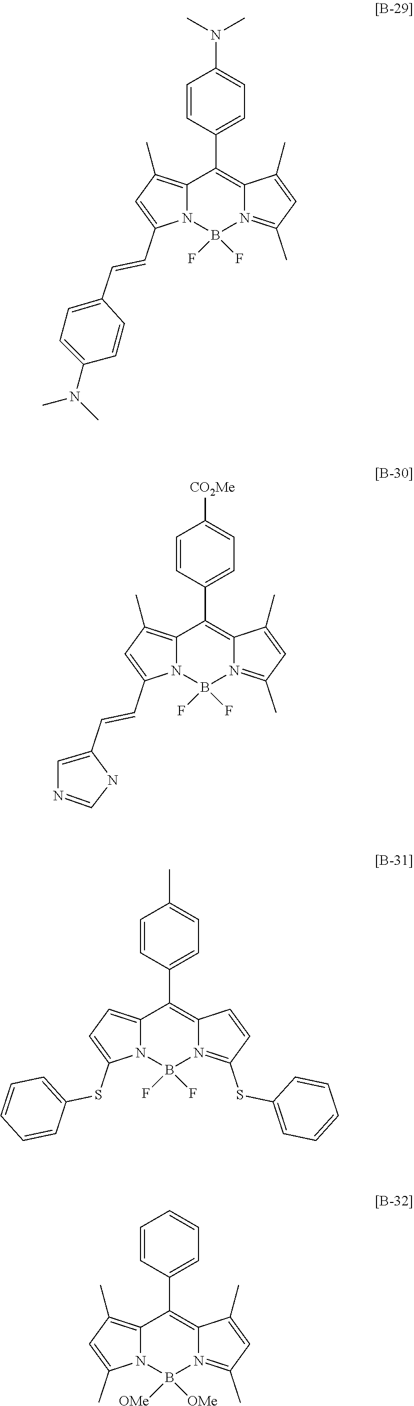

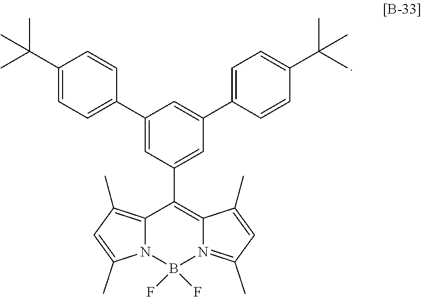

10. The light-emitting organic nanoparticles of claim 2, wherein the surfactant is one or more selected from the group consisting of an anionic surfactant, a cationic surfactant, an amphoteric surfactant, and a nonionic surfactant.

11. A composition for a color conversion film, comprising the light-emitting organic nanoparticles of claim 1 and a water-soluble polymer resin.

12. The composition of claim 11, comprising 1 to 20 parts by weight of the light-emitting organic nanoparticles based on 100 parts by weight of the water-soluble polymer resin.

13. The composition of claim 11, further comprising 0.01 to 20 parts by weight of a crosslinking agent based on 100 parts by weight of the water-soluble polymer resin.

14. The composition of claim 11, further comprising 1 to 20 parts by weight of a light scattering agent based on 100 parts by weight of the water-soluble polymer resin.

15. The composition of claim 11, wherein the water-soluble polymer resin has a weight average molecular weight of 5,000 to 100,000 g/mol and a degree of hydration of 70 to 100%, and is one or more polymers or copolymers selected from the group consisting of a nonionic water-soluble polymer, an anionic water-soluble polymer, and a cationic water-soluble polymer,
the nonionic water-soluble polymer is one or more polymers or copolymers selected from the group consisting of polyvinyl alcohol (PVA), polyethylene oxide (PEO), polyacrylamide (PAM), and polyvinylpyrrolidone (PVP),
the anionic water-soluble polymer is one or more polymers or copolymers selected from the group consisting of polyacrylic acid (PAA) and its derivatives, poly(styrene sulfonic acid) (PSSA), poly(silicic acid) (PSiA), poly(phosphoric acid) (PPA), poly(ethylenesulfinic acid) (PESA), poly[3-(vinyloxy)propane-1-sulfonic acid], poly(4-vinylphenol), poly(4-vinylphenol sulfuric acid), poly(ethylenephosphoric acid), poly(maleic acid), poly(2-methacryloxyethane-1-sulfonic acid), poly(3-methacryloyloxypropane-1-sulfonic acid), and poly(4-vinylbenzoic acid), and
the cationic water-soluble polymer is one or more polymers or copolymers selected from the group consisting of polyethyleneimine (PEI), polyamines, polyamideamine (PAMAM), poly(diallyldimethyl ammonium chloride) (PDADMAC), poly(4-vinylbenzyltrimethylammonium salt), poly [(dimethylimino)trimethylene(dimethylimino)hexamethylenedibromide](polybrene), poly(2-vinylpiperidine salt), poly(vinylamine salt), and poly(2-vinylpyridine) and derivatives thereof.

16. The composition of claim 13, wherein the crosslinking agent is one or more selected from the group consisting of glutaraldehyde, glyoxal, maleic acid, citric acid, trisodium trimetaphosphate, sodium hexametaphosphate, dianhydrides, succinic acid, suberic acid, sulfosuccinic acid, and K₂S₂O₈.

17. The composition of claim 14, wherein the light scattering agent is one or more types of inorganic oxide particles selected from the group consisting of TiO₂, ZnO, Fe₃O₄, CeO₂, MoO₂, Ag₂O, CuO, and NiO, and
the inorganic metal oxide particles have an average particle size of 200 to 400 nm.

18. A color conversion film manufactured using the composition for a color conversion film according to claim 11.

19. A display device comprising the color conversion film of claim 18.

20. A light-emitting diode device comprising the color conversion film of claim 18.
